(19) United States
(12) Patent Application Publication
(10) Pub. No.: US 2025/0046672 A1
(43) Pub. Date: Feb. 6, 2025

(54) SEMICONDUCTOR MODULE

(71) Applicant: ROHM CO., LTD., Kyoto-shi (JP)

(72) Inventor: Masashi HAYASHIGUCHI, Kyoto-shi (JP)

(21) Appl. No.: 18/923,270

(22) Filed: Oct. 22, 2024

Related U.S. Application Data
(63) Continuation of application No. PCT/JP2023/014921, filed on Apr. 12, 2023.

(30) Foreign Application Priority Data
Apr. 26, 2022 (JP) 2022-072276
Dec. 23, 2022 (JP) 2022-206150

(51) Int. Cl. H01L 23/367; H01L 23/473

(52) U.S. Cl. CPC H01L 23/3675; H01L 23/473

(57) ABSTRACT

A semiconductor module includes a cooling unit and a semiconductor device attached to the cooling unit. The cooling unit includes a housing and a heat dissipating member. The housing includes a recess and a bottom portion. The heat dissipating member is attached to the bottom portion and at least partly accommodated in the recess. The recess includes an inlet and an outlet. The semiconductor device includes a substrate that includes a heat dissipating layer covering the recess. The heat dissipating layer includes a base surface facing the recess and a depression recessed from the base surface. The depression overlaps with the recess in plan view.

### TECHNICAL FIELD

The present disclosure relates to a semiconductor module that includes a cooling unit and a semiconductor device.

### BACKGROUND ART

WO 2017/094370 A1 discloses an example of a semiconductor module that includes a cooling unit and a semiconductor device. The cooling unit of the semiconductor module includes a radiator and a housing. The housing has a hollow region and an opening to the hollow region. The radiator is attached to the housing to close the opening. The semiconductor device is bonded to the radiator at a location outside the hollow region. When the hollow region is filled with coolant, the coolant comes into contact with the radiator. In this way, the semiconductor device is cooled.

In the semiconductor module disclosed in WO 2017/094370 A1, the semiconductor device is cooled indirectly via the radiator. In addition, a gap is present between the radiator in the hollow region and the housing, so that coolant tends to flow locally through the gap. This may result in insufficient cooling of the radiator and the semiconductor device by the coolant.

### BRIEF DESCRIPTION OF THE DRAWINGS

FIG. 1 is a plan view of a cooling unit included in a semiconductor module according to a first embodiment of the present disclosure.

FIG. 2 is a front view of the cooling unit shown in FIG. 1.

FIG. 3 is a left-side view of the cooling unit shown in FIG. 1.

FIG. 4 is an enlarged fragmentary view of FIG. 1.

FIG. 5 is a sectional view taken along line V-V of FIG. 4.

FIG. 6 is a sectional view taken along line VI-VI of FIG. 4.

FIG. 7 is a perspective view of one of a plurality of semiconductor devices included in the semiconductor module according to the first embodiment of the present disclosure.

FIG. 8 is a plan view of the semiconductor device shown in FIG. 7.

FIG. 9 is a plan view corresponding to FIG. 8, except that a sealing resin is shown as transparent.

FIG. 10 is an enlarged fragmentary view of FIG. 9.

FIG. 11 is a plan view corresponding to FIG. 8, except that a first conductive member is shown as transparent and that the sealing resin and a second conductive member are omitted.

FIG. 12 is a right-side view of the semiconductor device shown in FIG. 7.

FIG. 13 is a bottom view of the semiconductor device shown in FIG. 7.

FIG. 14 is a sectional view taken along line XIV-XIV of FIG. 9.

FIG. 15 is a sectional view taken along line XV-XV of FIG. 9.

FIG. 16 is an enlarged fragmentary view showing a portion around a first element shown in FIG. 15.

FIG. 17 is an enlarged fragmentary view showing a portion around a second element shown in FIG. 15.

FIG. 18 is a sectional view taken along line XVIII-XVIII of FIG. 9.

FIG. 19 is a sectional view taken along line XIX-XIX of FIG. 9.

FIG. 20 is a plan view of the semiconductor module according to the first embodiment of the present disclosure.

FIG. 21 is a front view of the semiconductor module shown in FIG. 20.

FIG. 22 is an enlarged fragmentary view of FIG. 20, with a mounting component omitted.

FIG. 23A is a sectional view taken along line XXIIIA-XXIIIA in FIG. 22.

FIG. 23B is a sectional view taken along line XXIIIB-XXIIIB in FIG. 22.

FIG. 24 is an enlarged fragmentary plan view of a cooling unit included in a semiconductor module according to a second embodiment of the present disclosure.

FIG. 25 is a sectional view taken along line XXV-XXV in FIG. 24.

FIG. 26 is a sectional view taken along line XXVI-XXVI in FIG. 24.

FIG. 27 is an enlarged fragmentary sectional view of the semiconductor module according to the second embodiment of the present disclosure.

FIG. 28 is an enlarged fragmentary plan view of a cooling unit included in a semiconductor module according to a third embodiment of the present disclosure.

FIG. 29 is a sectional view taken along line XXIX-XXIX in FIG. 28.

FIG. 30 is a sectional view taken along line XXX-XXX in FIG. 28.

FIG. 31 is an enlarged fragmentary sectional view of the semiconductor module according to the third embodiment of the present disclosure.

FIG. 32 is an enlarged fragmentary plan view of a cooling unit included in a semiconductor module according to a fourth embodiment of the present disclosure.

FIG. 33 is a sectional view taken along line XXXIII-XXXIII in FIG. 32.

FIG. 34 is a sectional view taken along line XXXIV-XXXIV in FIG. 32.

FIG. 35 is a bottom view of one of a plurality of semiconductor devices included in the semiconductor module according to the fourth embodiment of the present disclosure.

FIG. 36 is a sectional view of the semiconductor device shown in FIG. 35.

FIG. 37 is a sectional view of the semiconductor device shown in FIG. 35, taken along a line different from that in FIG. 36.

FIG. 38 is an enlarged fragmentary plan view of the semiconductor module according to the fourth embodiment of the present disclosure, with a mounting component omitted.

FIG. 39 is a sectional view taken along line XXXIX-XXXIX in FIG. 38.

FIG. 40 is an enlarged fragmentary plan view of a variation of the cooling unit shown in FIG. 32.

FIG. 41 is an enlarged fragmentary sectional view of a cooling unit included in a semiconductor module according to a fifth embodiment of the present disclosure.

FIG. 42 is an enlarged fragmentary sectional view of the cooling unit shown in FIG. 41, taken along a line different from that in FIG. 41.

FIG. 43 is an enlarged fragmentary sectional view of the semiconductor module according to the fifth embodiment of the present disclosure.

FIG. 44 is an enlarged fragmentary plan view of a semiconductor module according to a sixth embodiment of the present disclosure, with a mounting component omitted.

FIG. 45 is a sectional view taken along line XLV-XLV of FIG. 44.

FIG. 46 is a plan view of one of a plurality of semiconductor devices included in a semiconductor module according to a seventh embodiment of the present disclosure.

FIG. 47 is a plan view corresponding to FIG. 46, in which some components including a plurality of first semiconductor elements and a sealing resin are shown as transparent, and some layers including a first insulating layer, a first conductive layer, a second conductive layer, and a first heat dissipating layer are omitted.

FIG. 48 is a bottom view of the semiconductor device shown in FIG. 46.

FIG. 49 is a plan view corresponding to FIG. 48, in which some components including a plurality of second semiconductor elements and a sealing resin are shown as transparent, and some layers including a second insulating layer, a third conductive layer, and a second heat dissipating layer are omitted.

FIG. 50 is a right-side view of the semiconductor device shown in FIG. 46.

FIG. 51 is a front view of the semiconductor device shown in FIG. 46.

FIG. 52 is a sectional view taken along line LII-LII in FIG. 47.

FIG. 53 is a sectional view taken along line LIII-LIII in FIG. 47.

FIG. 54 is a sectional view taken along line LIV-LIV in FIG. 47.

FIG. 55 is a sectional view taken along line LV-LV in FIG. 47.

FIG. 56 is a sectional view taken along line LVI-LVI in FIG. 47.

FIG. 57 is an enlarged fragmentary view of FIG. 54, showing a portion around a first semiconductor element and a first spacer.

FIG. 58 is an enlarged fragmentary view of FIG. 54, showing a portion around a second semiconductor element and a second spacer.

FIG. 59 is a front view of the semiconductor module according to the seventh embodiment of the present disclosure.

FIG. 60 is an enlarged fragmentary plan view of the semiconductor module shown in FIG. 59, with an additional cooling unit omitted.

FIG. 61 is a sectional view taken along line LXI-LXI in FIG. 60.

FIG. 62 is a plan view of one of a plurality of semiconductor devices included in a semiconductor module according to an eighth embodiment of the present disclosure.

FIG. 63 is a bottom view of the semiconductor device shown in FIG. 62.

FIG. 64 is a sectional view of the semiconductor device shown in FIG. 62 and corresponds to FIG. 54.

FIG. 65 is a sectional view of the semiconductor device shown in FIG. 62 and corresponds to FIG. 55.

FIG. 66 is an enlarged fragmentary plan view of the semiconductor module according to the eighth embodiment of the present disclosure, with an additional cooling unit omitted.

FIG. 67 is a sectional view taken along line LXVII-LXVII in FIG. 66.

### DETAILED DESCRIPTION OF EMBODIMENTS

With reference to the accompanying drawings, embodiments of the present disclosure will be described.

### First Embodiment

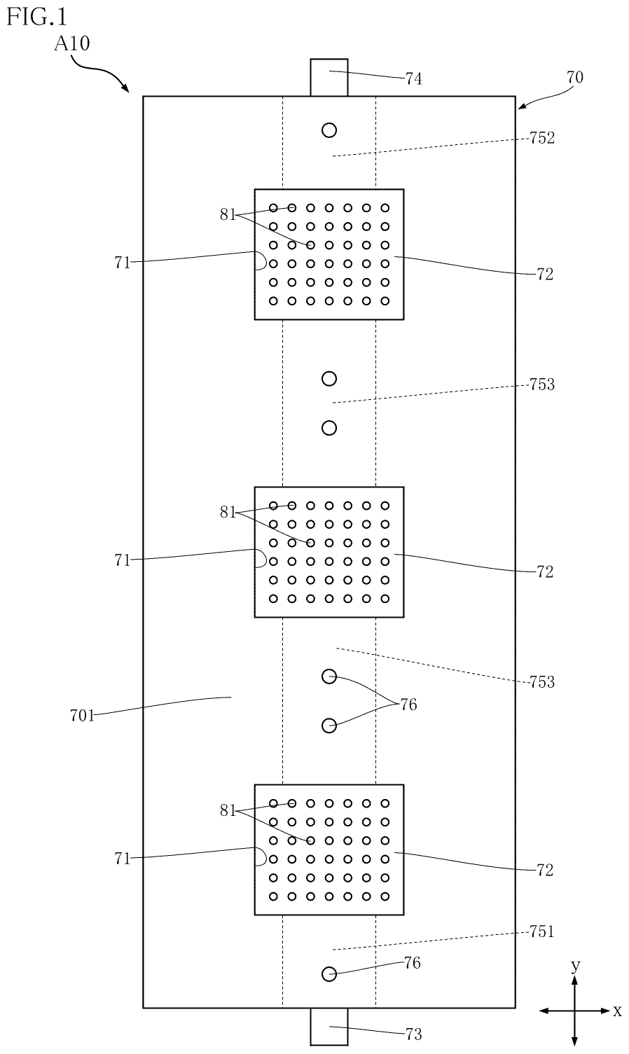

With reference to FIGS. 1 to 23B, a semiconductor module C10 according to a first embodiment of the present disclosure will be described. The semiconductor module C10 includes a cooling unit A10, a plurality of semiconductor devices B10, and a plurality of mounting components 88. For instance, the semiconductor module C10 constitutes a part of an inverter device for driving a three-phase AC motor.

### Cooling Unit A10

First, with reference to FIGS. 1 to 6, the cooling unit A10 included in the semiconductor module C10 is described. The cooling unit A10 is used for cooling the semiconductor devices B10. The cooling unit A10 includes a housing 70 and a plurality of heat dissipating members 81. In the description of the cooling unit A10, the direction normal to an obverse surface 701 (described later) of the housing 70 is defined as a “first direction z”. A direction orthogonal to the first direction z is defined as a “second direction x”. The direction orthogonal to both the first direction z and the second direction x is defined as a “third direction y”. The first direction z, the second direction x, and the third direction y are also used in the description of the semiconductor devices B10 and the semiconductor module C10.

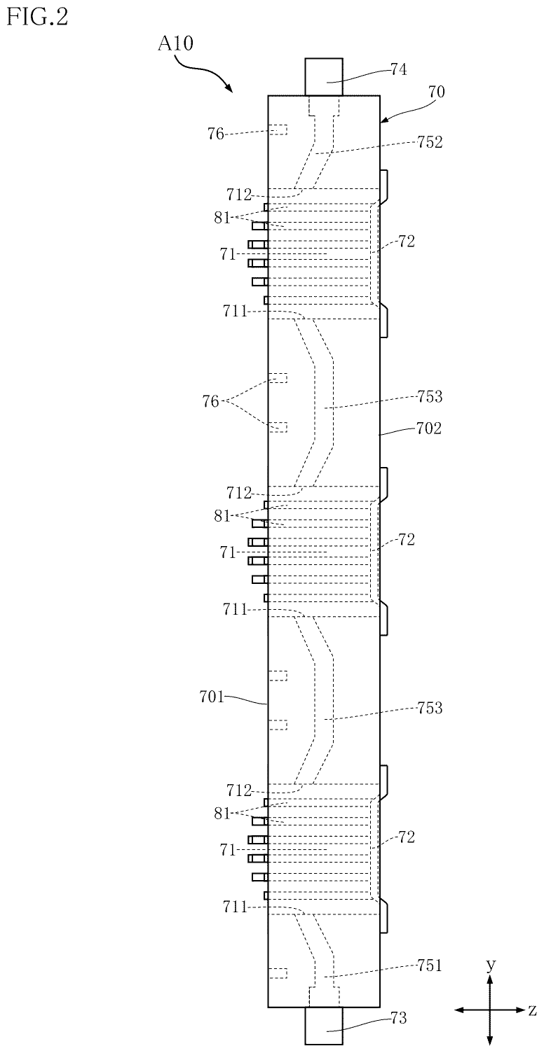

As shown in FIGS. 1 and 2, the housing 70 forms a major part of the cooling unit A10. For the cooling unit A10, the housing 70 is integral, except its bottom portions 72. The integral portion of the housing 70 is made of a material containing aluminum, for example.

As shown in FIGS. 1 to 6, the housing 70 includes a plurality of recesses 71 and a plurality of bottom portions 72. Each recess 71 is open on a first side in the first direction z. The recesses 71 are aligned in the third direction y. Each bottom portion 72 is located on a second side in the first direction z and defines a part of a recess 71.

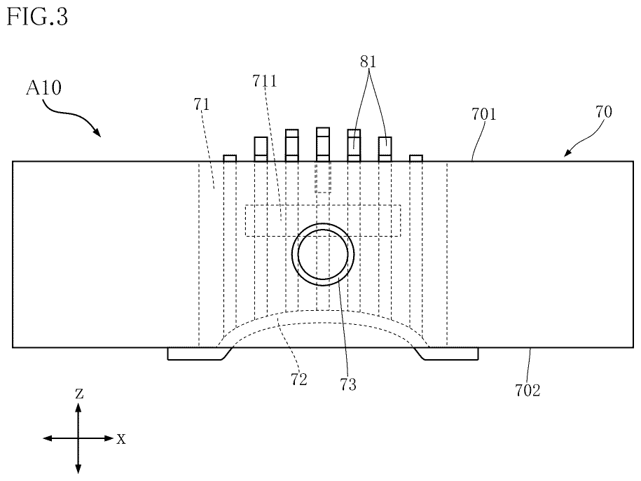

As shown in FIGS. 3, 5 and 6, the housing 70 has an obverse surface 701 and a reverse surface 702. The obverse surface 701 faces the side where the heat dissipating members 81 are located in the first direction z with respect to the bottom portions 72. The obverse surface 701 surrounds each recess 71. The recesses 71 are recessed from the obverse surface 701 in the first direction z. The reverse surface 702 faces away from the obverse surface 701 in the first direction z.

Each bottom portion 72 includes an elastic portion 721 that is elastically deformable. For the cooling unit A10, each elastic portion 721 is composed of a single piece. In addition, each bottom portion 72 is entirely composed of an elastic portion 721. The elastic portions 721 are made of a material containing natural rubber, for example. In another example, the material of the elastic portions 721 may be metal. In the cooling unit A10, the bottom portions 72 are joined to the reverse surface 702 of the housing 70 through vulcanization, for example. Alternatively, the bottom portions 72 may be integrally formed with the housing 70. The configuration of the bottom portions 72 is not specifically limited as long as each bottom portion 72 includes an elastic portion 721 that is elastically deformable.

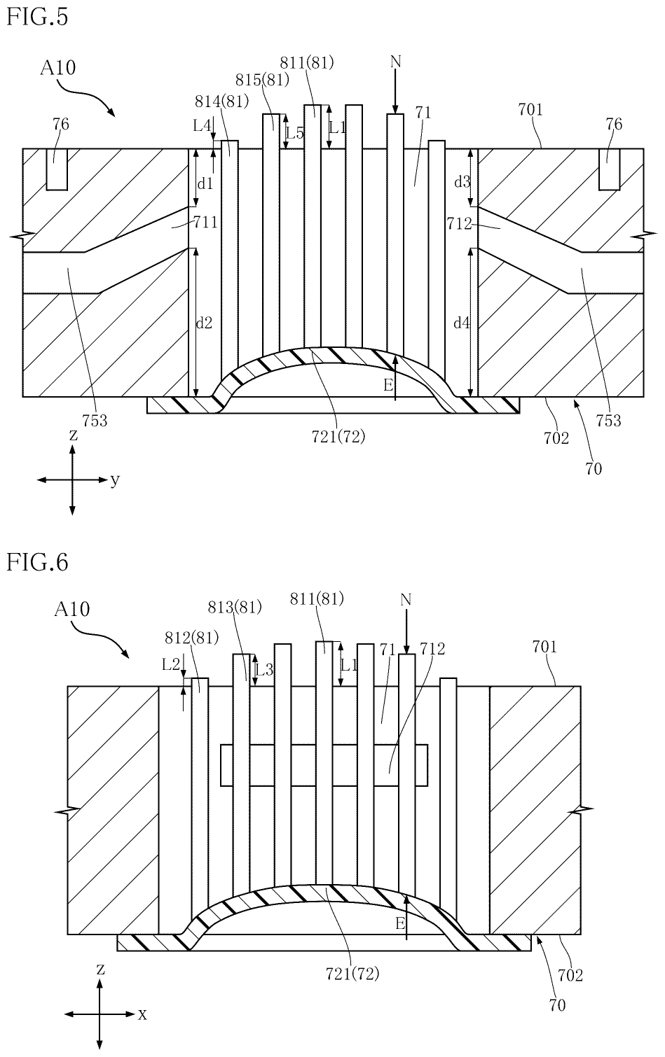

As shown in FIGS. 5 and 6, each heat dissipating members 81 is attached to a bottom portion 72. At least a portion of each heat dissipating member 81 is accommodated in a recess 71. The thermal conductivity of the heat dissipating members 81 is higher than that of the housing 70.

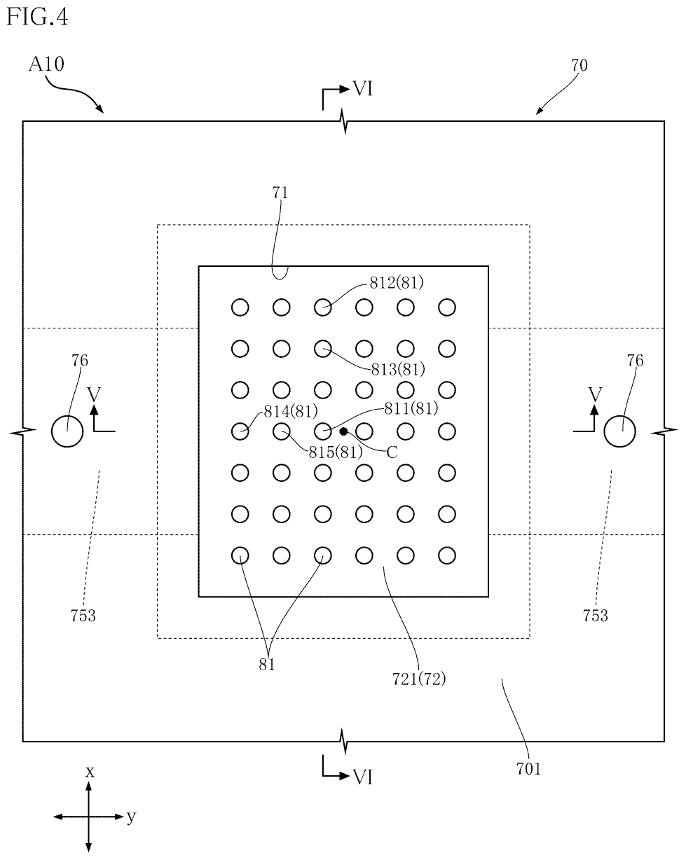

As shown in FIGS. 4 to 6, the heat dissipating members 81 include a first member 811, a second member 812, a third member 813, a fourth member 814, and a fifth member 815 that are spaced apart from one another. The first to fifth members 811 to 815 each have a rod-like shape extending in the first direction z and are supported on the elastic portion 721 of the bottom portion 72. The first to fifth members 811 to 815 are all equal in dimension in the first direction z. As shown in FIG. 4, the first to fifth members 811 to 815 are surrounded by the obverse surface 701 of the housing 70 as viewed in the first direction z (in plan view). As shown in FIGS. 5 and 6, when the elastic portion 721 is in the natural state, each of the first to fifth members 811 to 815 partly protrudes outward from the obverse surface 701. The natural state of the elastic portion 721 refers to the state in which the semiconductor device B10 is removed from the semiconductor module C10, and thus the only load acting on the elastic portion 721 in the cooling unit A10 is the weight of the heat dissipating members 81.

As shown in FIGS. 4 and 6, the first member 811 and the second member 812 are spaced apart from each other in the second direction x. The first member 811 is closest to the center C of the recess 71 as viewed in the first direction z. The center C coincides with the center of the geometric shape defined by the peripheral edge of the recess 71 as viewed in the first direction z. The second member 812 is closest to the obverse surface 701 of the housing 70. The third member 813 is located between the first member 811 and the second member 812 in the second direction x.

As shown in FIG. 6, when the elastic portion 721 of the bottom portion 72 is in the natural state, an amount that the first member 811 protrudes outward from the obverse surface 701 of the housing 70 (protruding amount L1) is greater than an amount that the second member 812 protrudes outward from the obverse surface 701 of the housing 70 (protruding amount L2). In addition, an amount that the third member 813 protrudes outward from the obverse surface 701 (protruding amount L3) is smaller than the protruding amount L1 and greater than the protruding amount L2.

As shown in FIGS. 4 and 5, the first member 811 and the fourth member 814 are spaced apart from each other in the third direction y. The fourth member 814 is closest to the obverse surface 701 of the housing 70. The fifth member 815 is located between the first member 811 and the fourth member 814 in the third direction y.

As shown in FIG. 5, when the elastic portion 721 of the bottom portion 72 is in the natural state, the protruding amount L1 of the first member 811 is greater than an amount of the fourth member 814 that protrudes outward from the obverse surface 701 (protruding amount L4). In addition, an amount of the fifth member 815 that protrudes outward from the obverse surface 701 (protruding amount L5) is smaller than the protruding amount L1 and greater than the protruding amount L4.

As shown in FIGS. 5 and 6, the bottom portion 72 bulges in the first direction z toward the side where the heat dissipating members 81 are located. The bottom portion 72 is farthest from the reverse surface 702 of the housing 70 in the first direction z at the center C shown in FIG. 4.

As shown in FIGS. 5 and 6, when a load N is applied toward the second side in the first direction z (the side where the bottom portion 72 is located in the first direction z with respect to the heat dissipating members 81), the elastic portion 721 of the bottom portion 72 exerts an elastic force E that pushes the heat dissipating members 81 toward the first side in the first direction z (the side where the heat dissipating members 81 are located in the first direction z with respect to the bottom portion 72). The elastic force E is generated by the elastic portion 721 being elastically deformed in response to the load N that is transmitted to the bottom portion 72 through the heat dissipating members 81. The elastic force E is the reaction of the load N.

As shown in FIG. 2, each recess 71 is provided with an inlet 711 and an outlet 712. The inlet 711 and the outlet 712 are located opposite to each other in the third direction y with respect to the recess 71. In the first direction z, the inlet 711 and the outlet 712 are located between the obverse surface 701 and the reverse surface 702 of the housing 70. The inlet 711 and the outlet 712 are in communication with the recess 71.

As shown in FIGS. 3 and 6, the first member 811 of the heat dissipating members 81 overlaps with the inlet 711 and the outlet 712 as viewed in the third direction y. As shown in FIG. 5, a distance d1 between the inlet 711 and the obverse surface 701 of the housing 70 in the first direction z is smaller than a distance d2 between the inlet 711 and the reverse surface 702 of the housing 70 in the first direction z. Additionally, a distance d3 between the outlet 712 and the obverse surface 701 in the first direction z is smaller than a distance d4 between the outlet 712 and the reverse surface 702 in the first direction z.

As shown in FIGS. 1 and 2, the housing 70 includes an inflow section 73, an outflow section 74, a first channel 751, a second channel 752, and two intermediate channels 753. The inflow section 73 and the outflow section 74 are located opposite in the third direction y with respect to the obverse surface 701 of the housing 70. The first channel 751 connects the inflow section 73 and the inlet 711 of the nearest recess 71. The second channel 752 connects the outflow section 74 and the outlet 712 of the nearest recess 71. Each of the two intermediate channel 753 is located between two recesses 71 that are adjacent to each other in the third direction y, connecting the outlet 712 of one recess 71 to the inlet 711 of the other recess 71. The cooling unit A10 is supplied with coolant, which enters from the inflow section 73 and flows through the first channel 751 and the two intermediate channels 753 to fill the recesses 71. After filling the recesses 71, the coolant flows through the second channel 752 to the outflow section 74 and exits to the outside. The coolant discharged to the outside is cooled again and returned to the cooling unit A10 from the inflow section 73. In this way, the coolant is circulated through the semiconductor module C10.

### Semiconductor Devices B10

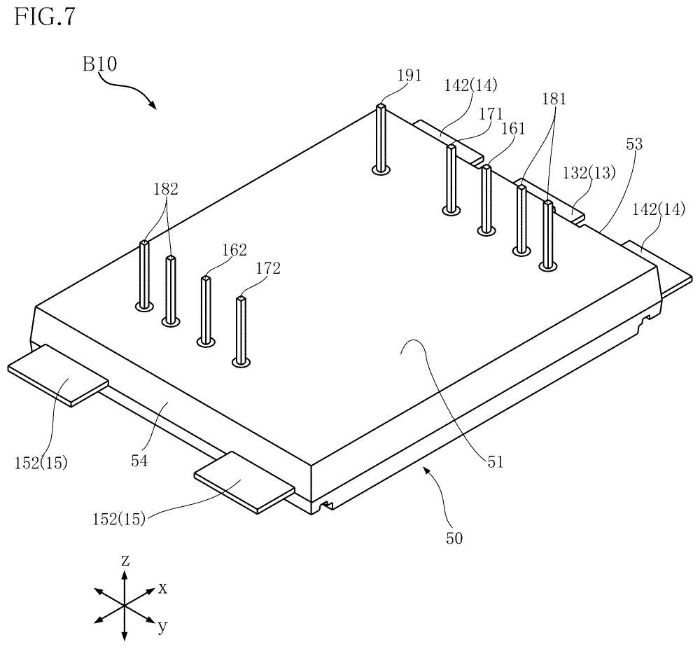

Next, with reference to FIGS. 7 to 19, the semiconductor devices B10 included in the semiconductor module C10 are described. The semiconductor devices B10 are all identical. The following description thus is directed to one semiconductor device B10.

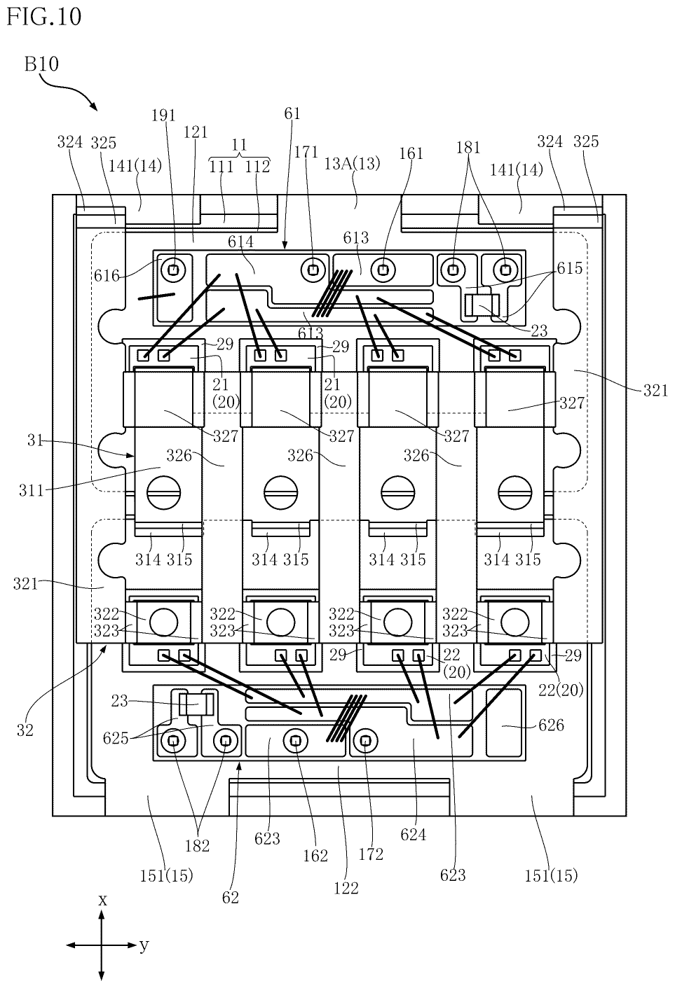

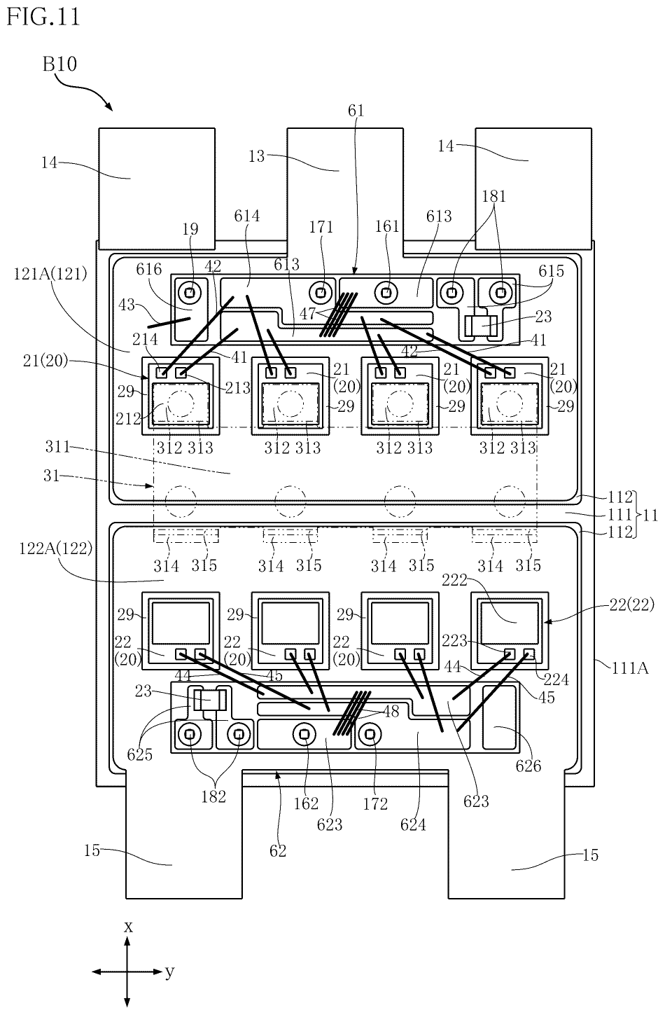

The semiconductor device B10 includes a substrate 11, a first conductive layer 121, a second conductive layer 122, a first power terminal 13, two second power terminals 14, two third power terminals 15, a first signal terminal 161, a second signal terminal 162, a plurality of semiconductor elements 20, a first conductive member 31, a second conductive member 32, and a sealing resin 50. The semiconductor device B10 additionally includes a third signal terminal 171, a fourth signal terminal 172, two fifth signal terminals 181, two sixth signal terminals 182, a seventh signal terminal 191, two thermistors 23, a first wiring 61, and a second wiring 62. For the convenience of illustration, FIGS. 9 and 10 show the sealing resin 50 as transparent. In FIG. 9, the outline of the sealing resin 50 is indicated by imaginary lines (two-dot-dash lines). For the convenience of illustration, FIG. 11 shows the first conductive member 31 as transparent and omits the second conductive member 32 and the sealing resin 50.

The semiconductor device B10 converts DC power inputted to the first power terminal 13 and the two second power terminals 14 into AC power using the semiconductor elements 20. The resulting AC power is outputted from the two third power terminals 15 to a power supply target, such as a motor. The semiconductor device B10 constitutes a part of a power conversion circuit, such as an inverter.

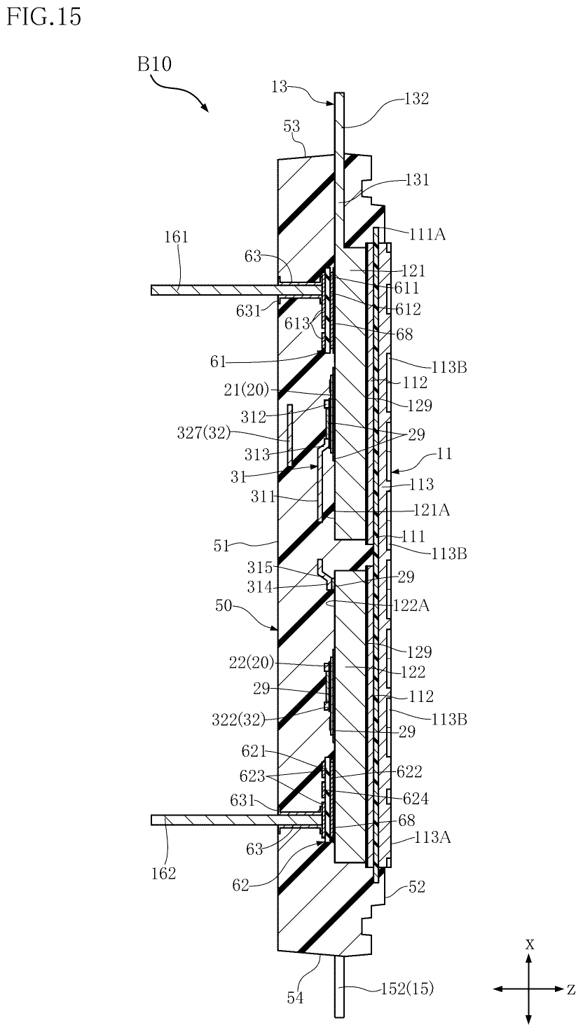

As shown in FIGS. 15 to 17, the substrate 11 is located opposite to the semiconductor elements 20 in the first direction z with respect to the first conductive layer 121 and the second conductive layer 122. The substrate 11 supports the first conductive layer 121 and the second conductive layer 122. The substrate 11 of the semiconductor device B10 is made of a direct bonded copper (DBC) substrate. As shown in FIGS. 15 to 17, the substrate 11 includes an insulating layer 111, two intermediate layers 112, and a heat dissipating layer 113. The substrate 11 is covered with the sealing resin 50, except at a portion of the heat dissipating layer 113.

As shown in FIGS. 15 to 17, the insulating layer 111 includes a portion located between the intermediate layer 112 and the heat dissipating layer 113 in the first direction z. The insulating layer 111 is made of a material with relatively high thermal conductivity. For example, the insulating layer 111 is made of a ceramic material containing aluminum nitride (AN). In a different example, the insulating layer 111 may be made of an insulating resin sheet, instead of a ceramic material. The insulating layer 111 is smaller in dimension in the first direction z than the first conductive layer 121 and the second conductive layer 122.

As shown in FIGS. 15 to 17, one of the two intermediate layers 112 is located between the insulating layer 111 and the first conductive layer 121 in the first direction z, and the other between the insulating layer 111 and the second conductive layer 122. The intermediate layers 112 are spaced apart from each other in the second direction x. The composition of the intermediate layers 112 may include copper (Cu). As shown in FIG. 11, the intermediate layers 112 are surrounded by a peripheral edge 111A of the insulating layer 111 as viewed in the first direction z.

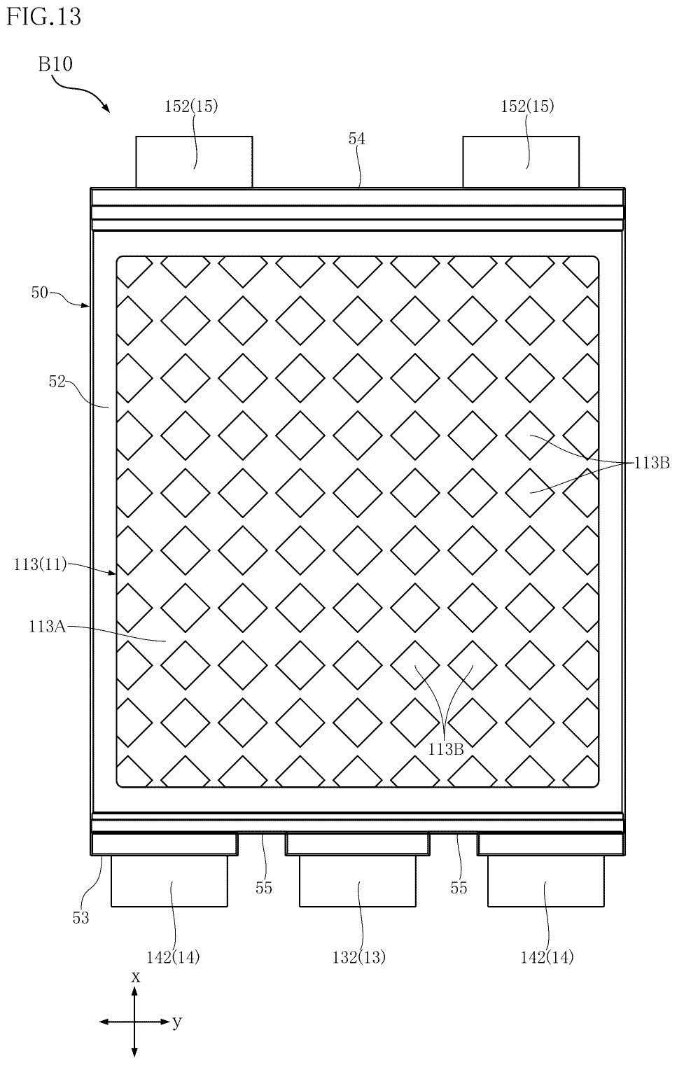

As shown in FIGS. 15 to 17, the heat dissipating layer 113 is located opposite to the intermediate layers 112 in the first direction z with respect to the insulating layer 111. As shown in FIG. 13, the heat dissipating layer 113 is exposed from the sealing resin 50. The composition of the heat dissipating layer 113 may include copper. The heat dissipating layer 113 is thicker than the insulating layer 111. The heat dissipating layer 113 is surrounded by the peripheral edge 111A of the insulating layer 111 as viewed in the first direction z.

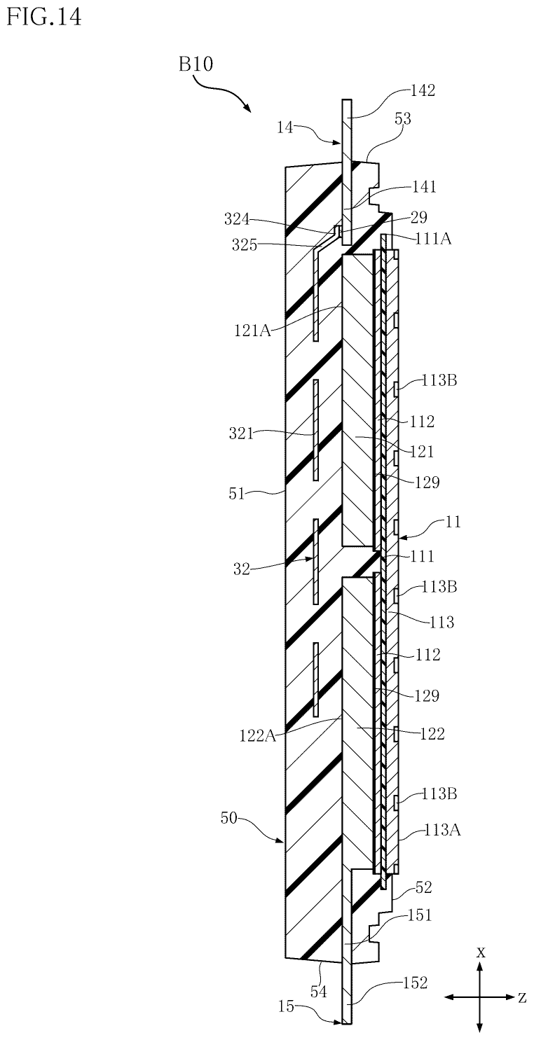

As shown in FIG. 13, the heat dissipating layer 113 has a base surface 113A and a plurality of depressions 113B. As shown in FIGS. 14 to 19, the base surface 113A faces away from the insulating layer 111 in the first direction z. The base surface 113A is located farther from the sealing resin 50 in the first direction z than a bottom surface 52 of the sealing resin 50. That is, the base surface 113A protrudes from the sealing resin 50 in the first direction z. The depressions 113B are recessed from the base surface 113A in the first direction z.

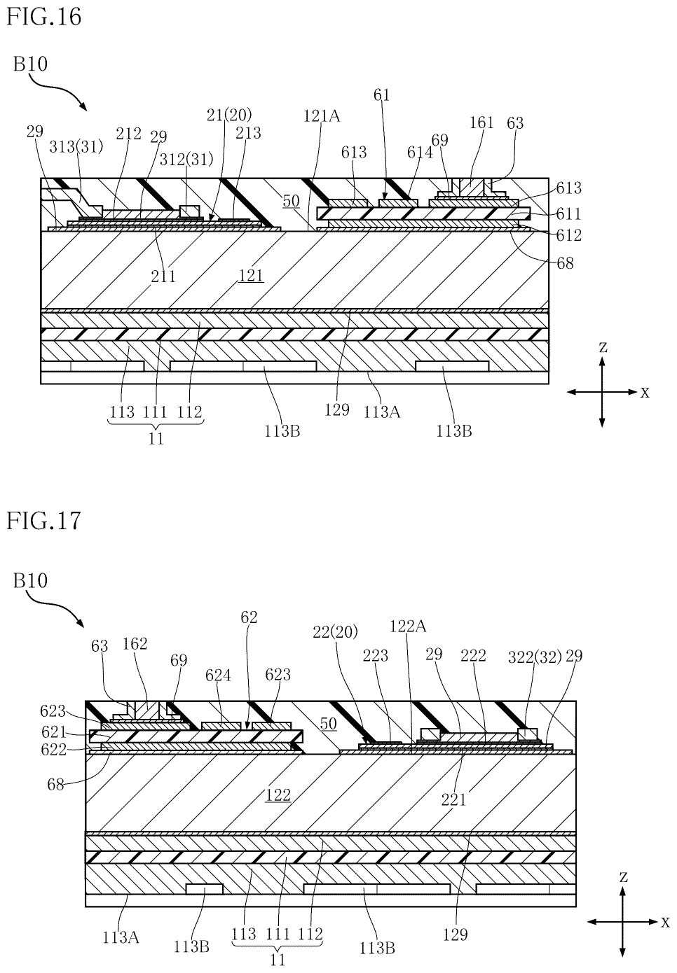

As shown in FIGS. 15 to 17, the first conductive layer 121 and the second conductive layer 122 are bonded to the substrate 11. The composition of the first conductive layer 121 and the second conductive layer 122 may include copper. The first conductive layer 121 and the second conductive layer 122 are spaced apart from each other in the second direction x. As shown in FIGS. 14 and 15, the first conductive layer 121 has a first obverse surface 121A facing in the first direction z. The first obverse surface 121A faces the semiconductor elements 20. As shown in FIG. 16, the first conductive layer 121 is bonded to one of the intermediate layers 112 via a first bonding layer 129. The first bonding layer 129 may be a layer of solder, for example. As shown in FIGS. 14 and 15, the second conductive layer 122 has a second obverse surface 122A facing the same side as the first obverse surface 121A in the first direction z. As shown in FIG. 17, the second conductive layer 122 is bonded to the other intermediate layer 112 via a first bonding layer 129.

As shown in FIGS. 11 and 15, each semiconductor element 20 is mounted on either the first conductive layer 121 or the second conductive layer 122. In one example, the semiconductor elements 20 may be metal-oxide-semiconductor field-effect transistors (MOSFETs). In other examples, the semiconductor elements 20 may be switching elements, such as insulated gate bipolar transistors (IGBTs), or diodes. The description of the semiconductor device B10 is directed to an example in which the semiconductor elements 20 are n-channel vertical MOSFETs. Each semiconductor element 20 includes a substrate made of a compound semiconductor. The composition of the compound semiconductor substrate may include a silicon carbide (SiC).

As shown in FIG. 11, the semiconductor device B10 includes, as the semiconductor elements 20, a plurality of first semiconductor elements 21 and a plurality of second semiconductor elements 22. The second semiconductor elements 22 are identical to the first semiconductor elements 21. The first semiconductor elements 21 are mounted on the first obverse surface 121A of the first conductive layer 121. The first semiconductor elements 21 are aligned in the third direction y. The second semiconductor elements 22 are mounted on the second obverse surface 122A of the second conductive layer 122. The second semiconductor elements 22 are aligned in the third direction y.

As shown in FIGS. 11 and 16, each first semiconductor element 21 includes a first electrode 211, a second electrode 212, a first gate electrode 213, and a first sensing electrode 214.

As shown in FIG. 16, the first electrode 211 faces the first obverse surface 121A of the first conductive layer 121. The first electrode 211 passes the electric current corresponding to the power to be converted by the first semiconductor element 21. That is, the first electrode 211 is the drain electrode of the first semiconductor element 21. The first electrode 211 is electrically bonded to the first obverse surface 121A via a conductive bonding layer 29. Hence, the first electrode 211 of each first semiconductor element 21 is electrically connected to the first conductive layer 121. The conductive bonding layer 29 is a layer of sintered metal, which includes silver (Ag), for example. Alternatively, the conductive bonding layer 29 may be a layer of solder.

As shown in FIG. 16, the second electrode 212 is located opposite to the first obverse surface 121A of the first conductive layer 121 in the first direction z. That is, the first electrode 211 and the second electrode 212 are located opposite to each other in the first direction z. The second electrode 212 passes the electric current corresponding to the power converted by the first semiconductor element 21. That is, the second electrode 212 is the source electrode of the first semiconductor element 21.

As shown in FIG. 16, the first gate electrode 213 is located opposite to the first obverse surface 121A of the first conductive layer 121 in the first direction z. That is, the first gate electrode 213 is on the same side as the second electrode 212 in the first direction z. The first gate electrode 213 receives a gate voltage applied to drive the first semiconductor element 21. As shown in FIG. 11, the first gate electrode 213 has a smaller area than the second electrode 212 as viewed in the first direction z.

As shown in FIG. 11, the first sensing electrode 214 is located on the same side as the second electrode 212 and the first gate electrode 213 in the first direction z. The first sensing electrode 214 is located next to the first gate electrode 213 in the third direction y. The first sensing electrode 214 receives the voltage equal to the voltage applied to the second electrode 212. The first sensing electrode 214 has substantially the same area as the first gate electrode 213 as viewed in the first direction z.

As shown in FIGS. 11 and 17, each second semiconductor element 22 includes a third electrode 221, a fourth electrode 222, a second gate electrode 223, and a second sensing electrode 224.

As shown in FIG. 17, the third electrode 221 faces the second obverse surface 122A of the second conductive layer 122. The third electrode 221 passes the electric current corresponding to the power to be converted by the second semiconductor element 22. That is, the third electrode 221 is the drain electrode of the second semiconductor element 22. The third electrode 221 is electrically bonded to the second obverse surface 122A via a conductive bonding layer 29. Hence, the third electrode 221 of each second semiconductor element 22 is electrically connected to the second conductive layer 122.

As shown in FIG. 17, the fourth electrode 222 is located opposite to the second obverse surface 122A of the second conductive layer 122 in the first direction z. That is, the third electrode 221 and the fourth electrode 222 are located opposite to each other in the first direction z. The fourth electrode 222 passes the electric current corresponding to the power converted by the second semiconductor element 22. That is, the fourth electrode 222 is the source electrode of the second semiconductor element 22.

As shown in FIG. 17, the second gate electrode 223 is located opposite to the second obverse surface 122A of the second conductive layer 122 in the first direction z. That is, the second gate electrode 223 is on the same side as the fourth electrode 222 in the first direction z. The second gate electrode 223 receives a gate voltage applied to drive the second semiconductor element 22. As shown in FIG. 11, the second gate electrode 223 has a smaller area than the fourth electrode 222 as viewed in the first direction z.

As shown in FIG. 11, the second sensing electrode 224 is located on the same side as the fourth electrode 222 and the second gate electrode 223 in the first direction z. The second sensing electrode 224 is located next to the second gate electrode 223 in the third direction y. The second sensing electrode 224 receives a voltage equal to the voltage applied to the fourth electrode 222. The second sensing electrode 224 has substantially the same area as the second gate electrode 223 as viewed in the first direction z.

As shown in FIGS. 9 and 15, the first power terminal 13 is located opposite to the second conductive layer 122 in the second direction x with respect to the first conductive layer 121 and is connected to the first conductive layer 121. Hence, the first power terminal 13 is electrically connected to the first electrodes 211 of the first semiconductor elements 21 via the first conductive layer 121. The first power terminal 13 is a P terminal (positive terminal) to which DC power to be converted is supplied. The first power terminal 13 extends from the first conductive layer 121 in the second direction x. The first power terminal 13 includes a covered portion 131 and an exposed portion 132. As shown in FIG. 15, the covered portion 131 is connected to the first conductive layer 121 and is covered with the sealing resin 50. The covered portion 131 is flush with the first obverse surface 121A of the first conductive layer 121. The exposed portion 132 extends from the covered portion 131 in the second direction x and is exposed to the outside from the sealing resin 50.

As shown in FIGS. 9 and 14, the two second power terminals 14 are located on the same side as the first power terminal 13 in the second direction x with respect to the first conductive layer 121 and the second conductive layer 122. The two second power terminals 14 are spaced apart from the first conductive layer 121 and the second conductive layer 122. Each of the two second power terminals 14 is electrically connected to the fourth electrodes 222 of the second semiconductor elements 22. Each of the two second power terminals 14 is an N terminal (negative terminal) to which DC power to be converted is supplied. The second power terminals 14 are spaced apart from each other in the third direction y. The two second power terminals 14 have the first power terminal 13 between them in the third direction y. Each of the second power terminals 14 includes a covered portion 141 and an exposed portion 142. As shown in FIG. 14, the covered portion 141 is spaced apart from the first conductive layer 121 and is covered with the sealing resin 50. The exposed portion 142 extends from the covered portion 141 in the second direction x and is exposed to the outside from the sealing resin 50.

As shown in FIGS. 9 and 14, the two third power terminals 15 are located opposite to the first conductive layer 121 in the second direction x with respect to the second conductive layer 122 and are connected to the second conductive layer 122. Hence, each of the two third power terminals 15 is electrically connected to the third electrodes 221 of the second semiconductor elements 22 via the second conductive layer 122. The two third power terminals 15 output the AC power converted by the semiconductor elements 20. The two third power terminals 15 of the semiconductor device B10 are spaced apart from each other in the third direction y. Each of the two third power terminals 15 includes a covered portion 151 and an exposed portion 152. As shown in FIG. 14, the covered portion 151 is connected to the second conductive layer 122 and is covered with the sealing resin 50. The covered portion 151 is flush with the second obverse surface 122A of the second conductive layer 122. The exposed portion 152 extends from the covered portion 151 in the second direction x and is exposed to the outside from the sealing resin 50.

As shown in FIG. 16, the first wiring 61 is bonded to the first obverse surface 121A of the first conductive layer 121. The first wiring 61 is located opposite to the second semiconductor elements 22 in the second direction x with respect to the first semiconductor elements 21. The first wiring 61 is electrically connected to the first semiconductor elements 21 and the first conductive layer 121. As shown in FIGS. 11 and 16, the first wiring 61 includes a first mounting layer 611, a first metal layer 612, two first gate wiring layers 613, a first sensing wiring layer 614, a first temperature sensing layer 615, and a second sensing wiring layer 616.

shown in FIG. 11, the first mounting layer 611 supports the two first gate wiring layers 613, the first sensing wiring layer 614, the two first temperature sensing layers 615, and the second sensing wiring layer 616. The first mounting layer 611 is an insulator. In one example, the first mounting layer 611 is made of a ceramic material. In other examples, the first mounting layer 611 may be made of an insulating resin sheet.

As shown in FIG. 16, the first metal layer 612 is located on the side closer to the first obverse surface 121A of the first conductive layer 121 in the first direction z with respect to the first mounting layer 611. The first metal layer 612 is bonded to the first mounting layer 611. The composition of the first metal layer 612 may include copper. The first metal layer 612 is bonded to the first obverse surface 121A via a second bonding layer 68. The second bonding layer 68 may be a layer of solder, for example.

As shown in FIGS. 11 and 16, the two first gate wiring layers 613 are located opposite to the first metal layer 612 with respect to the first mounting layer 611. The two first gate wiring layers 613 are bonded to the first mounting layer 611. A plurality of first wires 41 are electrically bonded to one of the two first gate wiring layers 613. The first wires 41 are electrically bonded to the first gate electrodes 213 of the first semiconductor elements 21. Additionally, a plurality of seventh wires 47 are each electrically bonded to the two first gate wiring layers 613. Hence, the two first gate wiring layers 613 are electrically connected to the first gate electrodes 213 of the first semiconductor elements 21.

As shown in FIGS. 11 and 16, the first sensing wiring layer 614 is located opposite to the first metal layer 612 with respect to the first mounting layer 611. The first sensing wiring layer 614 is bonded to the first mounting layer 611. A plurality of second wires 42 are electrically bonded to the first sensing wiring layer 614. The second wires 42 are electrically bonded to the first sensing electrodes 214 of the first semiconductor elements 21. Hence, the first sensing wiring layer 614 is electrically connected to the first sensing electrodes 214 of the first semiconductor elements 21.

As shown in FIG. 11, the two first temperature sensing layers 615 are located opposite to the first metal layer 612 with respect to the first mounting layer 611. The two first temperature sensing layers 615 are bonded to the first mounting layer 611. The two first temperature sensing layers 615 are next to each other in the third direction y.

As shown in FIG. 11, the second sensing wiring layer 616 is located opposite to the first metal layer 612 with respect to the first mounting layer 611. The second sensing wiring layer 616 is bonded to the first mounting layer 611. A third wire 43 is electrically bonded to the second sensing wiring layer 616. The third wire 43 is also electrically bonded to the first obverse surface 121A of the first conductive layer 121. Hence, the second sensing wiring layer 616 is electrically connected to the first conductive layer 121.

As shown in FIG. 17, the second wiring 62 is bonded to the second obverse surface 122A of the second conductive layer 122. The second wiring 62 is located opposite to the first semiconductor elements 21 in the second direction x with respect to the second semiconductor elements 22. The second wiring 62 is electrically connected to second the semiconductor elements 22 and the second conductive layer 122. As shown in FIGS. 11 and 17, the second wiring 62 includes a second mounting layer 621, a second metal layer 622, two second gate wiring layers 623, a third sensing wiring layer 624, two second temperature sensing layers 625, and a fourth sensing wiring layer 626.

As shown in FIG. 11, the second mounting layer 621 supports the two second gate wiring layers 623, the third sensing wiring layer 624, the two second temperature sensing layers 625, and the fourth sensing wiring layer 626. The second mounting layer 621 is an insulator. In one example, the second mounting layer 621 is made of a ceramic material. In other examples, the second mounting layer 621 may be made of an insulating resin sheet.

As shown in FIG. 17, the second metal layer 622 is located on the side closer to the second obverse surface 122A of the second conductive layer 122 in the first direction z with respect to the second mounting layer 621. The second metal layer 622 is bonded to the second mounting layer 621. The composition of the second metal layer 622 may include copper. The second metal layer 622 is bonded to the second obverse surface 122A via a second bonding layer 68.

As shown in FIGS. 11 and 17, the two second gate wiring layers 623 are located opposite to the second metal layer 622 with respect to the second mounting layer 621. The two second gate wiring layers 623 are bonded to the second mounting layer 621. A plurality of fourth wires 44 are electrically bonded to one of the two second gate wiring layers 623. The fourth wires 44 are electrically bonded to the second gate electrodes 223 of the second semiconductor elements 22. Additionally, a plurality of eighth wires 48 are each electrically bonded to the two second gate wiring layers 623. Hence, the two second gate wiring layers 623 are electrically connected to the second gate electrodes 223 of the second semiconductor elements 22.

As shown in FIGS. 11 and 17, the third sensing wiring layer 624 is located opposite to the second metal layer 622 with respect to the second mounting layer 621. The third sensing wiring layer 624 is bonded to the second mounting layer 621. A plurality of fifth wires 45 are electrically bonded to the third sensing wiring layer 624. The respective fifth wires 45 are electrically bonded to the second sensing electrodes 224 of the second semiconductor elements 22. Hence, the third sensing wiring layer 624 is electrically connected to the second sensing electrodes 224 of the second semiconductor elements 22.

As shown in FIG. 11, the two second temperature sensing layers 625 are located opposite to the second metal layer 622 with respect to the second mounting layer 621. The two second temperature sensing layers 625 are bonded to the second mounting layer 621. The two second temperature sensing layers 625 are located next to each other in the third direction y.

As shown in FIG. 11, the fourth sensing wiring layer 626 is located opposite to the second metal layer 622 with respect to the second mounting layer 621. The fourth sensing wiring layer 626 is bonded to the second mounting layer 621.

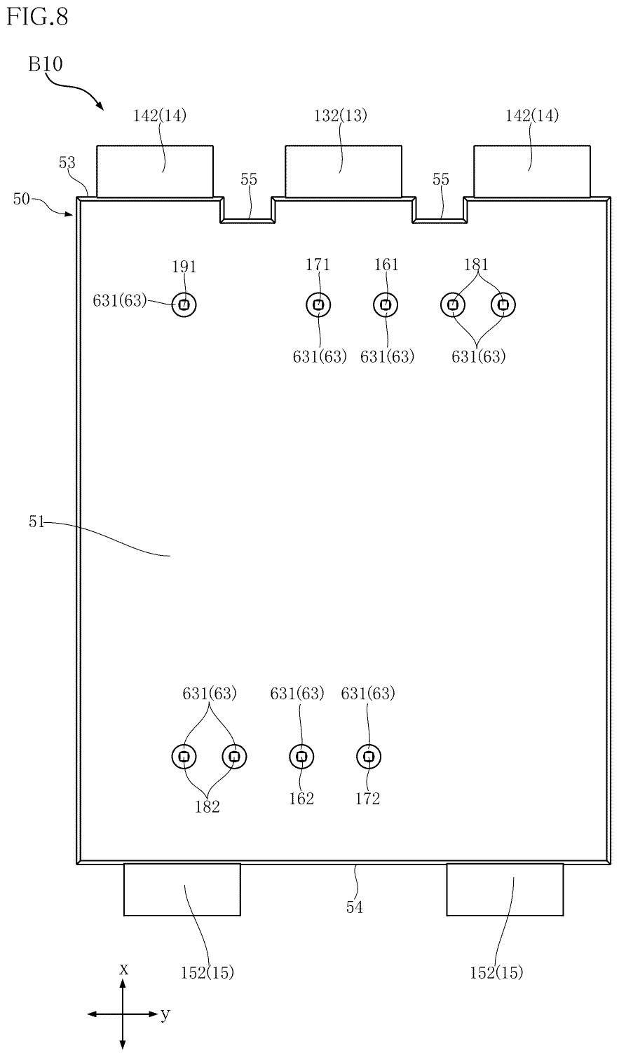

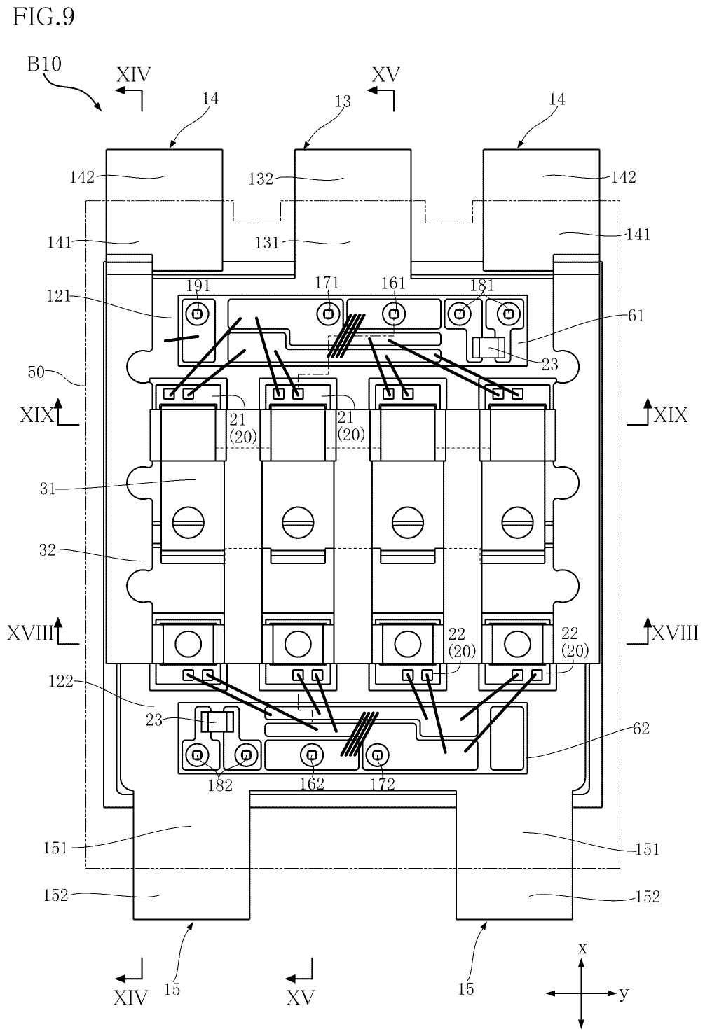

As shown in FIGS. 16 and 17, a plurality of sleeves 63 are provided. Each sleeve 63 is electrically bonded to either the first wiring 61 or the second wiring 62 via a third bonding layer 69. The third bonding layer 69 may be a layer of solder, for example. The sleeves 63 are made of a conductive material, such as metal. Each sleeve 63 is tubular and extends in the first direction z. As shown in FIGS. 8 and 15, each sleeve 63 has an end surface 631 facing the same side as the first obverse surface 121A of the first conductive layer 121 in the first direction z. The end surface 631 is exposed to the outside from a top surface 51 (described later) of the sealing resin 50. The third bonding layer 69 may be a layer of solder, for example.

As shown in FIG. 10, one of the two thermistors 23 is electrically bonded to the two first temperature sensing layers 615 of the first wiring 61. As shown in FIG. 10, the other thermistor 23 is electrically bonded to the two second temperature sensing layers 625 of the second wiring 62. The two thermistors 23 are used as temperature sensors for the semiconductor device B10.

As shown in FIG. 7, each of the signal terminals, namely the first signal terminal 161, the second signal terminal 162, the third signal terminal 171, the fourth signal terminal 172, the two fifth signal terminals 181, the two sixth signal terminals 182, and the seventh signal terminal 191, is a metal pin extending in the first direction z. These signal terminals protrude from the top surface 51 (described later) of the sealing resin 50. Each signal terminal is press-fitted into a sleeve 63. Thus, the signal terminals are supported by the respective sleeves 63 and are each electrically connected to either the first wiring 61 or the second wiring 62.

As shown in FIGS. 11 and 16, the first signal terminal 161 is fitted into one of the sleeves 63 that is electrically bonded to one of the two first gate wiring layers 613 of the first wiring 61. Hence, the first signal terminal 161 is electrically connected to the first gate electrodes 213 of the first semiconductor elements 21 via the two first gate wiring layers 613. The first signal terminal 161 receives a gate voltage applied for driving the first semiconductor elements 21.

As shown in FIGS. 11 and 17, the second signal terminal 162 is fitted into one of the sleeves 63 that is electrically bonded to one of the two second gate wiring layers 623 of the second wiring 62. Hence, the second signal terminal 162 is electrically connected to the second gate electrodes 223 of the second semiconductor elements 22 via the two second gate wiring layers 623. The second signal terminal 162 receives a gate voltage applied for driving the second semiconductor elements 22.

As shown in FIG. 8, the third signal terminal 171 is located next to the first signal terminal 161 in the third direction y. As shown in FIG. 11, the third signal terminal 171 is fitted into one of the sleeves 63 that is electrically bonded to the first sensing wiring layer 614 of the first wiring 61. Hence, the third signal terminal 171 is electrically connected to the first sensing electrodes 214 of the first semiconductor elements 21 via the first sensing wiring layer 614. The third signal terminal 171 receives a voltage equal to the voltage applied to the first sensing electrodes 214 of the first semiconductor elements 21.

As shown in FIG. 8, the fourth signal terminal 172 is located next to the second signal terminal 162 in the third direction y. As shown in FIG. 11, the fourth signal terminal 172 is fitted into one of the sleeves 63 that is electrically bonded to the third sensing wiring layer 624 of the second wiring 62. Hence, the fourth signal terminal is 172 electrically connected to the second sensing electrodes 224 of the second semiconductor element 22 via the third sensing wiring layer 624. The fourth signal terminal 172 receives a voltage equal to the voltage applied to the second sensing electrodes 224 of the second semiconductor elements 22.

As shown in FIG. 8, the two fifth signal terminals 181 are located opposite to the third signal terminal 171 in the third direction y with respect to the first signal terminal The two fifth signal terminals 181 are next to each 161. other in the third direction y. As shown in FIG. 11, the two fifth signal terminals 181 are fitted into two sleeves 63 that are electrically bonded to the two first temperature sensing layers 615 of the first wiring 61. Hence, the two fifth signal terminals 181 are electrically connected to one of the two thermistors 23 that is electrically bonded to the two first temperature sensing layers 615.

As shown in FIG. 8, the two sixth signal terminals 182 are located opposite to the fourth signal terminal 172 in the third direction y with respect to the second signal terminal 162. The two sixth signal terminals 182 are next to each other in the third direction y. As shown in FIG. 11, the two sixth signal terminals 182 are fitted into two sleeves 63 that are electrically bonded to the two second temperature sensing layers 625 of the second wiring 62. Hence, the two sixth signal terminals 182 are electrically connected to one of the two thermistors 23 that is electrically bonded to the two second temperature sensing layers 625.

As shown in FIG. 8, the seventh signal terminal 191 is located opposite to the first signal terminal 161 in the third direction y with respect to the third signal terminal 171. As shown in FIG. 11, the seventh signal terminal 191 is fitted into one of the sleeves 63 that is electrically bonded to the second sensing wiring layer 616 of the first wiring 61. Hence, the seventh signal terminal 191 is electrically connected to the first conductive layer 121 via the second sensing wiring layer 616. The seventh signal terminal 191 receives a voltage corresponding to the DC power inputted to the first power terminal 13 and the two second power terminals 14.

As shown in FIGS. 11 and 16, the first conductive member 31 is electrically bonded to the second electrodes 212 of the first semiconductor elements 21 and the second obverse surface 122A of the second conductive layer 122. Hence, the second electrodes 212 of the first semiconductor elements 21 are electrically connected to the second conductive layer 122. The composition of the first conductive member 31 may include copper. The first conductive member 31 is a metal clip. As shown in FIG. 11, the first conductive member 31 includes a body 311, a plurality of first bonding portions 312, plurality of first connecting portions 313, a second bonding portion 314, and a second connecting portion 315.

The body 311 forms a major part of the first conductive member 31. As shown in FIG. 11, the body 311 extends in the third direction y. As shown in FIG. 15, the body 311 extends across the gap between the first conductive layer 121 and the second conductive layer 122.

As shown in FIG. 16, the first bonding portions 312 are electrically bonded to the second electrodes 212 of the first semiconductor elements 21. The first bonding portions 312 face the second electrodes 212 of the first semiconductor elements 21.

As shown in FIG. 11, the first connecting portions 313 connect the body 311 and the first bonding portions 312. The first connecting portions 313 are spaced apart from each other in the third direction y. As shown in FIG. 15, as viewed in the third direction y, each first connecting portion 313 is inclined away from the first obverse surface 121A of the first conductive layer 121 as it approaches the body 311 from the first bonding portion 312.

As shown in FIGS. 11 and 15, the second bonding portion 314 is electrically bonded to the second obverse surface 122A of the second conductive layer 122. The second bonding portion 314 faces the second obverse surface 122A. The second bonding portion 314 extends in the third direction y. The second bonding portion 314 has a dimension in the third direction y that is equal to the dimension of the body 311 in the third direction y.

As shown in FIGS. 11 and 15, the second connecting portion 315 connects the body 311 and the second bonding portion 314. As viewed in the third direction y, the second connecting portion 315 is inclined away from the second obverse surface 122A of the second conductive layer 122 as it approaches the body 311 from the second bonding portion 314. The second connecting portion 315 has a dimension in the third direction y that is equal to the dimension of the body 311 in the third direction y.

As shown in FIGS. 15, 16 and 19, a conductive bonding layer 29 is present between the second electrode 212 of each first semiconductor element 21 and a first bonding portion This conductive bonding layer 29 electrically bonds the 312. first bonding portion 312 and the second electrode 212 of the first semiconductor element 21. As shown in FIG. 15, a conductive bonding layer 29 is present also between the second obverse surface 122A of the second conductive layer 122 and the second bonding portion 314. This conductive bonding layer 29 electrically bonds the second obverse surface 122A and the second bonding portion 314.

As shown in FIGS. 10 and 17, the second conductive member 32 is electrically bonded to the second electrodes 212 of the second semiconductor elements 22 and the covered portion 141 of each of the two second power terminals 14. Hence, the second electrodes 212 of the second semiconductor elements 22 are electrically connected to the two second power terminals 14. The composition of the second conductive member 32 may include copper. The second conductive member 32 is a metal clip. As shown in FIG. 10, the second conductive member 32 includes two bodies 321, a plurality of third bonding portions 322, a plurality of third connecting portions 323, two fourth bonding portions 324, two fourth connecting portions 325, a plurality of intermediate portions 326, and a plurality of cross beams 327.

As shown in FIG. 10, the two bodies 321 are spaced apart from each other in the third direction y. Each body 321 extends in the second direction x. As shown in FIG. 14, the two bodies 321 are parallel to the first obverse surface 121A and the second obverse surface 122A of the first conductive layer 121 and the second conductive layer 122, respectively. The two bodies 321 are located farther from the first obverse surface 121A and the second obverse surface 122A than the body 311 of the first conductive member 31.

As shown in FIG. 10, the intermediate portions 326 are spaced apart from each other in the third direction y and are located between the two bodies 321 in the third direction y. Each intermediate portion 326 extends in the second direction x. Each intermediate portion 326 has a smaller dimension in the second direction x than each body 321 in the second direction x.

As shown in FIG. 17, the third bonding portions 322 are electrically bonded to the fourth electrodes 222 of the second semiconductor elements 22. The third bonding portions 322 face the fourth electrodes 222 of the second semiconductor elements 22.

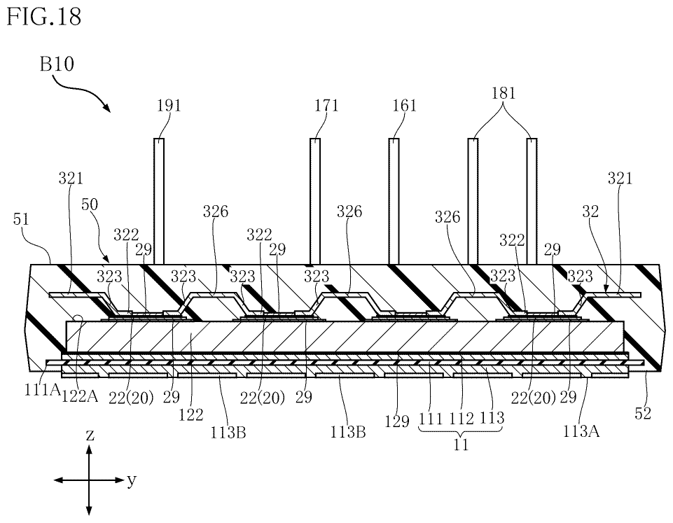

As shown in FIGS. 10 and 18, a third connecting portion 323 is connected to each end of each third bonding portion 322 in the third direction y. In addition, a third connecting portion 323 is connected to each of the bodies 321 and the intermediate portions 326. As viewed in the second direction x, each third connecting portion 323 is inclined away from the second obverse surface 122A of the second conductive layer 122 as it approaches the corresponding body 321 or intermediate portion 326 from the corresponding third bonding portion 322.

As shown in FIGS. 10 and 14, the two fourth bonding portions 324 are bonded to the covered portions 141 of the two second power terminals 14. Each fourth bonding portion 324 faces the covered portion 141 of the corresponding second power terminal 14.

As shown in FIGS. 10 and 14, the two fourth connecting portions 325 connect the two bodies 321 and the two fourth bonding portions 324 respectively. As viewed in the third direction y, each fourth connecting portion 325 is inclined away from the first obverse surface 121A of the first conductive layer 121 as it approaches the body 321 from the fourth bonding portion 324.

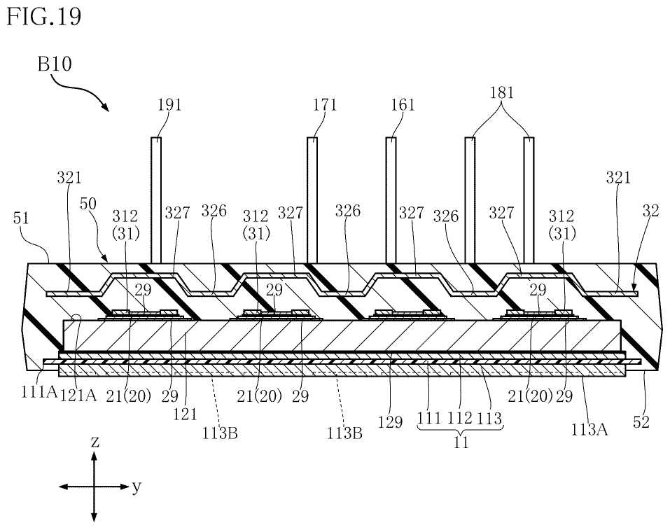

As shown in FIGS. 10 and 19, the cross beams 327 are aligned in the third direction y. As viewed in the first direction z, each cross beam 327 includes a region that overlaps with a first bonding portion 312 of the first conductive member 31. Each cross beam 327 that is located between other cross beams 327 in the third direction y is connected at each end in the third direction y to an intermediate portion 326. Each of the two other cross beams 327 is connected to a body 321 at one end in the third direction y and to an intermediate portion 326 at the other end. As viewed in the second direction x, each cross beam 327 protrudes in the first direction z toward the same side as that the first obverse surface 121A of the first conductive layer 121 faces.

As shown in FIGS. 15, 17 and 18, a conductive bonding layer 29 is present between the fourth electrode 222 of each second semiconductor element 22 and a third bonding portion 322. This conductive bonding layer 29 electrically bonds the third bonding portion 322 and the fourth electrode 222 of the second semiconductor element 22. As shown in FIG. 14, a conductive bonding layer 29 is also present between the covered portion 141 of each second power terminal 14 and a fourth bonding portion 324. This conductive bonding layer 29 electrically bonds the covered portion 141 of the second power terminal 14 and the fourth bonding portion 324.

As shown in FIGS. 14, 15, 18 and 19, the sealing resin 50 covers the first conductive layer 121, the second conductive layer 122, the semiconductor elements 20, the first conductive member 31, and the second conductive member 32. The sealing resin 50 also covers a portion of each of the substrate 11, the first power terminal 13, the third power terminals 15, and the second power terminal 14. The sealing resin 50 is electrically insulating. The sealing resin 50 is made of a material containing a black epoxy resin, for example. As shown in FIGS. 8 and 12 to 15, the sealing resin 50 has a top surface 51, a bottom surface 52, a first side surface 53, a second side surface 54, and two recessed portions 55.

As shown in FIGS. 14 and 15, the top surface 51 faces the same side as the first obverse surface 121A of the first conductive layer 121 in the first direction z. As shown in FIGS. 14 and 15, the bottom surface 52 faces away from the top surface 51 in the first direction z. As shown in FIG. 13, the heat dissipating layer 113 of the substrate 11 is exposed from the bottom surface 52.

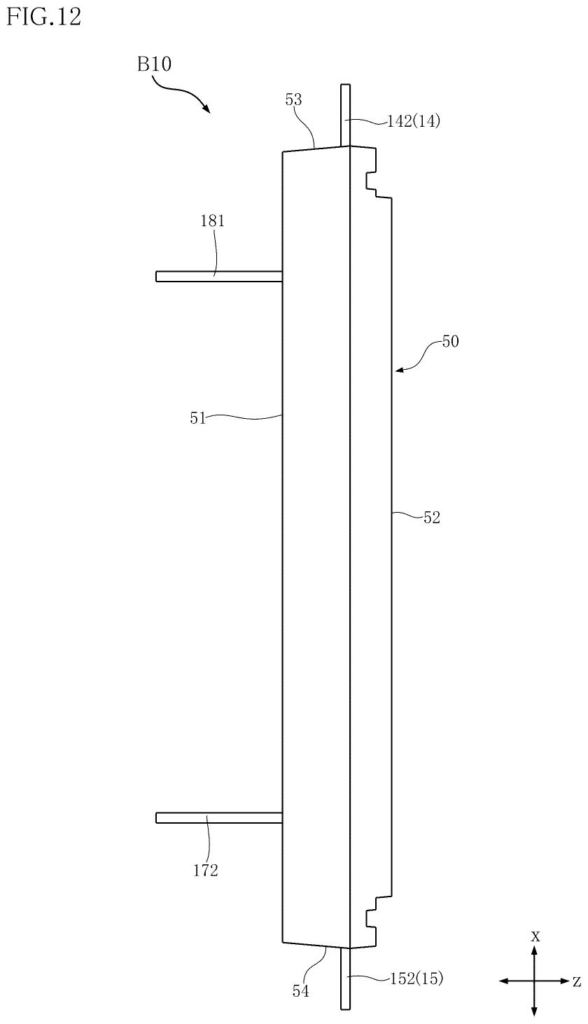

As shown in FIGS. 8 and 12, the first side surface 53 and the second side surface 54 are spaced apart from each other in the second direction x. The first side surface 53 and the second side surface 54 face away from each other in the second direction x. The exposed portion 132 of the first power terminal 13 and the exposed portions 142 of the second power terminals 14 protrude to the outside from the first side surface 53. The exposed portions 152 of the third power terminals 15 protrude to the outside from the second side surface 54.

As shown in FIGS. 8 and 13, the two recessed portions 55 are recessed from the first side surface 53 in the second direction x. Each recessed portion 55 extends in the first direction z from the top surface 51 to the bottom surface 52. The recessed portions 55 are located on opposite sides of the first power terminal 13 in the third direction y.

### Semiconductor Module C10

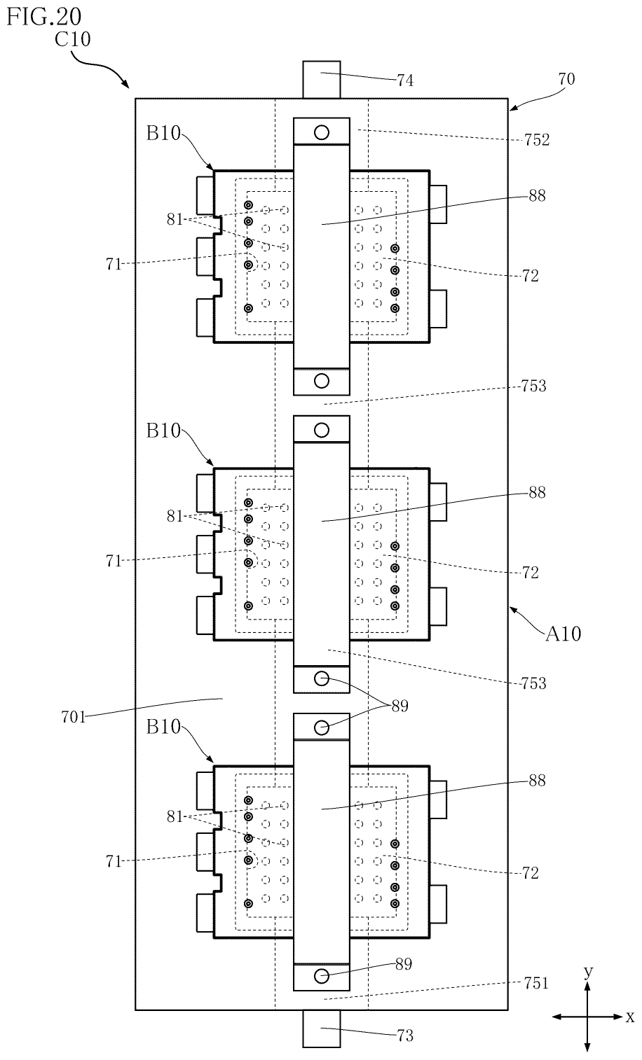

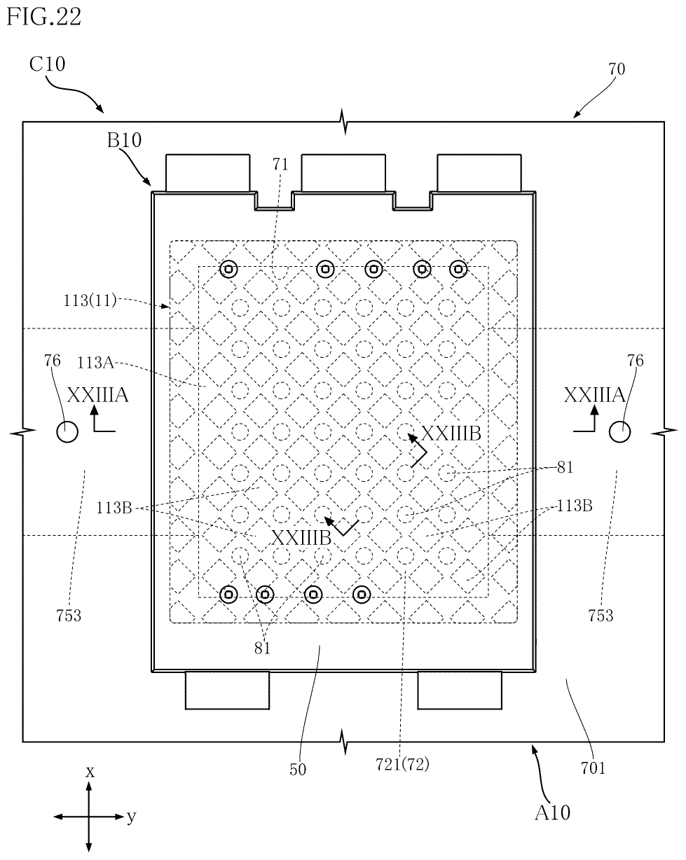

Next, with reference to FIGS. 20 to 23B, the semiconductor module C10 will be described. For the convenience of illustration, FIG. 22 omits the mounting components 88.

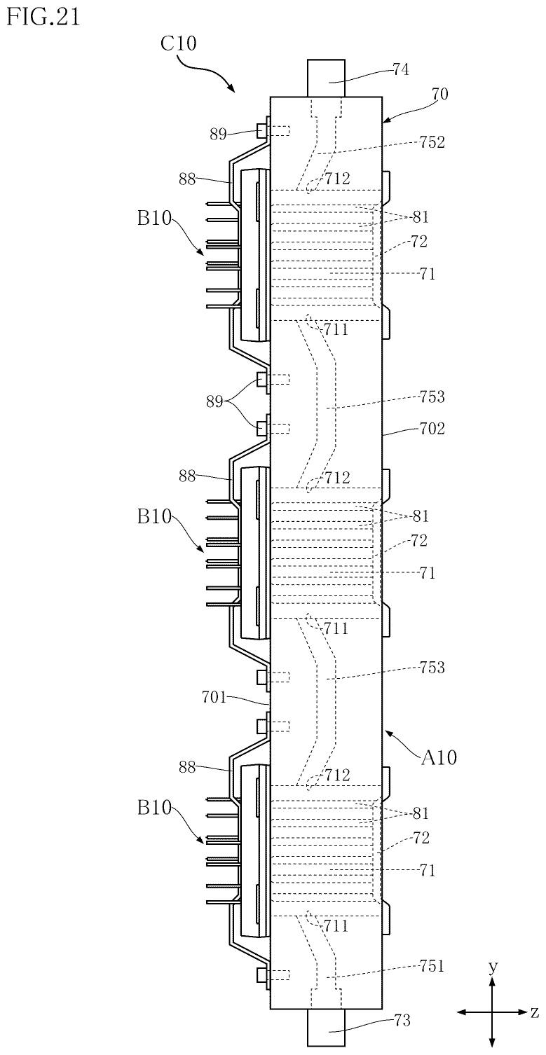

As shown in FIGS. 20 and 21, the semiconductor devices B10 are attached to the housing 70 of the cooling unit A10. Specifically, the semiconductor devices B10 are mounted on the obverse surface 701 of the housing 70, such that each semiconductor device B10 covers a recess 71. Hence, the semiconductor devices B10 are aligned in the third direction y.

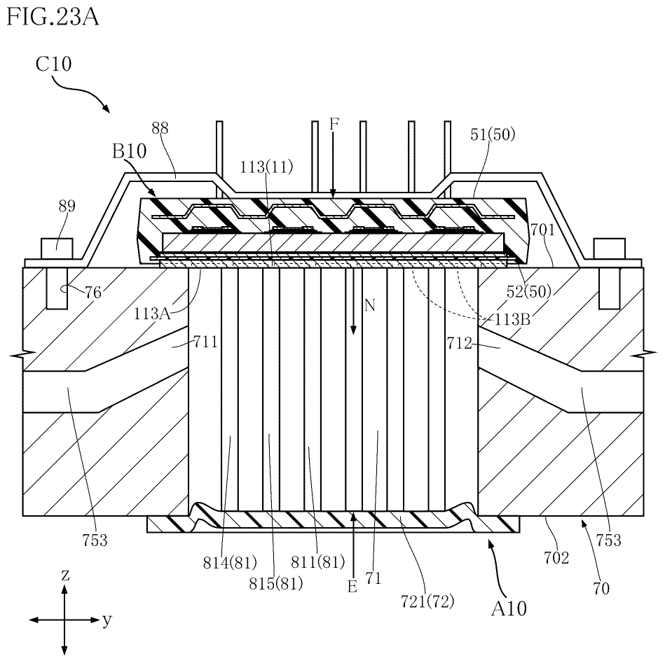

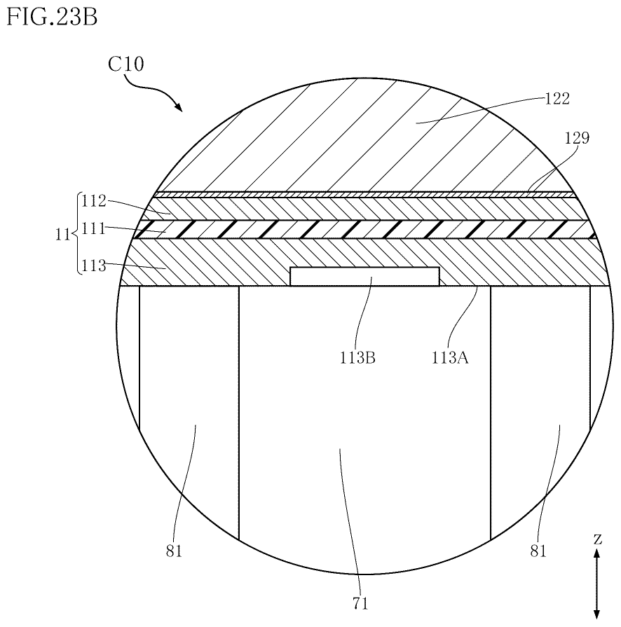

As shown in FIG. 22 and FIG. 23A, each semiconductor device B10 covers a recess 71 of the housing 70 with the heat dissipating layer 113 of the substrate 11. The base surface 113A of the heat dissipating layer 113 faces the recess 71. The depressions 113B in the heat dissipating layer 113 overlap with the recess 71 as viewed in first direction z. As viewed in the first direction z, the peripheral edge of the heat dissipating layer 113 surrounds the recess 71. The base surface 113A is in contact with the obverse surface 701 of the housing 70. In addition, the bottom surface 52 of the sealing resin 50 of each semiconductor device B10 is spaced apart from the obverse surface 701 of the housing 70.

As shown in FIG. 22, the base surface 113A of the heat dissipating layer 113 overlaps with the heat dissipating members 81 of the cooling unit A10 as viewed in the first direction z. Hence, as viewed in first direction z, each depression 113B in the heat dissipating layer 113 is spaced apart from the heat dissipating members 81. As shown in FIG. 23B, each heat dissipating member 81 is in contact with the base surface 113A.

As shown in FIGS. 20 and 21, the mounting components 88 secure the semiconductor devices B10 to the housing 70 of the cooling unit A10. The mounting components 88 are made of a material containing metal. Each mounting component 88 is in contact with and spans across the top surface 51 of the sealing resin 50 of a semiconductor device B10. The mounting components 88 may be leaf springs. Each mounting component 88 is located between the first signal terminal 161 and the second signal terminal 162 of the semiconductor device B10 in the second direction x. Each mounting component 88 is secured to the housing 70 by inserting two fastening members 89 into two mounting holes 76 located near the opposite ends of the semiconductor device B10 in the third direction y. The fastening members 89 may be bolts, for example.

As shown in FIG. 23A, in the semiconductor module C10, a load F applied by each mounting component 88 in the first direction z toward the bottom portion 72 of the housing 70 acts on the corresponding semiconductor device B10. As a result, a load N in the first direction z toward the same side as the load F is applied to the heat dissipating members 81 from the base surface 113A of the heat dissipating layer 113. In response, the elastic portion 721 of the bottom portion 72 exerts an elastic force E opposing the load N in the first direction z on the heat dissipating members 81.

Next, advantages of the semiconductor module C10 will be described.

The semiconductor module C10 includes a cooling unit A10 and a semiconductor device B10. The cooling unit A10 includes: a housing 70 including a recess 71 and a bottom portion 72; and a heat dissipating member 81 attached to the bottom portion 72 and at least partly accommodated in the recess 71. The recess 71 includes an inlet 711 and an outlet 712. The semiconductor device B10 includes a substrate 11 that includes a heat dissipating layer 113 covering the recess 71. The heat dissipating layer 113 includes a base surface 113A facing the recess 71 and a depression 113B recessed from the base surface 113A. The depression 113B overlaps with the recess 71 as viewed in first direction z. This configuration promotes the flow of coolant circulating in the semiconductor module C10 into the recess 71. This ensures that coolant that flows around the heat dissipating member 81 comes into contact with both the base surface 113A and the depression 113B of the heat dissipating layer 113. This means that a greater surface area of the heat dissipating layer 113 comes into contact with coolant. This configuration of the semiconductor module C10 can therefore achieve more efficient cooling of the semiconductor device B10 that is attached to the cooling unit A10.

The heat dissipating member 81 is in contact with the base surface 113A of the heat dissipating layer 113. The semiconductor module C10 additionally includes a mounting component 88 that secures the semiconductor device B10 to the cooling unit A10. The bottom portion 72 includes an elastic portion 721 that is elastically deformable. In the semiconductor module C10, a load F in the first direction z toward the bottom portion 72 is applied from the mounting component 88 to the semiconductor device B10. In response, an elastic force E opposing the load F in the first direction Z is applied from the elastic portion 721 to the heat dissipating member 81. With this configuration, the heat dissipating member 81 is pressed against the base surface 113A. This helps the conduction of heat from the semiconductor device B10 to the heat dissipating member 81. In addition, there is no gap formed at either end of the heat dissipating member 81 in the first direction z. This ensures that the coolant can uniformly contact the heat dissipating member 81 along its entire length in the first direction z. This also enhances the efficiency of cooling the semiconductor device B10.

In the cooling unit A10, the thermal conductivity of the heat dissipating member 81 is higher than that of the housing 70. This configuration enhances the conduction of heat from the semiconductor device B10 to the heat dissipating member 81 and also enhances the cooling of the heat dissipating member 81 by coolant.

The heat dissipating member 81 includes a first member 811 and a second member 812 that are spaced apart from each other in the second direction x. The first member 811 and the second member 812 are surrounded by the obverse surface 701 of the housing 70 as viewed in the first direction z. This configuration of the semiconductor module C10 ensures that the heat dissipating member 81 is not caught between the obverse surface 701 and the semiconductor device B10. This configuration also allows the heat dissipating member 81 to move in the first direction z without interfering with the housing 70 when the load N acts on the heat dissipating member 81 and the responsive elastic force E from the elastic portion 721 acts on the heat dissipating member 81 as shown in FIG. 23A.

Each of the first member 811 and the second member 812 includes a portion protruding outward from the obverse surface 701 of the housing 70. This configuration serves to increase the elastic force E that is shown in FIG. 23A. When the elastic portion 721 of the bottom portion 72 is in the natural state, the amount of each of the first and second members 811 and 812 protruding outward from the obverse surface 701 of the housing 70 is greater for the first member 811 than for the second member 812. With this configuration, the elastic portion 721, which bulges toward the heat dissipating member 81 in the first direction z in the state shown in FIGS. 5 and 6, is elastically deformed to be substantially flat as shown in FIG. 23A. As a result, the first and second members 811 and 812 are pressed against the base surface 113A to ensure close contact.

The elastic portion 721 of the bottom portion 72 is integrally formed as one piece. The first member 811 and the second member 812 are supported on the elastic portion 721. This configuration can prevent the loss of the elastic force E acting on the first member 811 and the second member 812.

The housing 70 of the cooling unit A10 has the inlet 711 and the outlet 712 located opposite to each other in the third direction y with respect to the recess 71. As viewed in the third direction y, the first member 811 overlaps with the inlet 711 and the outlet 712. This configuration helps to prevent uneven heat distribution in the coolant around the first member 811.

The distance d1 between the inlet 711 and the obverse surface 701 of the housing 70 in the first direction z is smaller than the distance d2 between the inlet 711 and the reverse surface 702 of the housing 70 in the first direction z. In addition, the distance d3 between the outlet 712 and the obverse surface 701 in the first direction z is smaller than the distance d4 between the outlet 712 and the reverse surface 702 in the first direction z. This configuration achieves a velocity distribution of the coolant in first direction z such that the velocity is higher near the obverse surface 701 than near the reverse surface 702. This means that coolant in contact with the heat dissipating layer 113 of the semiconductor device B10 flows faster, so that the efficiency of cooling the semiconductor device B10 can be further improved.

### Second Embodiment

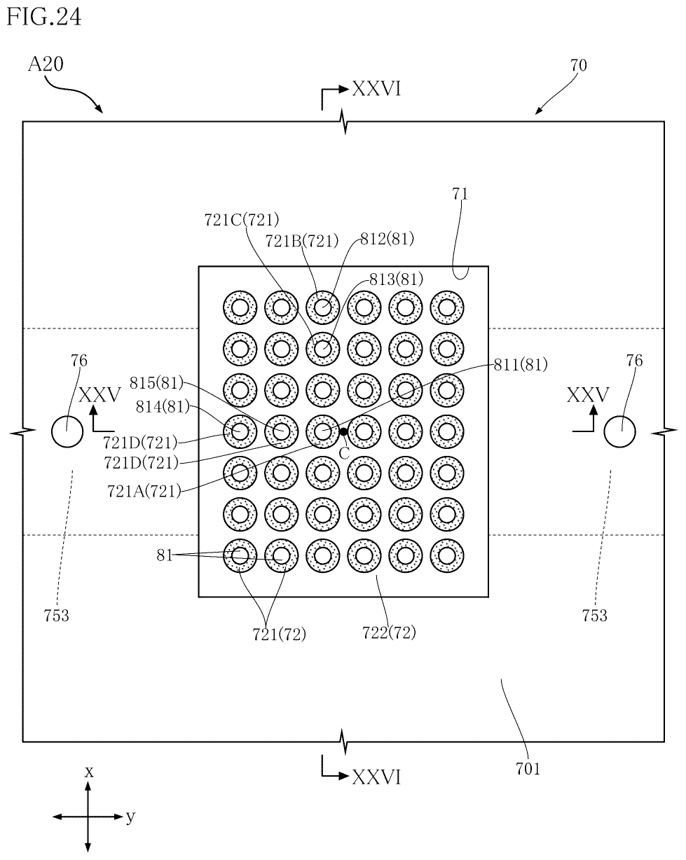

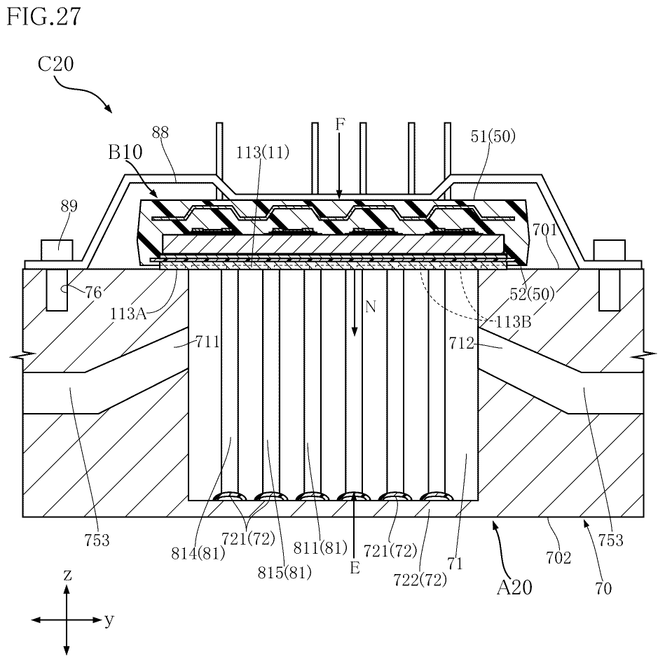

With reference to FIGS. 24 to 27, a semiconductor module C20 according to a second embodiment of the present disclosure will be described. In these figures, elements that are identical or similar to those of the cooling unit A10, the semiconductor devices B10, and the semiconductor module C10 described above are indicated by the same reference numerals. In addition, the description of such elements is not repeated to avoid redundancy. I Note that the section shown in FIG. 27 corresponds in position to the section of the semiconductor module C10 shown in FIG. 23A.

The semiconductor module C20 includes a cooling unit A20, a plurality of semiconductor devices B10, and a plurality of mounting components 88. The cooling unit A20 differs from the cooling unit A10 of the semiconductor module C10 in the configuration of the bottom portions 72 of the housing 70.

As shown in FIGS. 24 to 26, the elastic portion 721 of each bottom portion 72 includes a plurality of separate pieces. These pieces are aligned in the second direction x and the third direction y, forming a grid. The bottom portion 72 includes a base 722. The base 722 is integrally formed with the other portions of the housing 70. The base 722 extends flat in the first direction z. The plurality of pieces forming the elastic portions 721 are bonded to the base 722.

As shown in FIGS. 24 to 26, the plurality of pieces forming the elastic portions 721 include a first elastic portion 721A, a second elastic portion 721B, a third elastic portion 721C, a fourth elastic portion 721D, and a a fifth elastic portion 721E. Of the heat dissipating members 81, the first member 811 is supported on the first elastic portion 721A. The second member 812 is supported on the second elastic portion 721B. The third member 813 is supported on the third elastic portion 721C. The fourth member 814 is supported on the fourth elastic portion 721D. The fifth member 815 is supported on the fifth elastic portion 721E. When the elastic portion 721 is in the natural state, the protruding amounts L1, L2, L3, L4, and L5 respectively of the first, second, third, fourth, and fifth members 811, 812, 813, 814, and 815 from the obverse surface 701 of the housing 70 are all equal.

As shown in FIG. 27, in the semiconductor module C20, a load F applied by each mounting component 88 in the first direction z toward the bottom portion 72 of the housing 70 acts on the corresponding semiconductor device B10. As a result, a load N in the first direction z toward the same side as the load F is applied to the heat dissipating members 81 from the base surface 113A of the heat dissipating layer 113. In response, the elastic portions 721 forming the bottom portion 72 exerts an elastic force E opposing the load N in the first direction z on the respective heat dissipating members 81.

Next, advantages of the semiconductor module C20 will be described.

The semiconductor module C20 includes a cooling unit A20 and a semiconductor device B10. The cooling unit A20 includes: a housing 70 including a recess 71 and a bottom portion 72; and a heat dissipating member 81 attached to the bottom portion 72 and at least partly accommodated in the recess 71. The recess 71 includes an inlet 711 and an outlet 712. The semiconductor device B10 includes a substrate 11 that includes a heat dissipating layer 113 covering the recess 71. The heat dissipating layer 113 includes a base surface 113A facing the recess 71 and a depression 113B recessed from the base surface 113A. The depression 113B overlaps with the recess 71 as viewed in first direction z. This configuration of the semiconductor module C20 can therefore achieve more efficient cooling of the semiconductor device B10 that is attached to the cooling unit A20. The semiconductor module C20 has a configuration in common with the semiconductor module C10, thereby achieving the same effect as the semiconductor module C10.

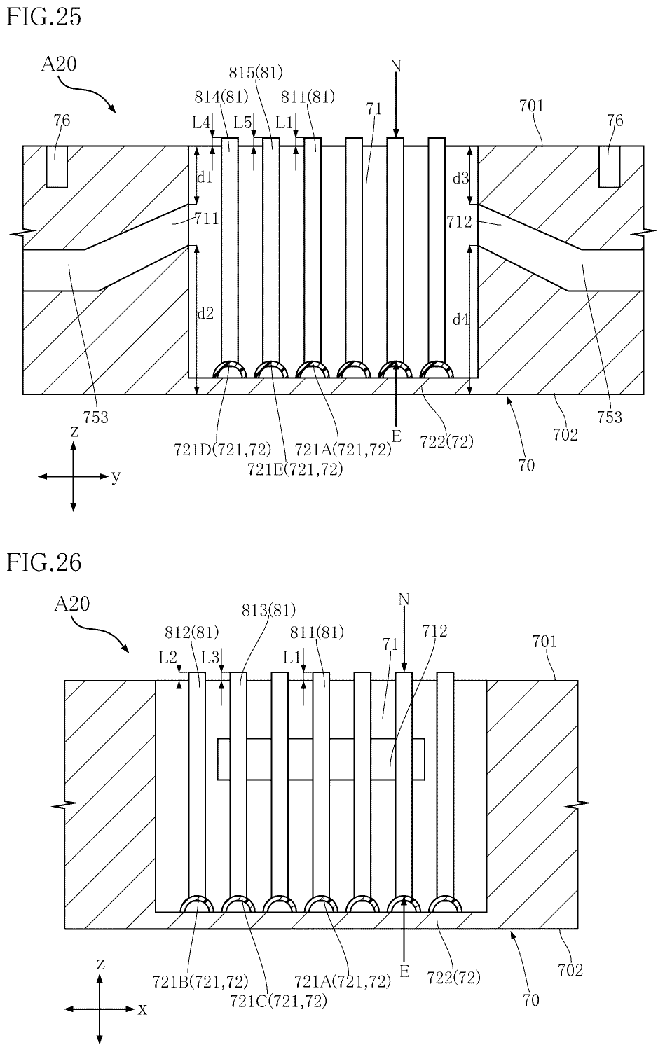

In the cooling unit A20, the bottom portion 72 has an elastic portion 721 that includes a first elastic portion 721A and a second elastic portion 721B spaced apart from each other. Of the heat dissipating members 81, the first member 811 is supported on the first elastic portion 721A, and the second member 812 is supported on the second elastic portion 721B. With this configuration, even if the base 722 of the bottom portion 72 is flat in the first direction z as shown in FIGS. 25 and 26, the elastic force E is generated by the first elastic portion 721A and the second elastic portion 721B.

### Third Embodiment

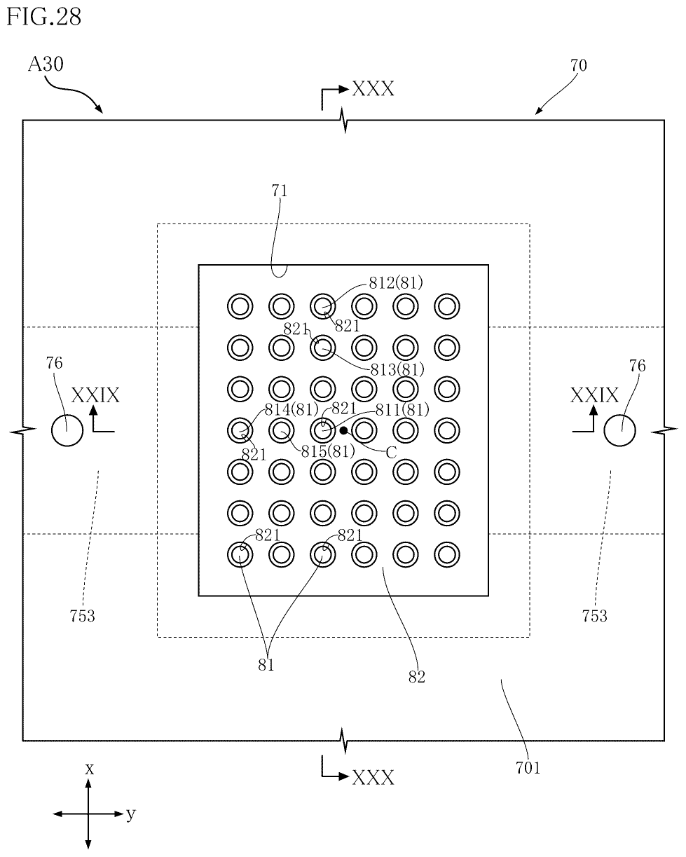

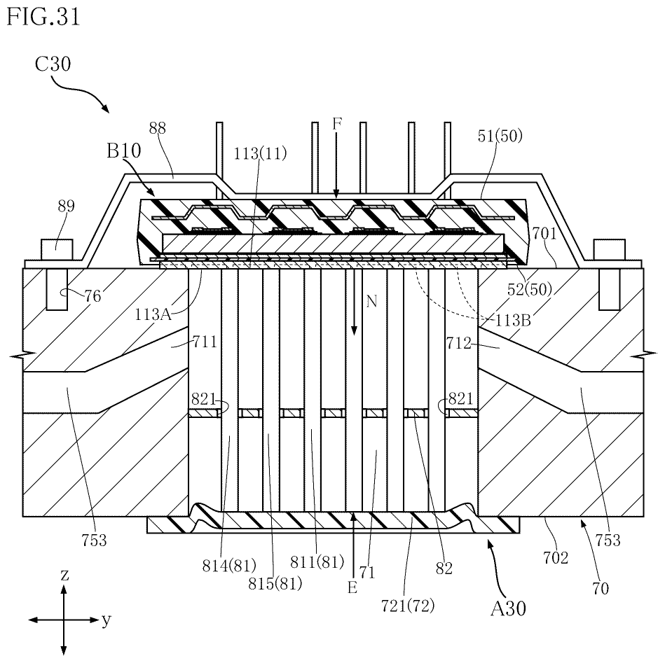

With reference to FIGS. 28 to 31, a semiconductor module C30 according to a third embodiment of the present disclosure will be described. In these figures, elements that are identical or similar to those of the cooling unit A10, the semiconductor devices B10, and the semiconductor module C10 described above are indicated by the same reference numerals. In addition, the description of such elements is not repeated to avoid redundancy. Note that the section shown in FIG. 31 corresponds in position to the section of the semiconductor module C10 shown in FIG. 23A.

The semiconductor module C30 includes a cooling unit A30, a plurality of semiconductor devices B10, and a plurality of mounting components 88. Different from the cooling unit A10 of the semiconductor module C10, the cooling unit A30 additionally includes a guide member 82.

As shown in FIGS. 28 to 30, the guide member 82 is accommodated in a recess 71 and is bonded to the housing 70. The guide member 82 is formed with a plurality of holes 821 penetrating in the first direction z. The first to fifth members 811 to 815 of the heat dissipating members 81 are individually inserted through the plurality of holes 821.

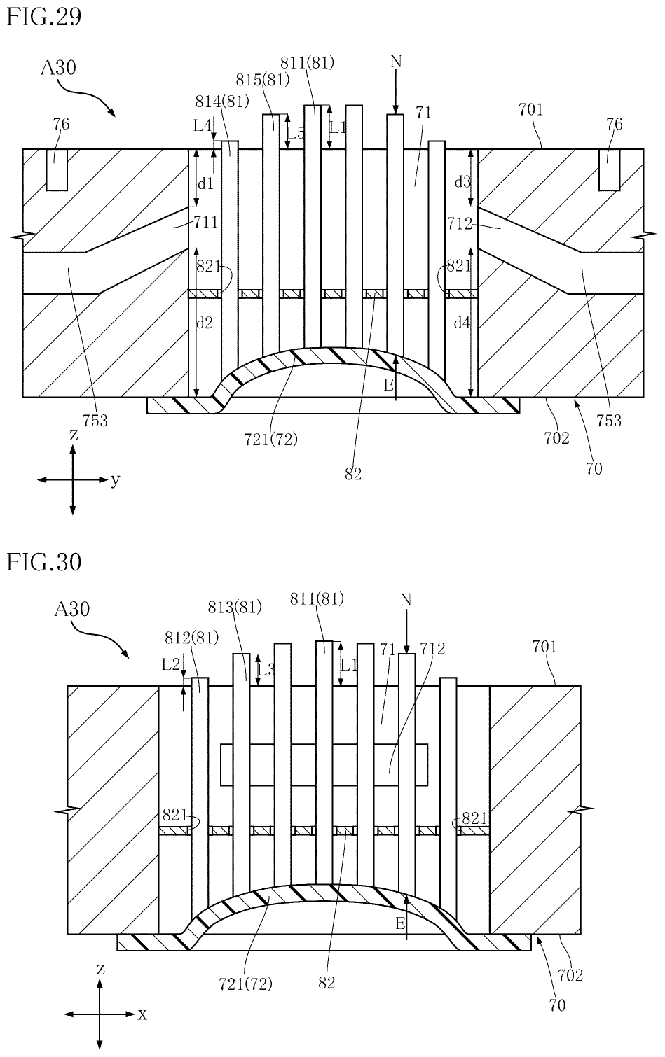

As shown in FIG. 29, the guide member 82 is located between the reverse surface 702 of the housing 70 and each of the inlet 711 and the outlet 712 in the first direction z.

As shown in FIG. 31, in the semiconductor module C30, a load F applied by each mounting component 88 in the first direction z toward the bottom portion 72 of the housing 70 acts on the corresponding semiconductor device B10. As a result, a load N in the first direction z toward the same side as the load F is applied to the heat dissipating members 81 from the base surface 113A of the heat dissipating layer 113. In response, the elastic portion 721 of the bottom portion 72 exerts an elastic force E opposing the load N in the first direction z on the heat dissipating members 81.

Next, advantages of the semiconductor module C30 will be described.

The semiconductor module C30 includes a cooling unit A30 and a semiconductor device B10. The cooling unit A30 includes: a housing 70 including a recess 71 and a bottom portion 72; and a heat dissipating member 81 attached to the bottom portion 72 and at least partly accommodated in the recess 71. The recess 71 includes an inlet 711 and an outlet 712. The semiconductor device B10 includes a substrate 11 that includes a heat dissipating layer 113 covering the recess 71. The heat dissipating layer 113 includes a base surface 113A facing the recess 71 and a depression 113B recessed from the base surface 113A. The depression 113B overlaps with the recess 71 as viewed in first direction z. This configuration of the semiconductor module C30 can therefore achieve more efficient cooling of the semiconductor device B10 that is attached to the cooling unit A30. The semiconductor module C30 has a configuration in common with the semiconductor module C10, thereby achieving the same effect as the semiconductor module C10.

The cooling unit A30 further includes a guide member 82 bonded to the housing 70. The guide member 82 is accommodated in the recess 71. The guide member 82 is formed with a plurality of holes 821 penetrating in the first direction z. The first and second members 811 and 812 of the heat dissipating members 81 are individually inserted through the plurality of holes 821. The guide member 82 restricts the movement of the first member 811 and the second member 812 in a direction orthogonal to the first direction z. This means that deflection of the first member 811 and the second member 812 is restricted in the direction orthogonal to the first direction z, allowing the load N to more effectively act on the elastic portion 721 of the bottom portion 72 and cause elastically deformation.

The guide member 82 is located between the reverse surface 702 of the housing 70 and each of the inlet 711 and the outlet 712 in the first direction z. This configuration prevents the guide member 82 from obstructing the flow of coolant in the recess 71 from the inlet 711 to the outlet 712.

### Fourth Embodiment

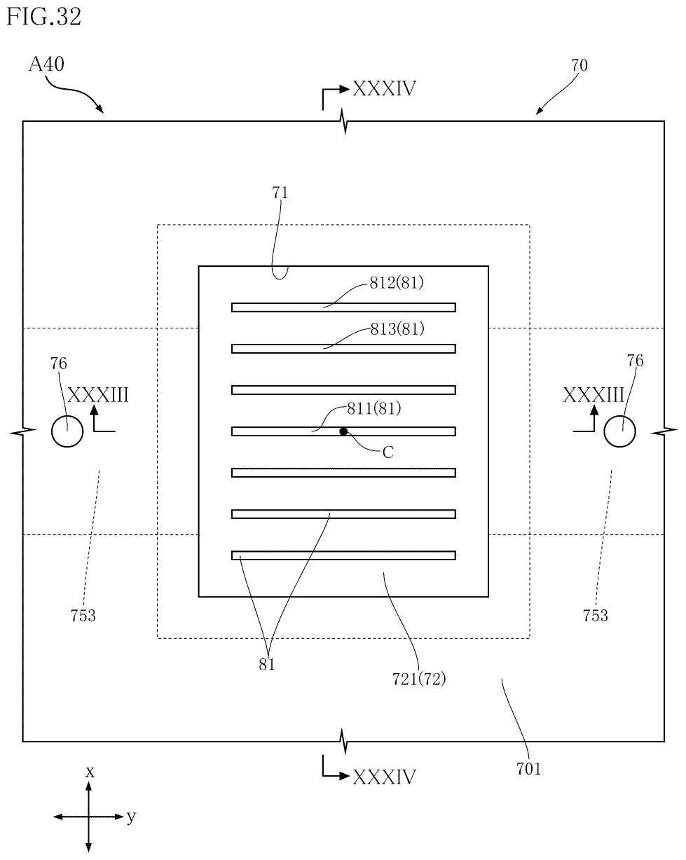

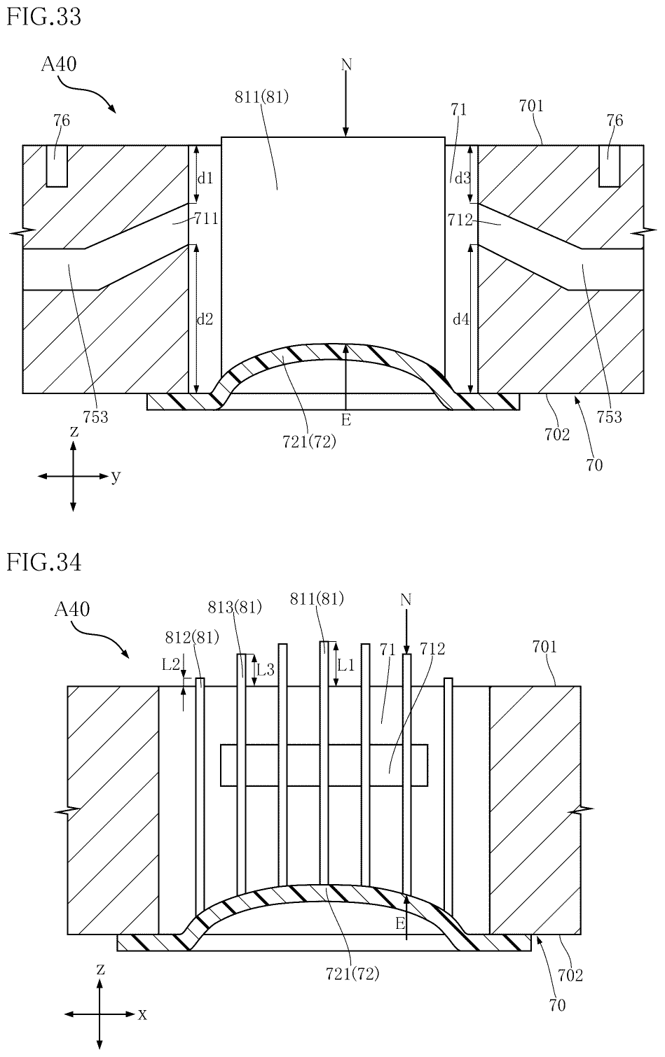

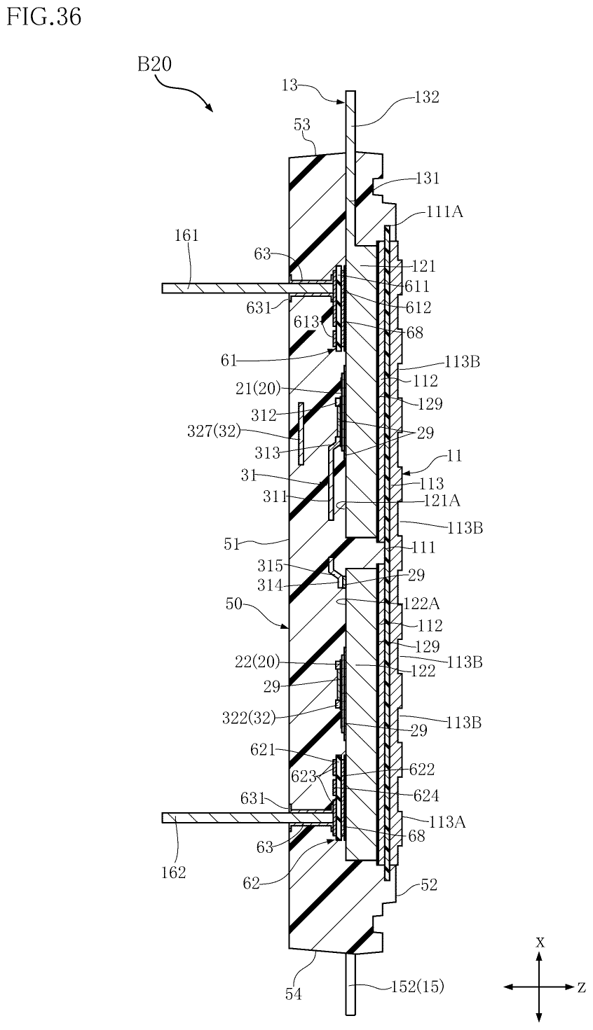

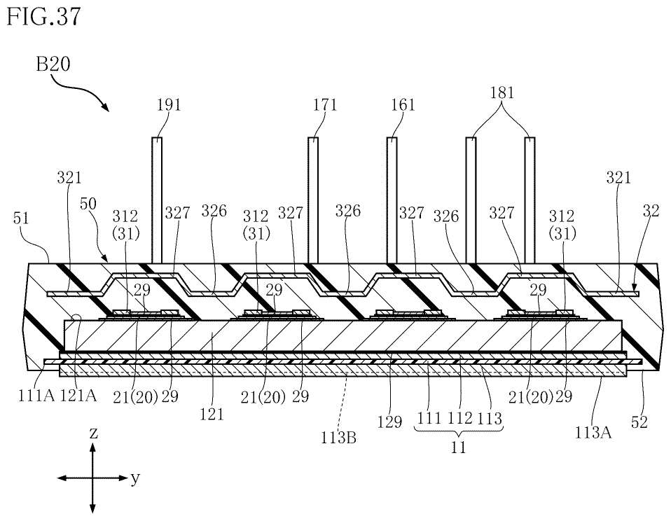

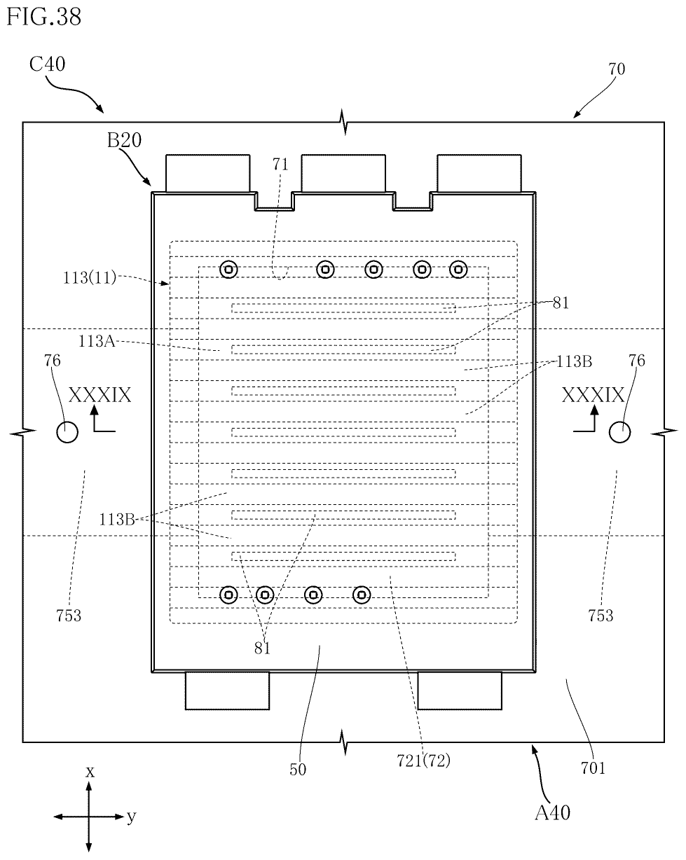

With reference to FIGS. 32 to 39, a semiconductor module C40 according to a fourth embodiment of the present disclosure will be described. In these figures, elements that are identical or similar to those of the cooling unit A10, the semiconductor devices B10, and the semiconductor module C10 described above are indicated by the same reference numerals. In addition, the description of such elements is not repeated to avoid redundancy. For the convenience of illustration, FIG. 38 omits the mounting components 88.

The semiconductor module C40 includes a cooling unit A40, a plurality of semiconductor devices B20, and a plurality of mounting components 88. The cooling unit A40 differs from the cooling unit A10 in the configuration of the heat dissipating members 81. In addition, each semiconductor device B20 differs from the semiconductor devices B10 in the configuration of the heat dissipating layer 113 of the substrate 11.

As shown in FIGS. 32 to 34, the heat dissipating members 81 include a first member 811, a second member 812, and a third member 813 each of which is a plate-like structure extending in the third direction y.

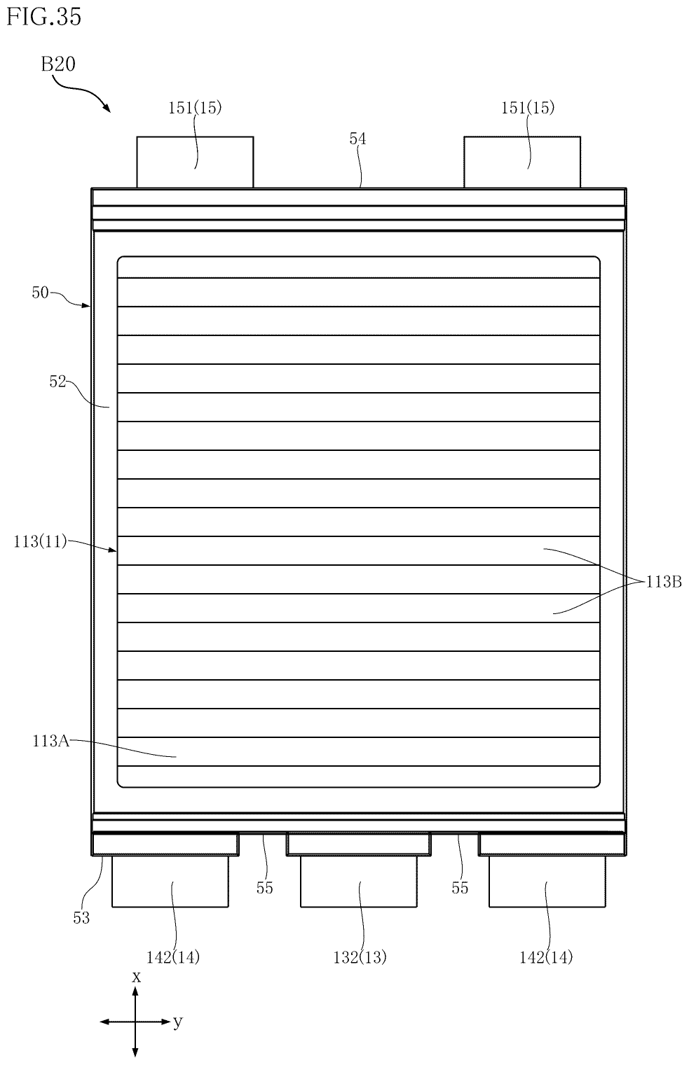

As shown in FIGS. 35 to 37, each of a plurality of depressions 113B of the heat dissipating layer 113 extends in the third direction y.

As shown in FIG. 38, the base surface 113A of the heat dissipating layer 113 overlaps with the heat dissipating members 81 as viewed in the first direction z. Each heat dissipating member 81 is in contact with the base surface 113A of the heat dissipating layer 113.

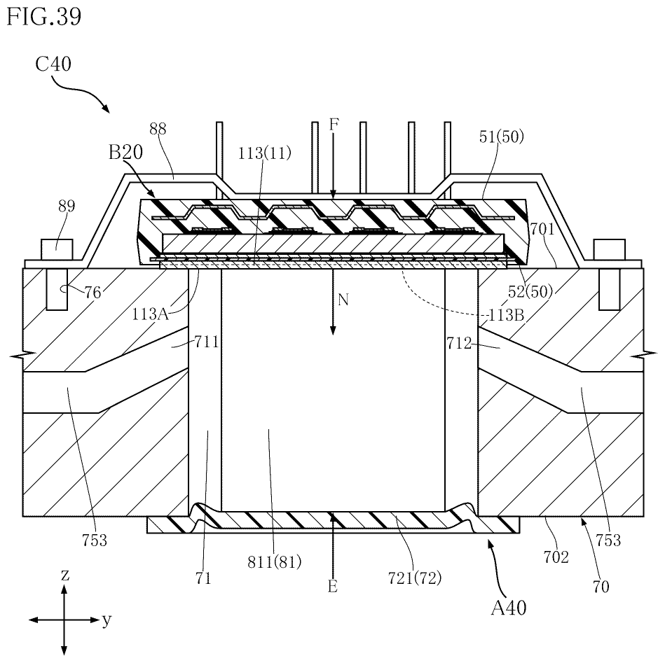

As shown in FIG. 39, in the semiconductor module C40, a load F applied by each mounting component 88 in the first direction z toward the bottom portion 72 of the housing 70 acts on the corresponding semiconductor device B20. As a result, a load N in the first direction z toward the same side as the load F is applied to the heat dissipating members 81 from the base surface 113A of the heat dissipating layer In response, the elastic portion 721 of the bottom 113. portion 72 exerts an elastic force E opposing the load N in the first direction z on the heat dissipating members 81.

### Variation

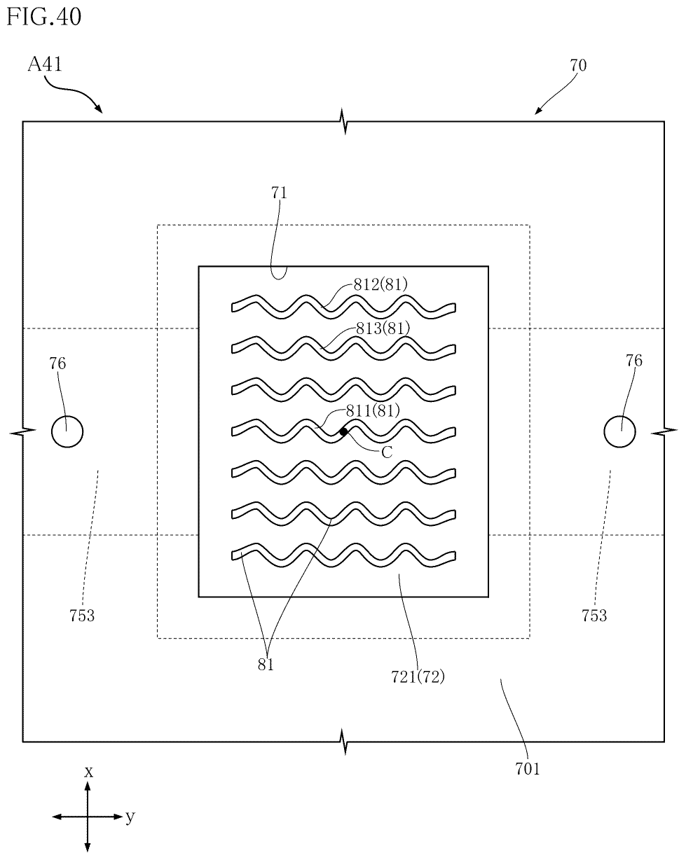

Next, with reference to FIG. 40, the following describes a cooling unit A41 according to a variation of the cooling unit A40.

The cooling unit A41 differs from the cooling unit A40 in the shape of the heat dissipating members 81. As shown in FIG. 40, the heat dissipating members 81 includes a first member 811, a second member 812, and a third member 813 each of which is a plate-like structure that meanders in a wavy pattern along the second direction x.

Next, advantages of the semiconductor module C40 will be described.

The semiconductor module C40 includes a cooling unit A40 and a semiconductor device B20. The cooling unit A40 includes: a housing 70 including a recess 71 and a bottom portion 72; and a heat dissipating member 81 attached to the bottom portion 72 and at least partly accommodated in the recess 71. The recess 71 includes an inlet 711 and an outlet 712. The semiconductor device B20 includes a substrate 11 that includes a heat dissipating layer 113 covering the recess 71. The heat dissipating layer 113 includes a base surface 113A facing the recess 71 and a depression 113B recessed from the base surface 113A. The depression 113B overlaps with the recess 71 as viewed in first direction z. This configuration of the semiconductor module C40 can therefore achieve more efficient cooling of the semiconductor device B20 that is attached to the cooling unit A40. The semiconductor module C40 has a configuration in common with the semiconductor module C10, thereby achieving the same effect as the semiconductor module C10.

In the cooling unit A40, each of the first member 811 and the second member 812 of the heat dissipating members 81 is a plate-like structure extending in the third direction y. This configuration allows the use of plate-like structures as the first member 811 and the second member 812 without obstructing the flow of coolant in the recess 71 from the inlet 711 to the outlet 712.

### Fifth Embodiment

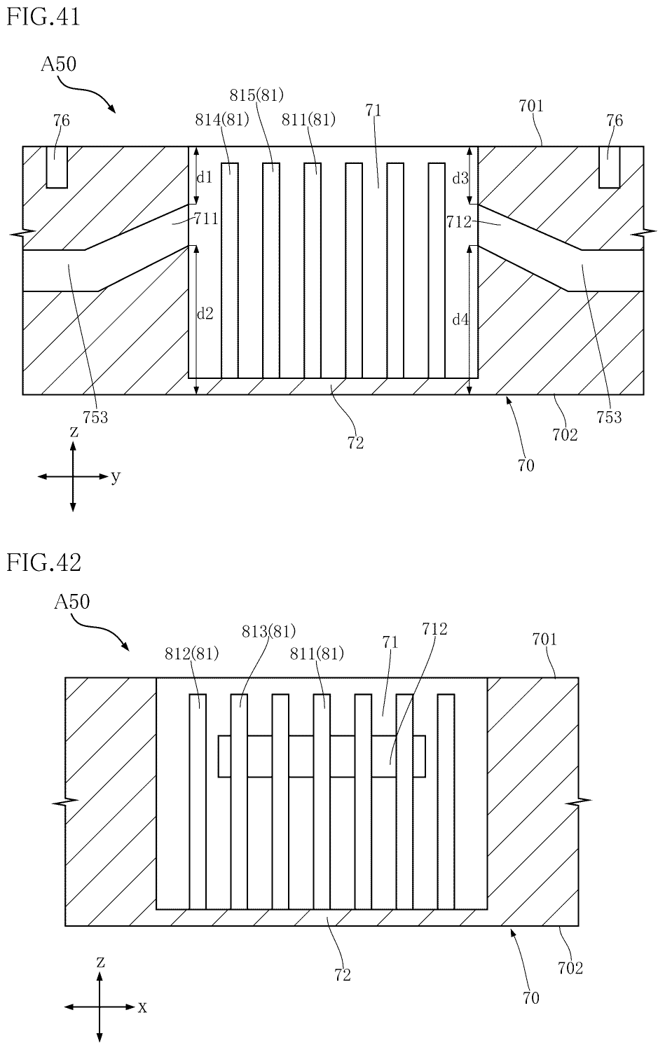

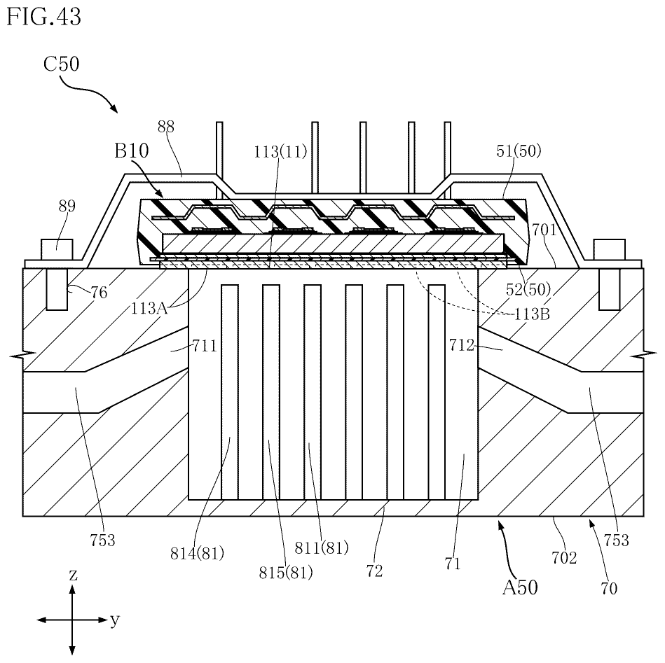

With reference to FIGS. 41 to 43, a semiconductor module C50 according to a fifth embodiment of the present disclosure will be described. In these figures, elements that are identical or similar to those of the cooling unit A10, the semiconductor devices B10, and the semiconductor module C10 described above are indicated by the same reference numerals. In addition, the description of such elements is not repeated to avoid redundancy. Note that the section shown in FIG. 41 corresponds in position to the section of the semiconductor module C10 shown in FIG. 5. The section shown in FIG. 42 corresponds in position to the section of the cooling unit A10 shown in FIG. 6. The section shown in FIG. 43 corresponds in position to the section of the semiconductor module C10 shown in FIG. 23A.

The semiconductor module C50 includes a cooling unit A50, a plurality of semiconductor devices B10, and a plurality of mounting components 88. The cooling unit A50 differs from the cooling unit A10 of the semiconductor module C10 in the configurations of the bottom portions 72 of the housing 70 and the heat dissipating members 81.

As shown in FIGS. 41 and 42, each bottom portion 72 has no elastic portion 721. The bottom portion 72 is integrally formed with the other portions of the housing 70. The heat dissipating members 81 are bonded to the bottom portion 72. Each heat dissipating member 81 is entirely accommodated within the recess 71 of the housing 70.

The substrate 11 of each semiconductor device B10 is located such that the depressions 113B in the heat dissipating layer 113 overlap with a recess 71 of the housing 70 as viewed in the first direction z. As viewed in the first direction z, the base surface 113A of the heat dissipating layer 113 overlaps with the heat dissipating members 81. For the semiconductor module C50, however, the base surface 113A is not in contact with the heat dissipating members 81.

Next, advantages of the semiconductor module C50 will be described.

The semiconductor module C50 includes a cooling unit A50 and a semiconductor device B10. The cooling unit A50 includes: a housing 70 including a recess 71 and a bottom portion 72; and a heat dissipating member 81 attached to the bottom portion 72 and at least partly accommodated in the recess 71. The recess 71 includes an inlet 711 and an outlet 712. The semiconductor device B10 includes a substrate 11 that includes a heat dissipating layer 113 covering the recess 71. The heat dissipating layer 113 includes a base surface 113A facing the recess 71 and a depression 113B recessed from the base surface 113A. The depression 113B overlaps with the recess 71 as viewed in first direction z. This configuration of the semiconductor module C50 can therefore achieve more efficient cooling of the semiconductor device B10 that is attached to the cooling unit A50. The semiconductor module C50 has a configuration in common with the semiconductor module C10, thereby achieving the same effect as the semiconductor module C10.

### Sixth Embodiment

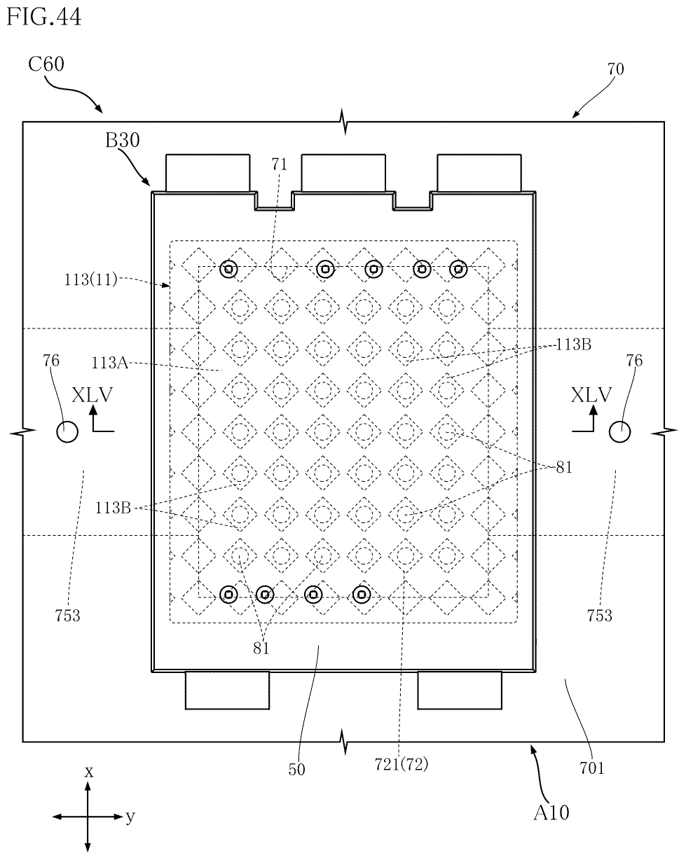

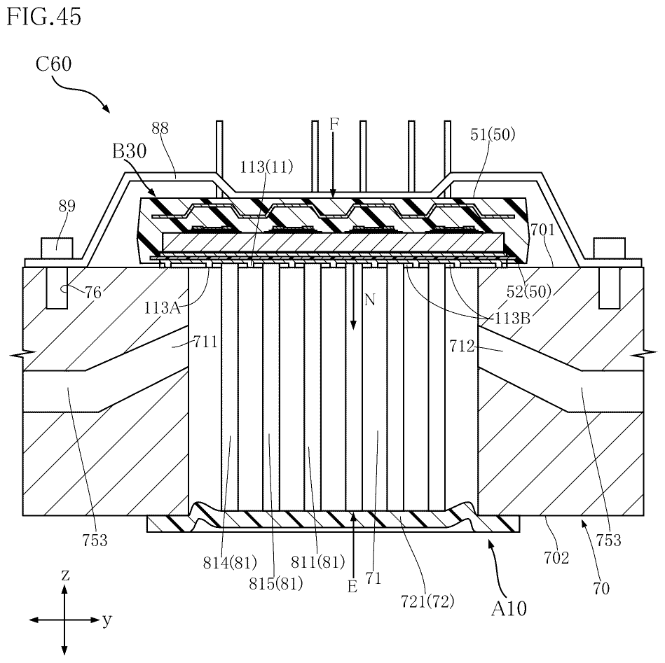

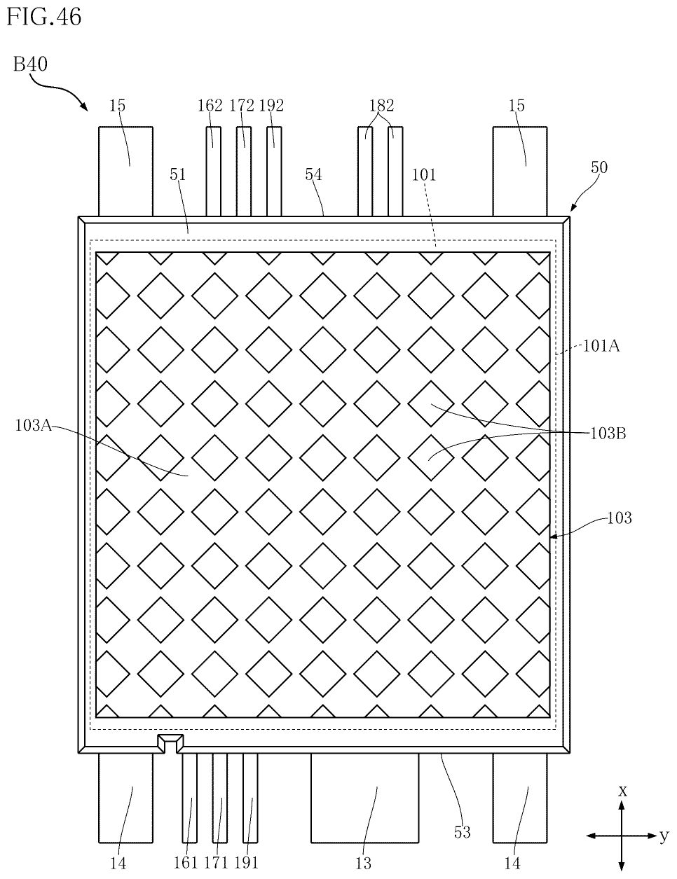

With reference to FIGS. 44 and 45, a semiconductor module C60 according to a sixth embodiment of the present disclosure will be described. In these figures, elements that are identical or similar to those of the cooling unit A10, the semiconductor devices B10, and the semiconductor module C10 described above are indicated by the same reference numerals. In addition, the description of such elements is not repeated to avoid redundancy. For the convenience of illustration, FIG. 44 omits the mounting components 88.

The semiconductor module C60 includes a cooling unit A10, a plurality of semiconductor devices B30, and a plurality of mounting components 88. In addition, each semiconductor device B30 differs from the semiconductor devices B10 in the configuration of the heat dissipating layer 113 of the substrate 11.

As shown in FIG. 44, the substrate 11 of each semiconductor device B30 is located relative to the cooling unit A10 such that the depressions 113B in the heat dissipating layer 113 overlap with a recess 71 of the housing 70 and also with the heat dissipating members 81 as viewed in the first direction z. The plurality of depressions 113B include those that overlap with either the first member 811, the second member 812, the third member 813, the fourth member 814, or the fifth member 815 of the heat dissipating members 81 as viewed in the first direction z. As shown in FIG. 45, in the semiconductor module C60, each heat dissipating member 81 is in contact with a depression 113B.

Next, advantages of the semiconductor module C60 will be described.

The semiconductor module C60 includes a cooling unit A10 and a semiconductor device B30. The cooling unit A10 includes: a housing 70 including a recess 71 and a bottom portion 72; and a heat dissipating member 81 attached to the bottom portion 72 and at least partly accommodated in the recess 71. The recess 71 includes an inlet 711 and an outlet 712. The semiconductor device B30 includes a substrate 11 that includes a heat dissipating layer 113 covering the recess 71. The heat dissipating layer 113 includes a base surface 113A facing the recess 71 and a depression 113B recessed from the base surface 113A. The depression 113B overlaps with the recess 71 as viewed in first direction z. This configuration of the semiconductor module C60 can therefore achieve more efficient cooling of the semiconductor device B30 that is attached to the cooling unit A10. The semiconductor module C60 has a configuration in common with the semiconductor module C10, thereby achieving the same effect as the semiconductor module C10.

### Seventh Embodiment

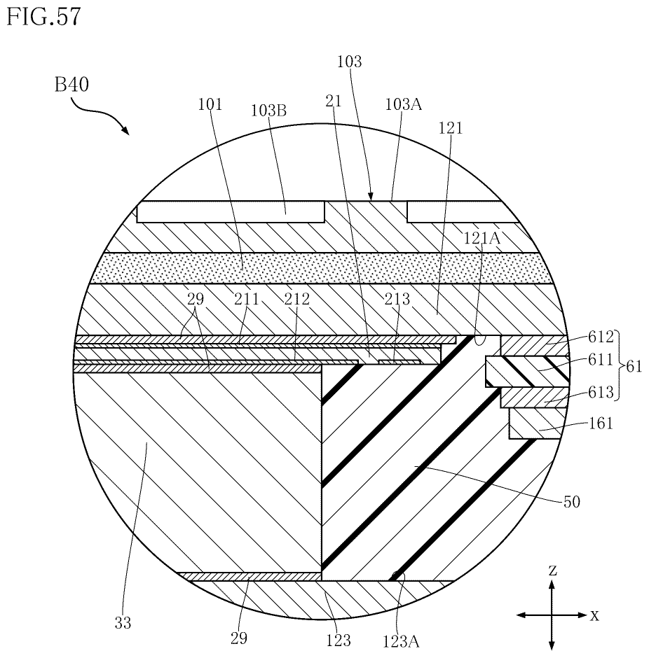

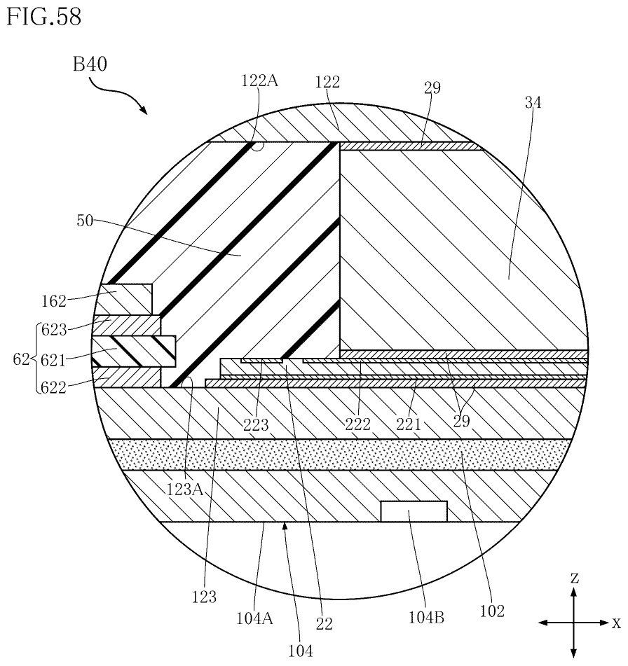

With reference to FIGS. 46 to 61, a semiconductor module C70 according to a seventh embodiment of the present disclosure will be described. In these figures, elements that are identical or similar to those of the cooling unit A10, the semiconductor devices B10, and the semiconductor module C10 described above are indicated by the same reference numerals. In addition, the description of such elements is not repeated to avoid redundancy.

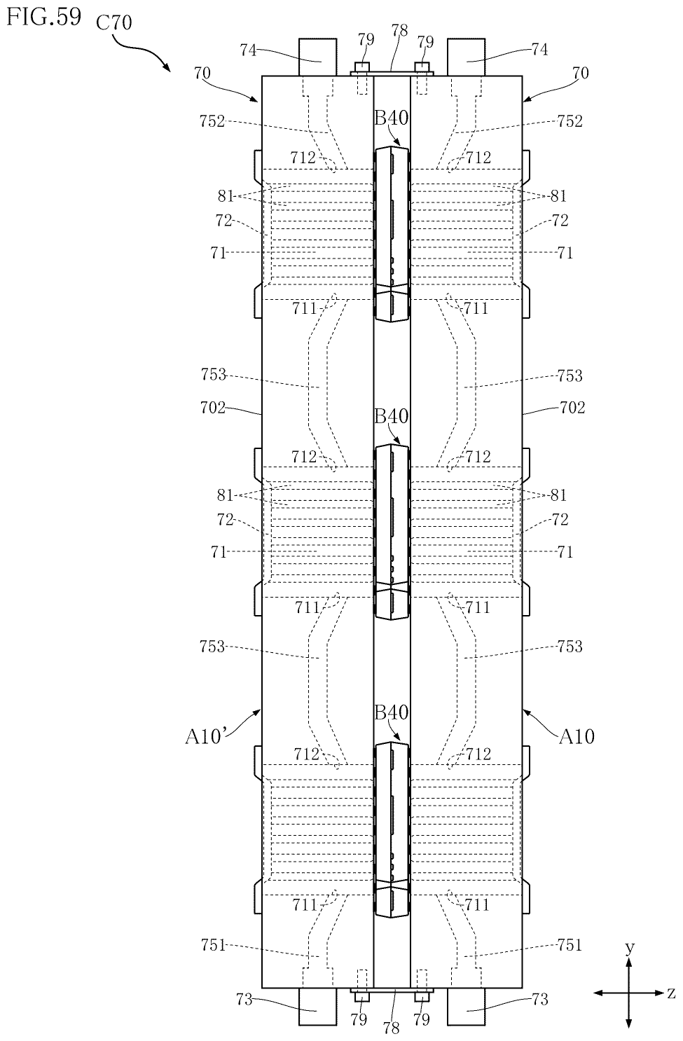

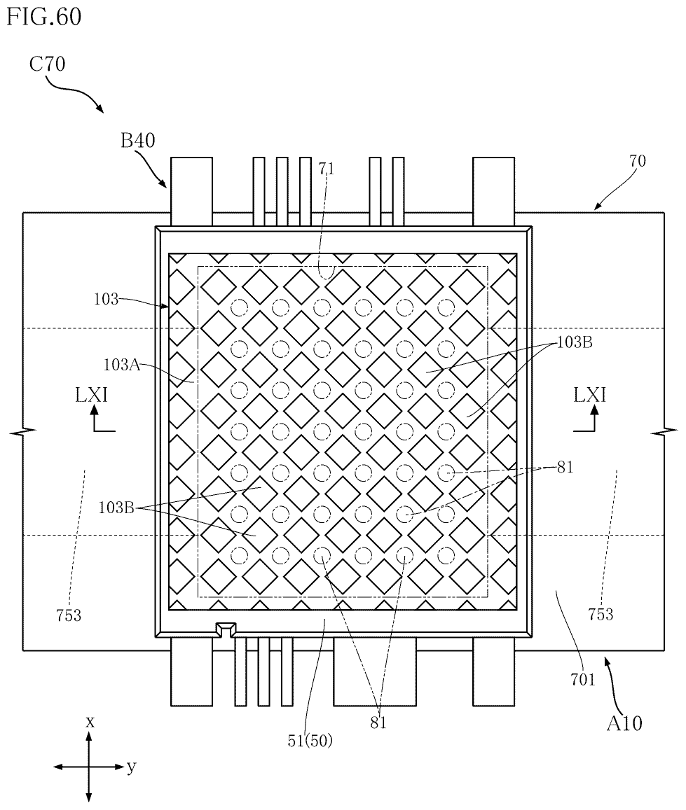

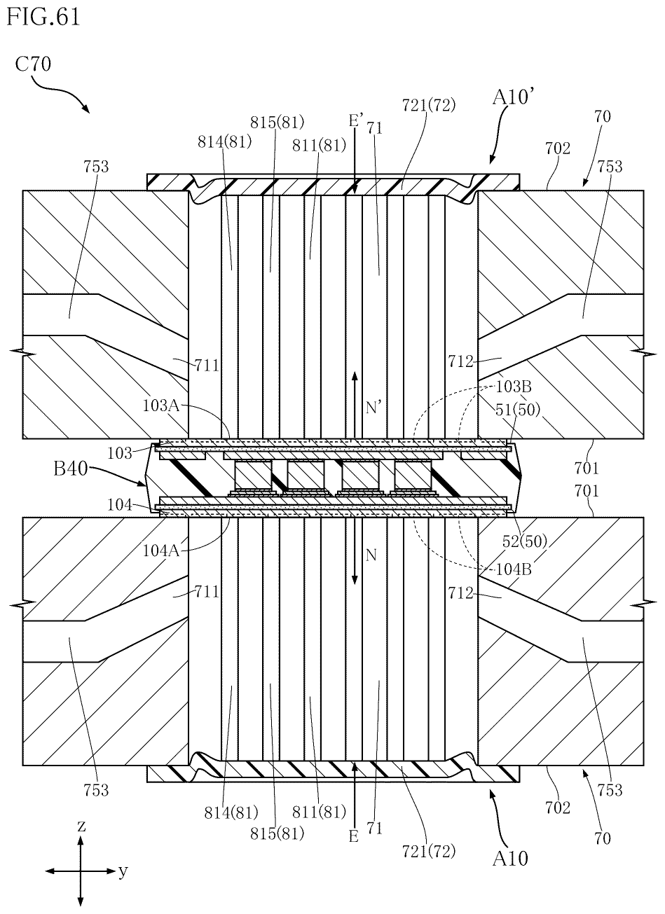

The semiconductor module C70 includes a cooling unit A10, an additional cooling unit A10′, a plurality of semiconductor devices B40, and a plurality of connecting members 78. As shown in FIGS. 59 and 61, the additional cooling unit A10′ is identical in configuration to the cooling unit A10. The cooling unit A10 is an example of a “first cooling unit”, and the additional cooling unit A10′ is an example of a “second cooling unit”.

### Semiconductor Devices B40

Next, with reference to FIGS. 46 to 58, the semiconductor devices B40 included in the semiconductor module C70 are described. All semiconductor devices B40 are all identical. Consequently, the following description pertains to one semiconductor device B40.

The semiconductor device B40 includes a first insulating layer 101, a first conductive layer 121, a second conductive layer 122, a third conductive layer 123, a second insulating layer 102, a first heat dissipating layer 103, a second heat dissipating layer 104, a plurality of semiconductor elements 20, a plurality of first spacers 33, a plurality of second spacers 34, and a sealing resin 50. The semiconductor device B40 additionally includes a first power terminal 13, two second power terminals 14, two third power terminals 15, a first signal terminal 161, a second signal terminal 162, a third signal terminal 171, a fourth signal terminal 172, two sixth signal terminals 182, a seventh signal terminal 191, an eighth signal terminal 192, a first wiring 61, and a second wiring 62.

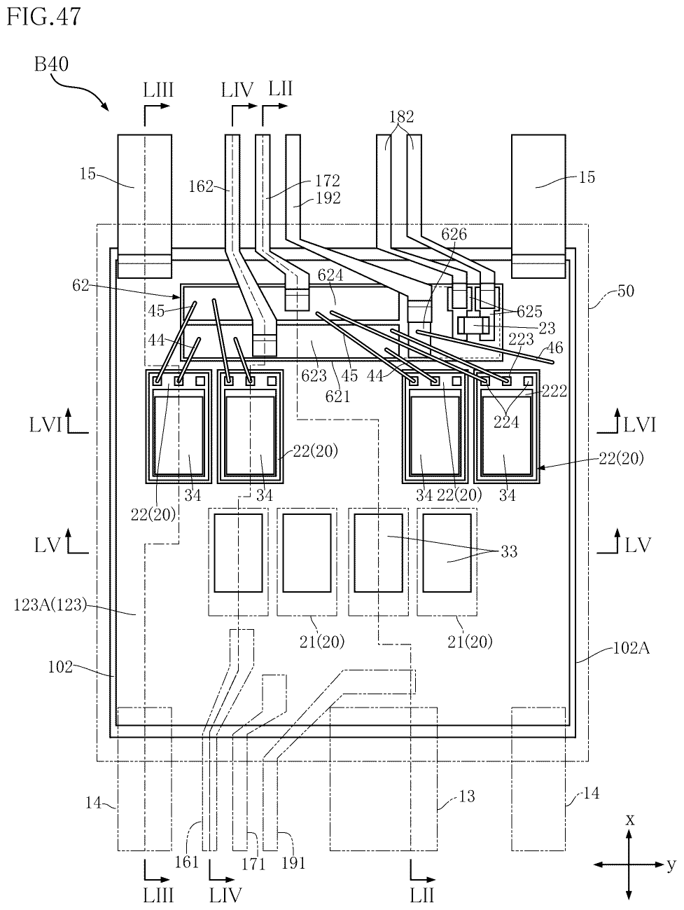

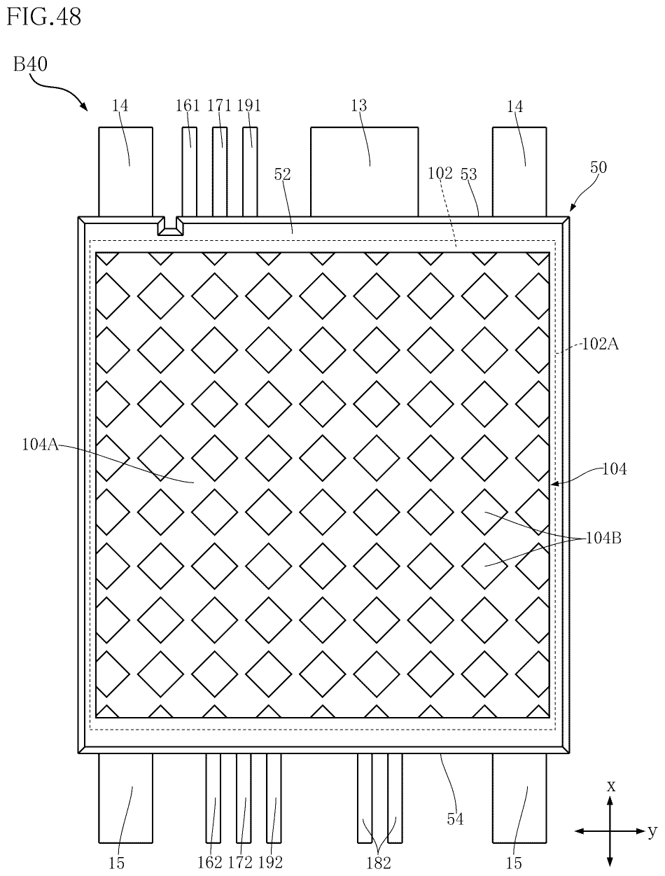

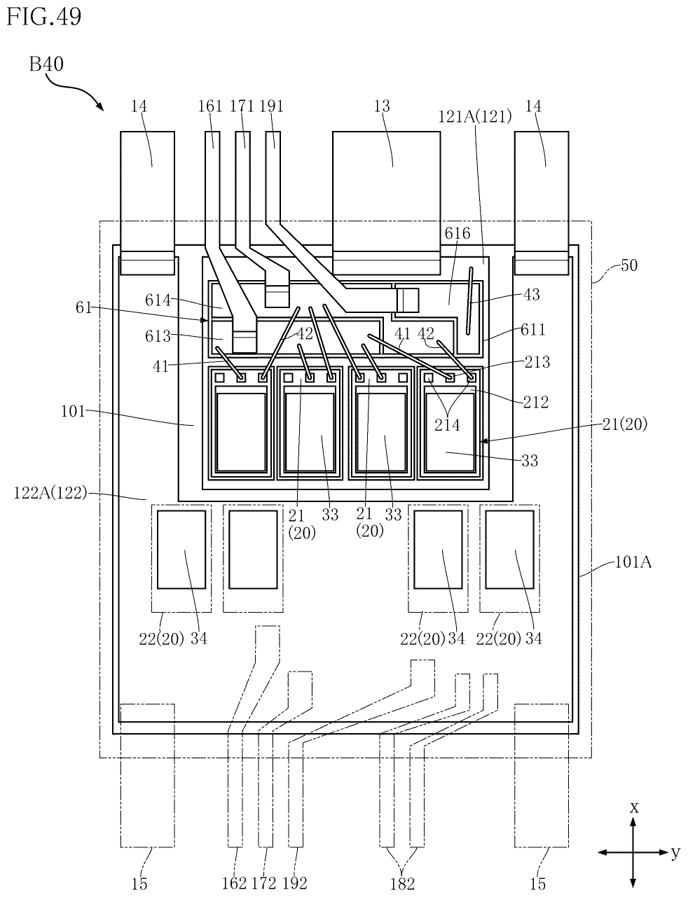

For the convenience of description, FIG. 47 shows some elements as transparent, including the first semiconductor elements 21 and the sealing resin 50. In addition, FIG. 47 omits some elements, including the first insulating layer 101, the first conductive layer 121, the second conductive layer 122, the first heat dissipating layer 103, and the first wiring 61. For the convenience of description, FIG. 49 shows some elements as transparent, including second the semiconductor elements 22 and the sealing resin 50. In addition, FIG. 49 omits some elements, including the second insulating layer 102, the third conductive layer 123, the second heat dissipating layer 104, and the second wiring 62. FIGS. 47 and 49 show the outlines of elements that are shown as transparent are indicated by imaginary lines (two-dot-dash lines). FIG. 47 also shows lines LII-LII, LIII-LIII, and LIV-LIV with dot-dash lines.

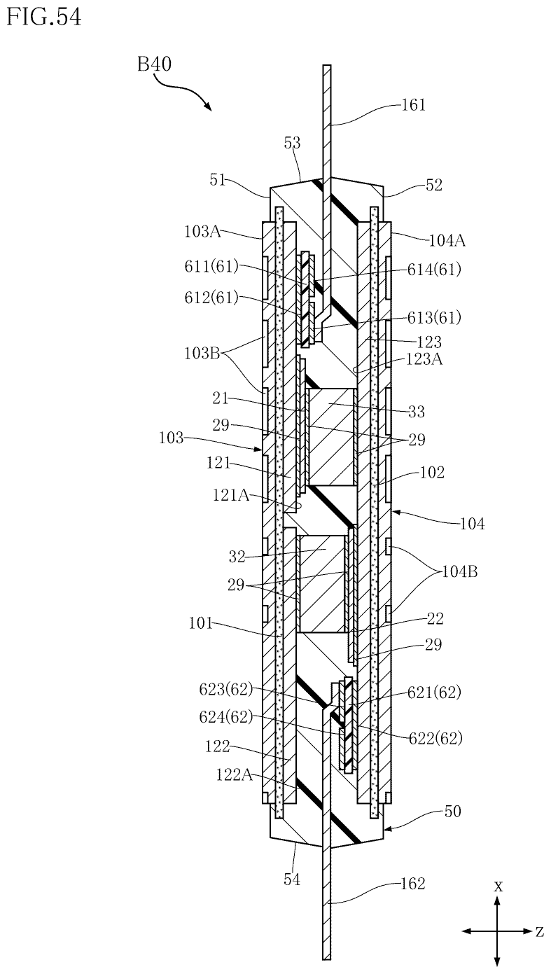

As shown in FIGS. 54 to 56, the sealing resin 50 covers the first semiconductor elements 21 and the second semiconductor elements 22. The sealing resin 50 has portions located between either the first conductive layer 121 or the second conductive layer 122 and the third conductive layer 123 in the first direction z.

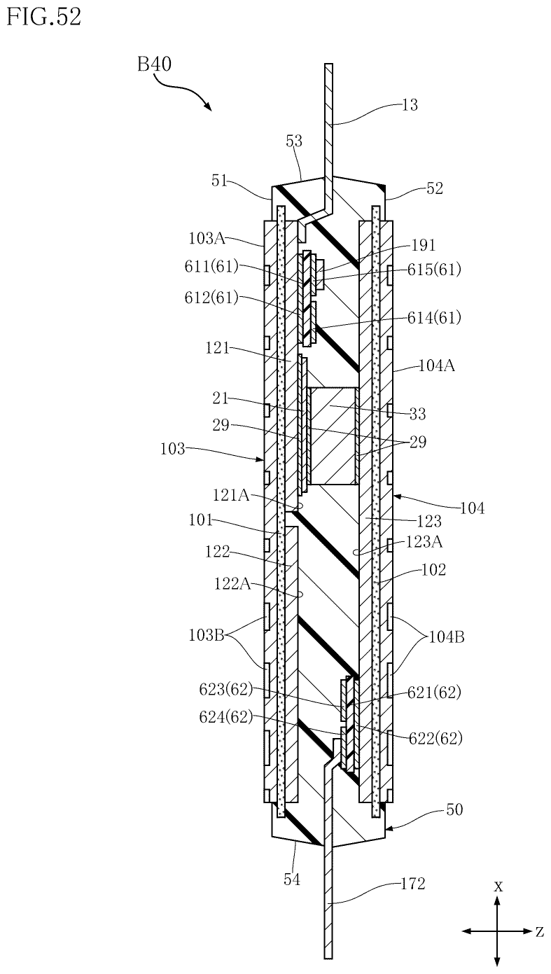

As shown in FIGS. 52 to 56, the first insulating layer 101 is covered with the sealing resin 50. The first insulating layer 101 is made of a material with relatively high thermal conductivity. The first insulating layer 101 may be made of a ceramic material containing either silicon nitride (Si₃N₄) or aluminum nitride. The first insulating layer 101 is smaller in dimension in the first direction z than each of the first conductive layer 121, the second conductive layer 122, and the first heat dissipating layer 103.

As shown in FIGS. 52, 54, and 55, the first conductive layer 121 is bonded to the surface of the first insulating layer 101 facing the first side in the first direction z. The first semiconductor elements 21 and the first wiring 61 are mounted on the first conductive layer 121. As shown in FIG. 49, the first conductive layer 121 is surrounded by the peripheral edge 101A of the first insulating layer 101 as viewed in the first direction z. The first conductive layer 121 is covered with the sealing resin 50. The composition of the first conductive layer 121 may include copper. The first conductive layer 121 has a first obverse surface 121A facing the first side in the first direction z. The first obverse surface 121A faces the first semiconductor elements 21 and the first wiring 61.

As shown ins FIGS. 52, 54 and 55, the second conductive layer 122 is located on the same side as the first conductive layer 121 in the first direction z with respect to the first insulating layer 101 and is bonded to the first insulating layer 101. As shown in FIG. 49, the second conductive layer 122 is surrounded by the peripheral edge 101A of the first insulating layer 101 as viewed in the first direction z. The second conductive layer 122 is covered with the sealing resin 50. The composition of the second conductive layer 122 may include copper. The second conductive layer 122 has a second obverse surface 122A facing the same side as the first obverse surface 121A of the first conductive layer 121 in the first direction z. The second obverse surface 122A faces the second spacers 34.

As shown in FIGS. 52, 54 and 55, the first heat dissipating layer 103 is located opposite to the first conductive layer 121 and the second conductive layer 122 in the first direction z with respect to the first insulating layer 101. The first heat dissipating layer 103 is bonded to the first insulating layer 101. As shown in FIG. 46, the first heat dissipating layer 103 is surrounded by the peripheral edge 101A of the first insulating layer 101 as viewed in the first direction z. The composition of the first heat dissipating layer 103 may include copper.

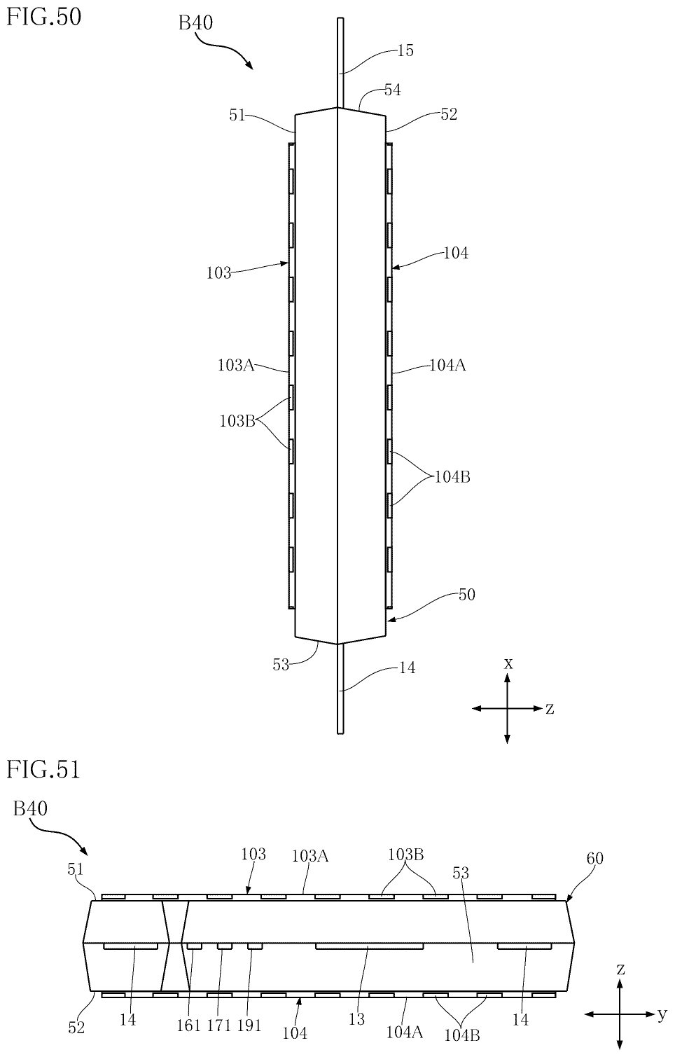

As shown in FIGS. 50 to 56, the first heat dissipating layer 103 partly protrudes from the top surface 51 of the sealing resin 50. As shown in FIGS. 46 and 52 to 56, the first heat dissipating layer 103 has a first base surface 103A and a plurality of first depressions 103B. The first base surface 103A faces away from the first insulating layer 101 in the first direction z. The first base surface 103A is located farther from the sealing resin 50 than the top surface 51. That is, the first base surface 103A protrudes from the sealing resin 50 in the first direction z. The first depressions 103B are recessed from the first base surface 103A in the first direction z.

As shown in FIGS. 47 and 49, the plurality of semiconductor elements 20 include the first semiconductor elements 21 and the second semiconductor elements 22. As shown in FIGS. 52 to 56, the semiconductor elements 20 are located between the first heat dissipating layer 103 and the second heat dissipating layer 104 in the first direction z.

As shown in FIGS. 52, 54 and 55, the first semiconductor elements 21 are electrically bonded to the first obverse surface 121A of the first conductive layer 121. As shown in FIG. 49, each first semiconductor element 21 includes two first sensing electrodes 214. The two first sensing electrodes 214 are located on opposite sides of the first gate electrode 213 in the third direction y. A first wire 41 is electrically bonded to one of the two first sensing electrodes 214.

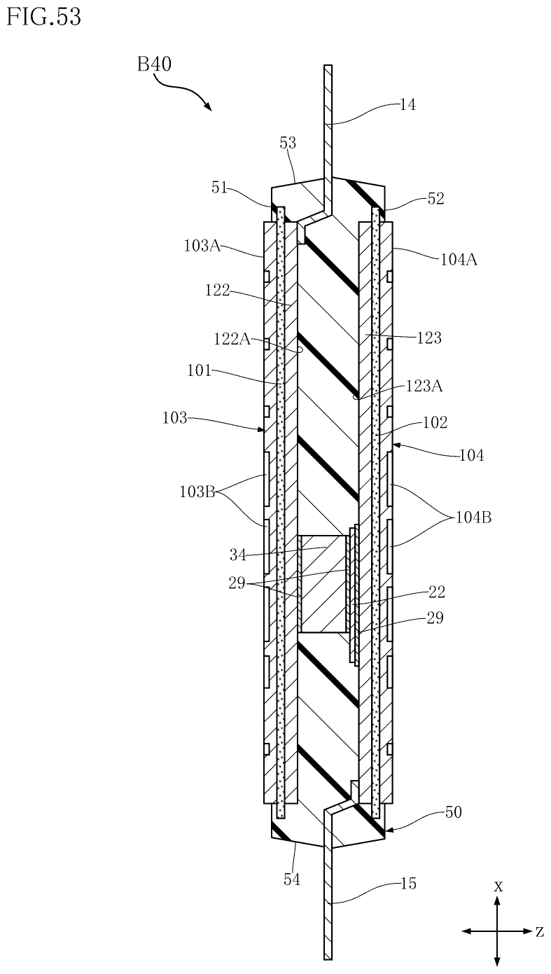

As shown in FIGS. 53, 54 and 56, the second semiconductor elements 22 are electrically bonded to a third obverse surface 123A (described later) of the third conductive layer 123. As shown in FIG. 47, each second semiconductor element 22 includes two second sensing electrodes 224. The two second sensing electrodes 224 are located on opposite sides of the second gate electrode 223 in the third direction y. A fourth wire 44 is electrically bonded to one of the two second sensing electrodes 224.

The first spacers 33 are electrical conductors. As shown in FIG. 49, the first spacers 33 are electrically bonded to the respective second 212 the electrodes of first semiconductor element 21 each via a conductive bonding layer 29. Each first spacer 33 is located between the third conductive layer 123 and the first semiconductor element 21 in the first direction z. As shown in FIGS. 47 and 49, each first spacer 33 is rectangular as viewed in the first direction z. Alternatively, each first spacer 33 may be circular as viewed in the first direction z. As shown in FIG. 49, the first spacers 33 are smaller in area than the second electrodes 212 as viewed in the first direction z. The composition of the first spacers 33 may include copper and molybdenum (Mo). The first spacers 33 are greater in dimension in the first direction z than any of the first conductive layer 121, the second conductive layer 122, and the third conductive layer 123.

The second spacers 34 are electrical conductors. As shown in FIG. 56, the second spacers 34 are electrically bonded to the second obverse surface 122A of the second conductive layer 122 each via a conductive bonding layer 29. The second spacers 34 are aligned in the third direction y. Each second spacer located between second 34 is a semiconductor element 22 and the second conductive layer 122 in the first direction z. As shown in FIGS. 47 and 49, each second spacer 34 is rectangular as viewed in the first direction z. Alternatively, each second spacer 34 may be circular as viewed in the first direction z. As shown in FIG. 47, the second spacers 34 are smaller in area than the fourth electrodes 222 of the second semiconductor element 22 as viewed in the first direction z. The composition of the second spacers 34 may include copper and molybdenum. The second spacers 34 are greater in dimension in the first direction z than any of the first conductive layer 121, the second conductive layer 122, and the third conductive layer 123.

As shown in FIGS. 52, 54 and 55, the third conductive layer 123 is spaced apart from the first conductive layer 121 and the second conductive layer 122 in the first direction z on the side of the first obverse surface 121A of the first conductive layer 121. The second semiconductor elements 22 and the second wiring 62 are mounted on the third conductive layer 123. As shown in FIG. 47, the third conductive layer 123 is surrounded by the peripheral edge 102A of the second insulating layer 102 as viewed in the first direction z. The third conductive layer 123 is covered with the sealing resin 50. The composition of the third conductive layer 123 may include copper. The third conductive layer 123 has a third obverse surface 123A facing the same side as the first obverse surface 121A of the first conductive layer 121 in the first direction z. The third obverse surface 123A faces the second semiconductor elements 22 and the second wiring 62. The area of the third obverse surface 123A is larger than the total area of the first obverse surface 121A and the second obverse surface 122A.

As shown in FIGS. 52, 54, and 55, the first spacers 33 are electrically bonded to the third obverse surface 123A of the third conductive layer 123 each via a conductive bonding layer 29. That is, the second electrode 212 of each first semiconductor element 21 is electrically bonded to the third conductive layer 123 via a first spacer 33. Hence, the second electrodes 212 of the first semiconductor elements 21 are electrically connected to the third conductive layer 123.

As shown in FIGS. 53, 54 and 56, the second spacers 34 are electrically bonded to the fourth electrodes 222 of the respective second semiconductor elements 22 each via a conductive bonding layer 29. That is, the fourth electrode 222 of each second semiconductor element 22 is electrically bonded to the second conductive layer 122 via a second spacer 34. Hence, the fourth electrodes 222 of the second semiconductor elements 22 are electrically connected to the second conductive layer 122.

In the semiconductor device B40, the first semiconductor elements 21 form a part of an upper arm circuit, and the second semiconductor elements 22 form a part of a lower arm circuit. In the semiconductor device B40, the second semiconductor elements 22 have the same configuration as the first semiconductor 21, the elements when second semiconductor elements 22 are inverted by rotation on the axis in the third direction y. Hence, the second electrodes 212 of the first semiconductor elements 21 and the third electrodes 221 of the second semiconductor elements 22 have mutually opposite polarities.

As shown in FIG. 54, the second insulating layer 102 is located opposite to the first semiconductor elements 21 and the second semiconductor elements 22 with respect to the third conductive layer 123. The second insulating layer 102 is bonded to the third conductive layer 123. The second insulating layer 102 is covered with the sealing resin 50. The second insulating layer 102 is made of a material with relatively high thermal conductivity. The second insulating layer 102 may be made of a ceramic material containing either silicon nitride or aluminum nitride. The second insulating layer 102 is smaller in dimension in the first direction z than each of the third conductive layer 123 and the second heat dissipating layer 104.

As shown in FIGS. 52 to 56, the second heat dissipating layer 104 is located opposite to the third conductive layer 123 in the first direction z with respect to the second insulating layer 102. The second heat dissipating layer 104 is bonded to the second insulating layer 102. The second heat dissipating layer 104 is spaced apart from the first heat dissipating layer 103 in the first direction z. As shown in FIG. 48, the second heat dissipating layer 104 is surrounded by the peripheral edge 102A of the second insulating layer 102 as viewed in the first direction z. The composition of the second heat dissipating layer 104 may include copper.

As shown in FIGS. 50 to 56, the second heat dissipating layer 104 partly protrudes from the bottom surface 52 of the sealing resin 50. As shown in FIGS. 48 and 52 to 56, the second heat dissipating layer 104 has a second base surface 104A and a plurality of second depressions 104B. The second base surface 104A faces away from the second insulating layer 102 in the first direction z. The second base surface 104A is located farther from the sealing resin 50 than the bottom surface 52. That is, the second base surface 104A protrudes from the sealing resin 50 in the first direction z. The second depressions 104B are recessed from the second base surface 104A in the first direction z.

As shown in FIGS. 52 and 54, the first wiring 61 is bonded to the first obverse surface 121A of the first conductive layer 121. The first wiring 61 is located opposite to the second semiconductor elements 22 in the second direction x with respect to the first semiconductor elements 21. The first wiring 61 is closer to the first insulating layer 101 in the first direction z than the second insulating layer 102. The first wiring 61 is electrically connected to the first semiconductor elements 21 and the first conductive layer 121. As shown in FIGS. 49 and 54, the first wiring 61 includes a first mounting layer 611, a first metal layer 612, a first gate wiring layer 613, a first sensing wiring layer 614, and a second sensing wiring layer 616. The first metal layer 612 is bonded to the first obverse surface 121A via solder, for example.

As shown in FIGS. 52 and 54, the second wiring 62 is bonded to the third conductive layer 123 of the third obverse surface 123A. The second wiring 62 is located opposite to the first semiconductor elements 21 in the second direction x with respect to the second semiconductor elements 22. The second wiring 62 is closer to the second insulating layer 102 in the first direction z than the first insulating layer 101. The second wiring 62 is electrically connected to the second semiconductor elements 22 and the third conductive layer 123. As shown in FIGS. 47 and 54, the second wiring 62 includes a second mounting layer 621, a second metal layer 622, a second gate wiring layer 623, a third sensing wiring layer 624, two second temperature sensing layers 625, and a fourth sensing wiring layer 626. The second metal layer 622 is bonded to the third obverse surface 123A via solder, for example. A thermistor 23 is electrically bonded to the two second temperature sensing layers 625.

As shown in FIG. 47, a sixth wire 46 is electrically bonded to the fourth sensing wiring layer 626. The sixth wire 46 is also electrically bonded to the third obverse surface 123A of the third conductive layer 123. Hence, the fourth sensing wiring layer 626 is electrically connected to the third conductive layer 123.

As shown in FIGS. 49 and 52, the first power terminal 13 is electrically bonded to the first obverse surface 121A of the first conductive layer 121. Hence, the first power terminal 13 is electrically connected to the first electrodes 211 of the first semiconductor elements 21 via the first conductive layer 121. The first power terminal 13 is located opposite to the second semiconductor elements 22 in the second direction x with respect to the first semiconductor elements 21. The first power terminal 13 is a metal lead made of a material containing copper or a copper alloy. The first power terminal 13 partly protrudes to the outside from the first side surface 53 of the sealing resin 50.

As shown in FIGS. 49 and 53, each of the two second power terminals 14 is electrically bonded to the second obverse surface 122A of the second conductive layer 122. Hence, each second power terminal 14 is electrically connected to the fourth electrodes 222 of the second semiconductor elements 22 via the second conductive layer 122. The two second power terminals 14 are located on the same side as the first power terminal 13 in the second direction x with respect to the first semiconductor elements 21. The two second power terminals 14 are located opposite to each other in the third direction y with respect to the first power terminal 13. The two second power terminals 14 are metal leads made of a material containing copper or a copper alloy. Each of the two second power terminals 14 partly protrudes to the outside from the first side surface 53 of the sealing resin 50.

As shown in FIGS. 47 and 53, each of the two third power terminals 15 is electrically bonded to the third obverse surface 123A of the third conductive layer 123. The two third power terminals 15 are located opposite to the first power terminal 13 and the two second power terminals 14 in the second direction x with respect to the first semiconductor elements 21 and the second semiconductor elements 22. The two third power terminals 15 are spaced apart from each other in the third direction y. The two third power terminals 15 are metal leads made of a material containing copper or a copper alloy. Each of the two third power terminals 15 partly protrudes to the outside from the second side surface 54 of the sealing resin 50.

As shown in FIGS. 46, 48 and 49, the first signal terminal 161 is located next to one of the two second power terminals 14 in the third direction y. The first signal terminal 161 is electrically bonded to the first gate wiring layer 613 of the first wiring 61. This electrically connects the first signal terminal 161 to the first gate electrodes 213 of the first semiconductor elements 21. The first signal terminal 161 is a metal lead made of a material containing copper or a copper alloy. The first signal terminal 161 partly protrudes to the outside from the first side surface 53 of the sealing resin 50.

As shown in FIGS. 46 to 48, the second signal terminal 162 is located next to one of the two third power terminals 15 in the third direction y. The second signal terminal 162 is electrically bonded to the second gate wiring layer 623 of the second wiring 62. This electrically connects the second signal terminal 162 to the second gate electrodes 223 of the second semiconductor elements 22. The second signal terminal 162 is a metal lead made of a material containing copper or a copper alloy. The second signal terminal 162 partly protrudes to the outside from the second side surface 54 of the sealing resin 50.

As shown in FIGS. 46, 48 and 49, the third signal terminal 171 is located next to the first signal terminal 161 in the third direction y. The third signal terminal 171 is electrically bonded to the first sensing wiring layer 614 of the first wiring 61. Hence, the third signal terminal 171 is electrically connected to one of the two first sensing electrodes 214 of each first semiconductor element 21. The third signal terminal 171 is a metal lead made of a material containing copper or a copper alloy. The third signal terminal 171 partly protrudes to the outside from the first side surface 53 of the sealing resin 50.

As shown in FIGS. 46 to 48, the fourth signal terminal 172 is located next to the second signal terminal 162 in the third direction y. The fourth signal terminal 172 is electrically bonded to the third sensing wiring layer 624 of the second wiring 62. Hence, the fourth signal terminal 172 is electrically connected to one of the two second sensing electrodes 224 of each second semiconductor element 22. The fourth signal terminal 172 is a metal lead made of a material The fourth signal containing copper or a copper alloy. terminal 172 partly protrudes to the outside from the second side surface 54 of the sealing resin 50.

As shown in FIGS. 46 to 48, the two sixth signal terminals 182 are located opposite to the second signal terminal 162 and the fourth signal terminal 172 in the third direction y with respect to the eighth signal terminal 192. The two sixth signal terminals 182 are located between one of the third power terminals 15 and the eighth signal terminal 192 in the third direction y. The two sixth signal terminals 182 are electrically bonded to the respective second temperature sensing layers 625 of the second wiring 62. Hence, the two sixth signal terminals 182 are electrically connected to the thermistor 23. The two sixth signal terminals 182 are metal leads made of a material containing copper or a copper alloy. Each of the two sixth signal terminals 182 partly protrudes to the outside from the second side surface 54 of the sealing resin 50.

As shown in FIGS. 46, 48 and 49, the seventh signal terminal 191 is located between the third signal terminal 171 and the first power terminal 13 in the third direction y. The seventh signal terminal 191 is electrically bonded to the second sensing wiring layer 616 of the first wiring 61. Hence, the seventh signal terminal 191 is electrically connected to the first conductive layer 121. The seventh signal terminal 191 is a metal lead made of a material containing copper or a copper alloy. The seventh signal terminal 191 partly protrudes to the outside from the first side surface 53 of the sealing resin 50.

As shown in FIGS. 46 to 48, the eighth signal terminal 192 is located next to the fourth signal terminal 172 in the third direction y. The eighth signal terminal 192 is electrically bonded to the fourth sensing wiring layer 626 of the second wiring 62. Hence, the eighth signal terminal 192 is electrically connected to the third conductive layer 123. The eighth signal terminal 192 is a metal lead made of a material containing copper or a copper alloy. The eighth signal terminal 192 partly protrudes to the outside from the second side surface 54 of the sealing resin 50.

### Semiconductor Module C70

Next, with reference to FIGS. 59 to 61, the semiconductor module C70 will be described. For the convenience of description, FIG. 60 shows the additional cooling unit A10′ as transparent.

As shown in FIG. 59, the additional cooling unit A10′ is spaced apart from the cooling unit A10 in the first direction z. The semiconductor devices B40 are bonded to both the cooling unit A10 and the additional cooling unit A10′ at a location between the obverse surfaces 701 of the respective housings 70 of the cooling units A10 and A10′ in the first direction z. Each semiconductor devices B40 covers a recess 71 of the housing 70 of the cooling unit A10 and a recess 71 of the housing 70 of the additional cooling unit A10′.

As shown in FIG. 61, the second heat dissipating layer 104 of each semiconductor device B40 covers the corresponding recess 71 of the housing 70 of the cooling unit A10. The second base surface 104A of the second heat dissipating layer 104 faces the recess 71 of the cooling unit A10. As viewed in the first direction z, the second depressions 104B in the second heat dissipating layer 104 overlap with the recess 71 of the cooling unit A10. As viewed in the first direction z, in addition, the peripheral edge of the second heat dissipating layer 104 surrounds the recess 71 of the cooling unit A10. The second base surface 104A is in contact with the obverse surface 701 of the housing 70 of the cooling unit A10. In addition, the sealing resin 50 of each semiconductor device B40 is disposed such that the bottom surface 52 is spaced apart from the obverse surface 701 of the cooling unit A10.

As shown in FIG. 61, the second base surface 104A of the second heat dissipating layer 104 overlaps with the heat dissipating members 81 of the cooling unit A10 as viewed in the first direction z. Hence, the second depressions 104B in the second heat dissipating layer 104 are spaced apart from each heat dissipating member 81 of the cooling unit A10 as viewed in the first direction z. The heat dissipating members 81 of the cooling unit A10 are in contact with the second base surface 104A.

As shown in FIGS. 60 and 61, the first heat dissipating layer 103 of each semiconductor device B40 covers a recess 71 of the housing 70 of the additional cooling unit A10′. The first base surface 103A of the first heat dissipating layer 103 faces the recess 71 of the additional cooling unit A10′. As viewed in the first direction z, the first depressions 103B in the first heat dissipating layer 103 overlap with the recess 71 in the additional cooling unit A10′. As viewed in the first direction z, in addition, the peripheral edge of the first heat dissipating layer 103 surrounds the recess 71 of the additional cooling unit A10′. The first base surface 103A is in contact with the obverse surface 701 of the housing 70 of the additional cooling unit A10′. In addition, the sealing resin 50 of each semiconductor device B40 is disposed such that the top surface 51 is spaced apart from the obverse surface 701 of the additional cooling unit A10′.

As shown in FIGS. 60 and 61, the first base surface 103A of the first heat dissipating layer 103 overlaps with the heat dissipating members 81 of the additional cooling unit A10′ as viewed in the first direction z. Hence, the first depressions 103B in the first heat dissipating layer 103 are spaced apart from each heat dissipating member 81 of the additional cooling unit A10′ as viewed in the first direction z. The heat dissipating members 81 of the additional cooling unit A10′ are in contact with the first base surface 103A.

As shown in FIG. 59, the connecting members 78 connect the cooling unit A10 and the additional cooling unit A10′ along their ends in the third direction y. The connecting members 78 may be thin plates, for example. Each connecting member 78 is attached to the cooling unit A10 and the additional cooling unit A10′ with two fastening members 79. The two fastening members 79 may be bolts, for example.

As shown in FIG. 61, in the semiconductor module C70, a load N in the first direction z is applied to the heat dissipating members 81 of the cooling unit A10 from the second base surface 104A of the second heat dissipating layer 104 of the semiconductor device B40. In response, the elastic portion 721 of the bottom portion 72 of the cooling unit A10 exerts an elastic force E that opposes the load N in the first direction z on the heat dissipating members 81.

As shown in FIG. 61, in the semiconductor module C70, a load N′ in the first direction z is applied to the heat dissipating members 81 of the additional cooling unit A10′ from the first base surface 103A of the first heat dissipating layer 103 of the semiconductor device B40. In response, the elastic portion 721 of the bottom portion 72 of the additional cooling unit A10′ exerts an elastic force E′ that opposes the load N′ in the first direction z on the heat dissipating members 81.

Next, advantages of the semiconductor module C70 will be described.

The semiconductor module C70 includes a cooling unit A10, an additional cooling unit A10′ spaced apart from the cooling unit A10 in the first direction z, and a semiconductor device B40. Each of the cooling unit A10 and the additional cooling unit A10′ includes a housing 70 including a recess 71 and a bottom portion 72; and a heat dissipating member 81 attached to the bottom portion 72 and at least partly accommodated in the recess 71. The recess 71 of each of the cooling unit A10 and the additional cooling unit A10′ includes an inlet 711 and an outlet 712. The semiconductor device B40 includes a first heat dissipating layer 103 and a second heat dissipating layer 104 respectively covering e recess 71 of the additional cooling unit A10′ and the recess of the cooling unit A10. The first heat dissipating layer 103 includes a first depression 103B that overlaps with the recess 71 of the additional cooling unit A10′ as viewed in the first direction z. The second heat dissipating layer 104 includes a second depression 104B that overlaps with the recess 71 of the cooling unit A10 as viewed in first direction z. This configuration promotes the flow of coolant circulating in the semiconductor module C70 into the respective recesses 71 of the cooling unit A10 and the additional cooling unit A10′. This ensures that the coolant flowing along the heat dissipating member 81 of the additional cooling unit A10′ is directed to the first base surface 103A and also to the first depression 103B of the first heat dissipating layer 103. In addition, the coolant flowing along the heat dissipating member 81 of the cooling unit A10 is directed to the second base surface 104A and also to the second depression 104B of the second heat dissipating layer 104. This means that the greater areas of the first heat dissipating layer 103 and the second heat dissipating layer 104 are in contact with coolant. This configuration of the semiconductor module C70 can therefore achieve more efficient cooling of the semiconductor device B10 that is attached to the cooling unit A10 and the additional cooling unit A10′. The semiconductor module C70 has a configuration in common with the semiconductor module C10, thereby achieving the same effect as the semiconductor module C10.

### Eighth Embodiment

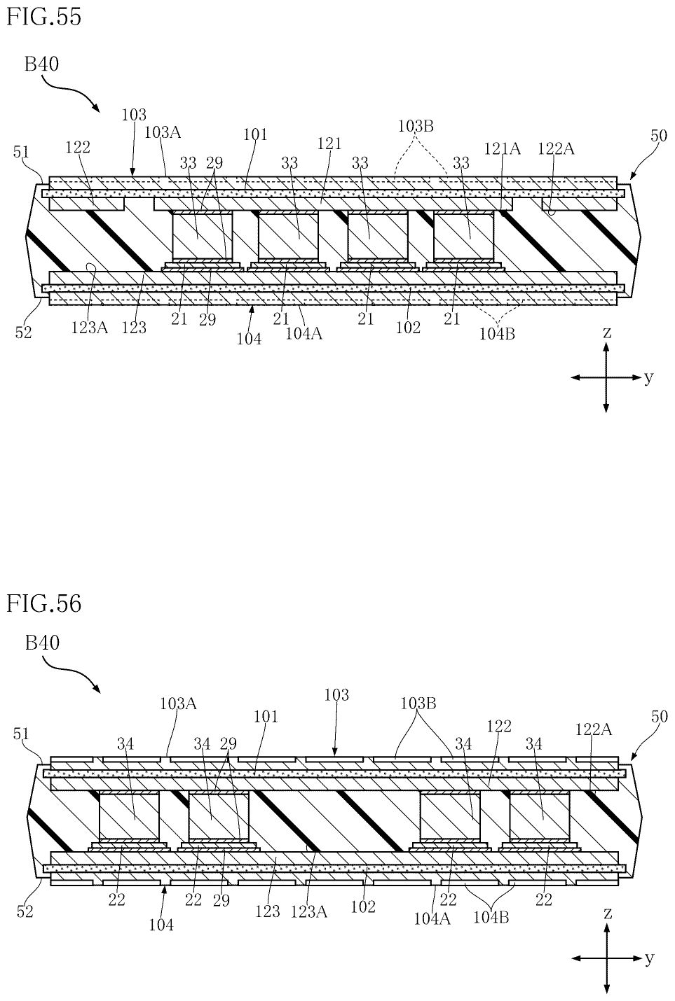

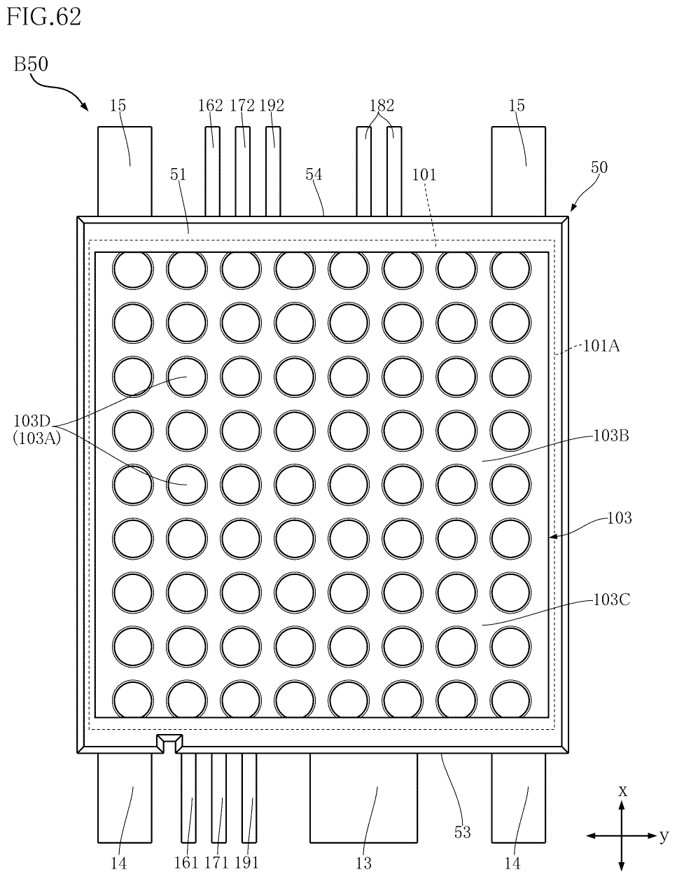

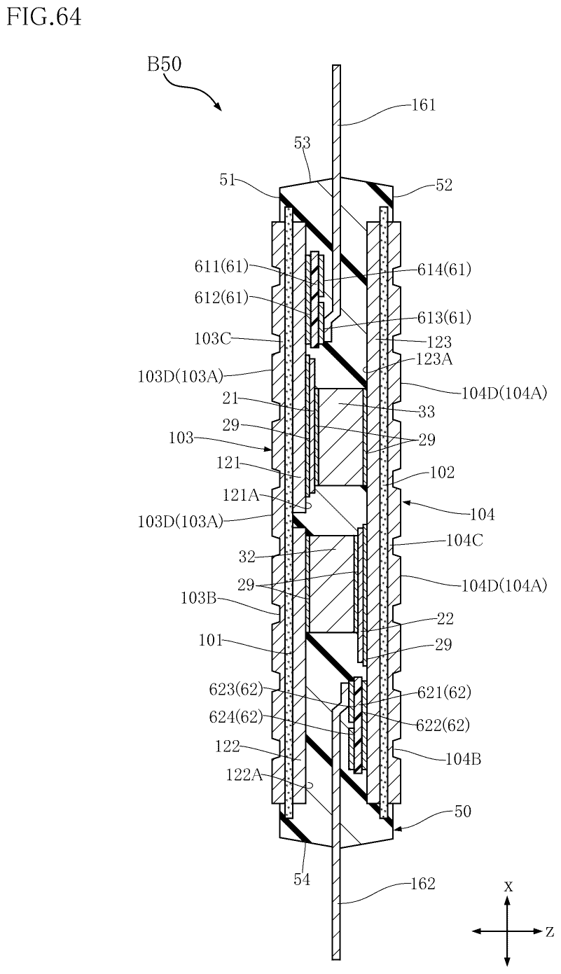

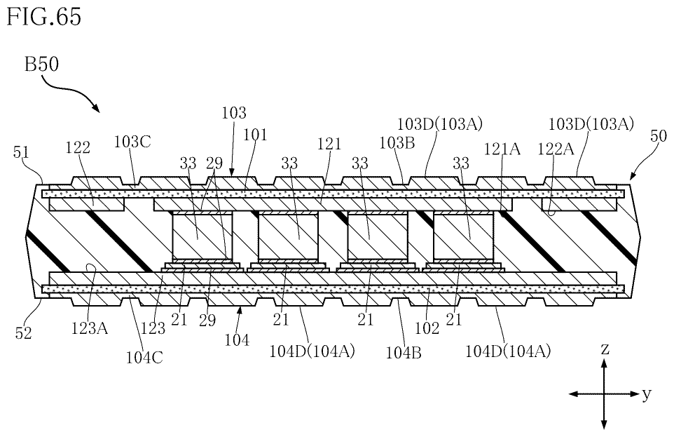

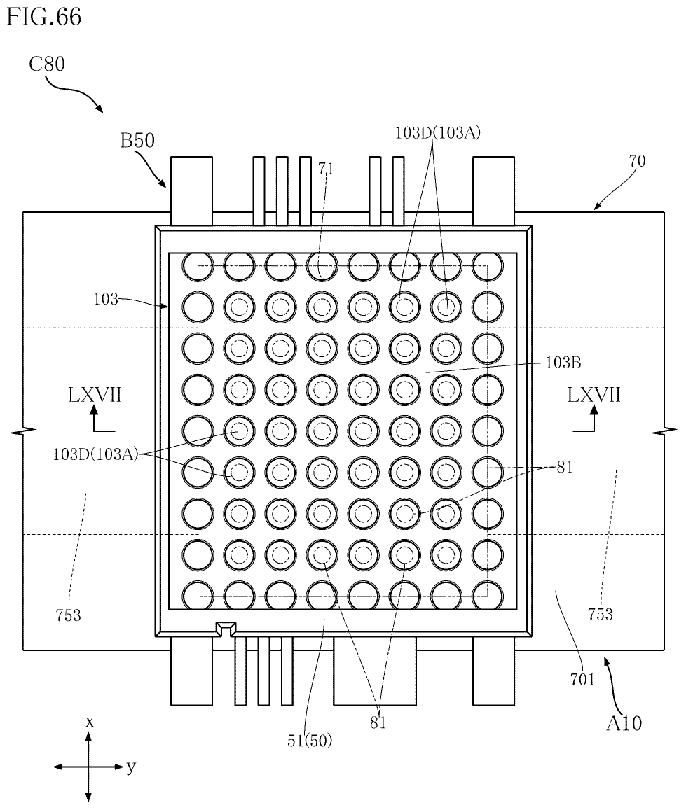

With reference to FIGS. 62 to 67, a semiconductor module C80 according to an eighth embodiment of the present disclosure will be described. In these figures, elements that are identical or similar to those of the cooling unit A10, the semiconductor devices B10, and the semiconductor module C10 described above are indicated by the same reference numerals. In addition, description of such elements is not repeated to avoid redundancy. Note that FIG. 64 corresponds to FIG. 54 showing the semiconductor device B40, and FIG. 65 corresponds to FIG. 55 showing the semiconductor device B40. For the convenience of description, FIG. 66 shows the additional cooling unit A10′ as transparent.

The semiconductor module C80 includes a cooling unit A10, an additional cooling unit A10′, a plurality of semiconductor devices B50, and a plurality of connecting members 78. Similarly to the semiconductor module C70 described above, the additional cooling unit A10′ is identical in configuration to the cooling unit A10. Each semiconductor device B50 differs from the semiconductor devices B40 in the configurations of the first heat dissipating layer 103 and the second heat dissipating layer 104.

As shown in FIGS. 62, 64, and 65, the first heat dissipating layer 103 includes a first base 103C and a plurality of first protrusions 103D. The first base 103C is bonded to the first insulating layer 101. At least a portion of the first base 103C is exposed from the top surface 51 of the sealing resin 50. Each first protrusion 103D protrudes from the first base 103C in the first direction z. Each first protrusion 103D has a first base surface 103A. In the semiconductor device B50, one first depression 103B is defined by the first base 103C and the first protrusions 103D. The first depression 103B is a continuous region.

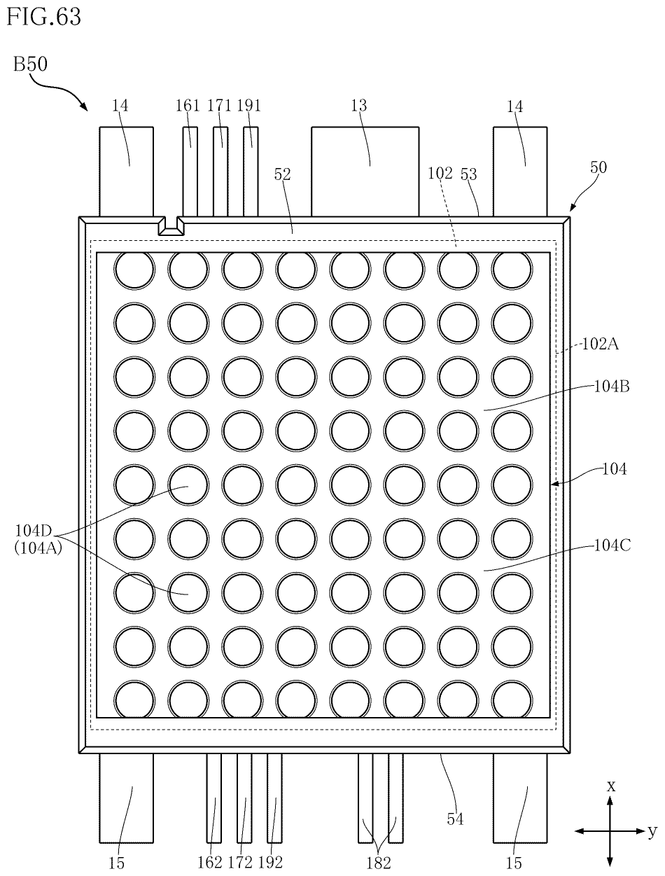

As shown in FIGS. 63 to 65, the second heat dissipating layer 104 includes a second base 104C and a plurality of second protrusions 104D. The second base 104C is bonded to the second insulating layer 102. At least a portion of the second base 104C is exposed from the bottom surface 52 of the sealing resin 50. Each second protrusion 104D protrudes from the second base 104C in the first direction z. Each second protrusion 104D has a second base surface 104A. In the semiconductor device B50, one second depression 104B is defined by the second base 104C and a plurality of second protrusions 104D. The second depression 104B is a continuous region.

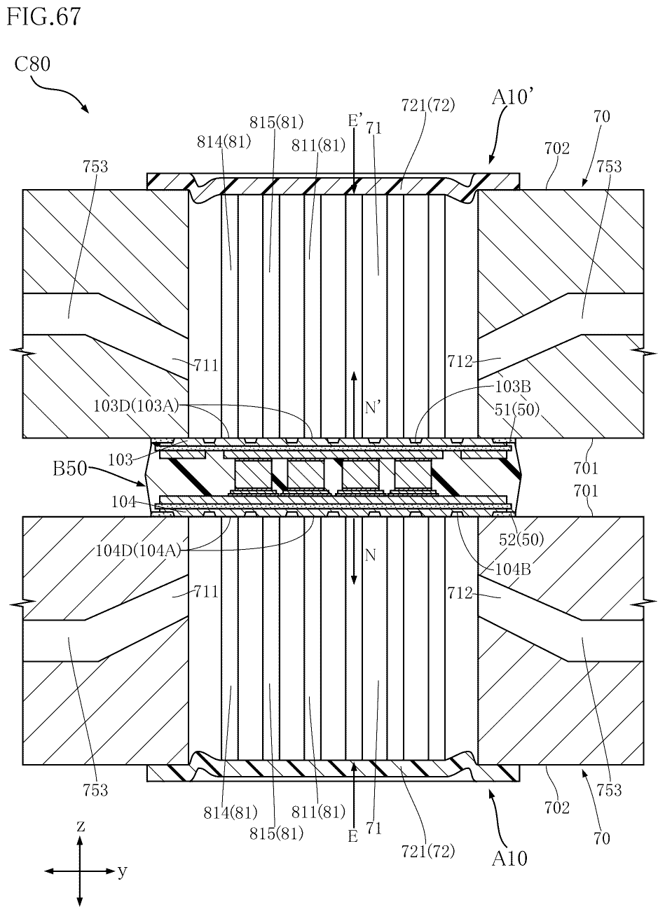

As shown in FIG. 67, the second heat dissipating layer 104 of each semiconductor device B50 is disposed such that the second protrusions 104D overlap with a recess 71 of the housing 70 of the cooling unit A10 and also with the heat dissipating members 81 of the cooling unit A10 as viewed in the first direction z. The second protrusions 104D include those overlapping with the first to fifth members 811 to 815 of the heat dissipating members 81 of the cooling unit A10 as viewed in the first direction z. The heat dissipating members 81 of the cooling unit A10 are in contact with the second protrusions 104D.

As shown in FIGS. 66 and 67, the first heat dissipating layer 103 of each semiconductor device B50 is disposed such that the first protrusions 103D overlap with a recess 71 of the housing 70 of the additional cooling unit A10′ and also with the heat dissipating members 81 of the additional cooling unit A10′. The first protrusions 103D include those overlapping with the first to fifth members 811 to 815 of the heat dissipating members 81 of the additional cooling unit A10′ as viewed in the first direction z. The heat dissipating members 81 of the additional cooling unit A10′ are in contact with the first protrusions 103D.

Next, advantages of the semiconductor module C80 will be described.

The semiconductor module C80 includes a cooling unit A10, an additional cooling unit A10′ spaced apart from the cooling unit A10 in the first direction z, and a semiconductor device B50. The cooling unit A10 and the additional cooling unit A10′ each include a housing 70 including a recess 71 and a bottom portion 72; and a heat dissipating member 81 attached to the bottom portion 72 and at least partly accommodated in the recess 71. The recess 71 of each of the cooling unit A10 and the additional cooling unit A10′ includes an inlet 711 The semiconductor device B50 includes a and an outlet 712. first heat dissipating layer 103 and a second heat dissipating layer 104 covering the respective recesses 71 of the additional cooling unit A10′ and the cooling unit A10. The first heat dissipating layer 103 includes a first depression 103B that overlaps with the recess 71 of the additional cooling unit A10′ as viewed in the first direction z. The second heat dissipating layer 104 includes a second depression 104B that overlaps with the recess 71 of the cooling unit A10 as viewed in first direction z. This configuration of the semiconductor module C80 can therefore achieve more efficient cooling of the semiconductor device B10 that is attached to the cooling unit A10 and the additional cooling unit A10′. The semiconductor module C80 has a configuration in common with the semiconductor module C10, thereby achieving the same effect as the semiconductor module C10.

The present disclosure is not limited to the embodiments described above. Various design changes may be made freely in the specific structure of each part of the present disclosure.

The present disclosure includes embodiments described in the following clauses.

Clause 1. A semiconductor module comprising:
a cooling unit; and
a semiconductor device attached to the cooling unit,
wherein the cooling unit includes: a housing including a recess that is open on a first side in a first direction and a bottom portion that is located on a second side in the first direction and defines a portion of the recess; and a heat dissipating member attached to the bottom portion, at least a portion of the heat dissipating member being accommodated in the recess,
the semiconductor device includes a substrate, a conductive layer supported on the substrate, and a semiconductor element disposed opposite to the substrate with respect to the conductive layer and bonded to the conductive layer,
the recess includes an inlet and an outlet opposite to each other with respect to the recess in a direction orthogonal to the first direction,
the substrate includes a heat dissipating layer covering the recess,
the heat dissipating layer includes a base surface facing the recess and a depression recessed from the base surface, and
the depression overlaps with the recess as viewed in the first direction.

Clause 2. The semiconductor module according to Clause 1, wherein the base surface overlaps with the heat dissipating member as viewed in the first direction.

Clause 3. The semiconductor module according to Clause 2, wherein the heat dissipating member is in contact with the base surface.

Clause 4. The semiconductor module according to Clause 3, further comprising a mounting component that secures the semiconductor device to the cooling unit,
wherein the bottom portion includes an elastic portion that is elastically deformable,
a load in the first direction toward the bottom portion is applied from the mounting component to the semiconductor device, and
an elastic force opposing the load in the first direction is applied from the elastic portion to the heat dissipating member.

Clause 5. The semiconductor module according to Clause 4, wherein the semiconductor device further includes a sealing resin covering the conductive layer and the semiconductor element,
the heat dissipating layer is exposed from the sealing resin, and
the mounting component is in contact with the sealing resin.

Clause 6. The semiconductor module according to Clause 5, wherein the base surface protrudes from the sealing resin.

Clause 7. The semiconductor module according to Clause 6, wherein the recess is surrounded by a peripheral edge of the heat dissipating layer as viewed in the first direction.

Clause 8. The semiconductor module according to any one of Clauses 4 to 7, wherein the heat dissipating member includes a first member and a second member spaced apart from each other in a second direction orthogonal to the first direction,
the housing includes an obverse surface facing a side where the heat dissipating member is located in the first direction with respect to the bottom portion and surrounding the recess,
the first member and the second member are surrounded by the obverse surface as viewed in the first direction,
the first member is closer to a center of the recess as viewed in the first direction,
the second member is closer to the obverse surface, and each of the first member and the second member includes a portion protruding outward from the obverse surface when the elastic portion is in a natural state.

Clause 9. The semiconductor module according to Clause 8, wherein the elastic portion is composed of one piece, and the first member and the second member are supported on the elastic portion.

Clause 10. The semiconductor module according to Clause 9, wherein when the elastic portion is in the natural state, an amount of the portion of each of the first and second members protruding outward from the obverse surface is greater for the first member than for the second member.

Clause 11. The semiconductor module according to Clause 10, wherein the heat dissipating member includes a third member located between the first member and the second member in the second direction and supported on the elastic portion,
the third member includes a portion protruding outward from the obverse surface when the elastic portion is in the natural state, and
when the elastic portion is in the natural state, an amount of the portion of each of the first, second, and third members protruding outward from the obverse surface is greater for the first member than for the third member, and greater for the third member than for the second member.

Clause 12. The semiconductor module according to Clause 8, wherein the elastic portion includes a first elastic portion and a second elastic portion spaced apart from each other,
the first member is supported on the first elastic portion, and
the second member is supported on the second elastic portion.

Clause 13. The semiconductor module according to Clause 8, wherein the inlet ant the outlet are located opposite to each other with respect to the recess in a third direction orthogonal to the first direction and the second direction, and
the first member overlaps with the inlet and the outlet as viewed in the third direction.

Clause 14. The semiconductor module according to Clause 13, wherein each of the first member and the second member is a plate-like structure that extends in the third direction.

Clause 15. The semiconductor module according to Clause 8, wherein the housing includes a reverse surface facing away from the obverse surface in the first direction,
a distance between the inlet and the obverse surface in the first direction is smaller than a distance between the inlet and the reverse surface in the first direction, and
a distance between the outlet and the obverse surface in the first direction is smaller than a distance between the outlet and the reverse surface in the first direction.

Clause 16. The semiconductor module according to Clause 15, wherein the cooling unit further includes a guide member accommodated in the recess and bonded to the housing,
the guide member includes a plurality of holes penetrating in the first direction, and
the first member and the second member are individually inserted through the plurality of holes.

Clause 17. The semiconductor module according to Clause 16, wherein the guide member is located between the reverse surface and each of the inlet and the outlet in the first direction.

Clause 18. A semiconductor module comprising:
a first cooling unit;
a second cooling unit spaced apart from the first cooling unit in a first direction; and
a semiconductor device attached to the first cooling unit and the second cooling unit,
wherein each of the first cooling unit and the second cooling unit includes: a housing including a recess that is open on a first side in a first direction and a bottom portion that is located on a second side in the first direction and defines a portion of the recess; and a heat dissipating member attached to the bottom portion, at least a portion of the heat dissipating member being accommodated in the recess,
the semiconductor device includes: first a heat dissipating layer covering the recess of the second cooling unit; a second heat dissipating layer covering the recess of the first cooling unit; and a semiconductor element located between the first heat dissipating layer and the second heat dissipating layer,
the recess of each of the first cooling unit and the second cooling unit includes an inlet and an outlet opposite to each other with respect to the recess in a direction orthogonal to the first direction,
the first heat dissipating layer includes a first base surface facing the recess of the second cooling unit and a first depression recessed from the first base surface,
the first depression overlaps with the recess of the second cooling unit as viewed in the first direction,
the second heat dissipating layer includes a second base surface facing the recess of the first cooling unit and a second depression recessed from the second base surface, and
the second depression overlaps with the recess of the first cooling unit as viewed in the first direction.

REFERENCE NUMERALS

| | |
|---|---|
| A10 to A50: cooling unit (first | |
| cooling unit) | |
| A10′: additional cooling unit | |
| (second cooling unit) | |
| B10 to B50: semiconductor device | |
| C10 to C80: semiconductor module | |
| 101: first insulating layer | 101A: peripheral edge |
| 102: second insulating layer | 102A: peripheral edge |
| 103: first heat dissipating layer | 103A: first base surface |
| 103B: first depression | 103C: first base |
| 103D: first protrusion | 104: second heat dissipating layer |
| 104A: second base surface | 104B: second depression |
| 104C: second base | 104D: second protrusion |
| 11: substrate | 111: insulating layer |
| 111A: peripheral edge | 112: intermediate layer |
| 113: heat dissipating layer | 113A: base surface |
| 113B: depression | 121: first conductive layer |
| 121A: first obverse surface | 122: second conductive layer |
| 122A: second obverse surface | 123: third conductive layer |
| 123A: third obverse surface | 129: first bonding layer |
| 13: first power terminal | 131: covered portion |
| 132: exposed portion | 14: second power terminal |
| 141: covered portion | 142: exposed portion |
| 15: third power terminal | 151: covered portion |
| 152: exposed portion | 161: first signal terminal |
| 162: second signal terminal | 171: third signal terminal |
| 172: fourth signal terminal | 181: fifth signal terminal |
| 182: sixth signal terminal | 191: seventh signal terminal |
| 192: eighth signal terminal | 20: semiconductor element |
| 21: first semiconductor element | 211: first electrode |
| 212: second electrode | 213: first gate electrode |
| 214: first sensing electrode | |
| 22: second semiconductor element | |
| 221: third electrode | 222: fourth electrode |
| 223: second gate electrode | 224: second sensing electrode |
| 23: thermistor | 29: conductive bonding layer |
| 31: first conductive member | 311: body |
| 312: first bonding portion | 313: first connecting portion |
| 314: second bonding portion | 315: second connecting portion |
| 32: second conductive member | 321: body |
| 322: third bonding portion | 323: third connecting portion |
| 324: fourth bonding portion | 325: fourth connecting portion |
| 326: intermediate portion | 327: cross beam |
| 33: first spacer | 34: second spacer |
| 41 to 48: first to eighth wires | 50: sealing resin |
| 51: top surface | 52: bottom surface |
| 53: first side surface | 54: second side surface |
| 55: recessed portion | 61: first wiring |
| 611: first mounting layer | 612: first metal layer |
| 613: first gate wiring layer | |
| 614: first sensing wiring layer | |
| 615: first temperature sensing layer | |
| 616: second sensing wiring layer | |
| 62: second wiring | 621: second mounting layer |
| 622: second metal layer | 623: second gate wiring layer |
| 624: third sensing wiring layer | |
| 625: second temperature sensing | |
| layer | |
| 626: fourth sensing wiring layer | 63: sleeve |
| 631: end surface | 68: second bonding layer |
| 69: third bonding layer | 70: housing |
| 701: obverse surface | 702: reverse surface |
| 71: recess | 711: inlet |
| 712: outlet | 72: bottom portion |
| 721: elastic portion | 721A: first elastic portion |
| 721B: second elastic portion | 721C: third elastic portion |
| 721D: fourth elastic portion | 721E: fifth elastic portion |
| 722: base | 73: inflow section |
| 74: outflow section | 751: first channel |
| 752: second channel | 753: intermediate channel |
| 76: mounting hole | 78: connecting member |
| 79: fastening member | 81: heat dissipating member |
| 811: first member | 812: second member |
| 813: third member | 814: fourth member |
| 815: fifth member | 82: guide member |
| 821: hole | 88: mounting component |
| 89: fastening member | z: first direction |
| x: second direction | y: third direction |

1. A semiconductor module comprising:
a cooling unit; and
a semiconductor device attached to the cooling unit,
wherein the cooling unit includes: a housing including a recess that is open on a first side in a first direction and a bottom portion that is located on a second side in the first direction and defines a portion of the recess; and a heat dissipating member attached to the bottom portion, at least a portion of the heat dissipating member being accommodated in the recess,
the semiconductor device includes a substrate, a conductive layer supported on the substrate, and a semiconductor element disposed opposite to the substrate with respect to the conductive layer and bonded to the conductive layer,
the recess includes an inlet and an outlet opposite to each other with respect to the recess in a direction orthogonal to the first direction,
the substrate includes a heat dissipating layer covering the recess,
the heat dissipating layer includes a base surface facing the recess and a depression recessed from the base surface, and
the depression overlaps with the recess as viewed in the first direction.

2. The semiconductor module according to claim 1, wherein the base surface overlaps with the heat dissipating member as viewed in the first direction.

3. The semiconductor module according to claim 2, wherein the heat dissipating member is in contact with the base surface.

4. The semiconductor module according to claim 3, further comprising a mounting component that secures the semiconductor device to the cooling unit,
wherein the bottom portion includes an elastic portion that is elastically deformable,
a load in the first direction toward the bottom portion is applied from the mounting component to the semiconductor device, and
an elastic force opposing the load in the first direction is applied from the elastic portion to the heat dissipating member.

5. The semiconductor module according to claim 4, wherein the semiconductor device further includes a sealing resin covering the conductive layer and the semiconductor element,
the heat dissipating layer is exposed from the sealing resin, and
the mounting component is in contact with the sealing resin.

6. The semiconductor module according to claim 5, wherein the base surface protrudes from the sealing resin.

7. The semiconductor module according to claim 6, wherein the recess is surrounded by a peripheral edge of the heat dissipating layer as viewed in the first direction.

8. The semiconductor module according to claim 4, wherein the heat dissipating member includes a first member and a second member spaced apart from each other in a second direction orthogonal to the first direction,
the housing includes an obverse surface facing a side where the heat dissipating member is located in the first direction with respect to the bottom portion and surrounding the recess,
the first member and the second member are surrounded by the obverse surface as viewed in the first direction,
the first member is closer to a center of the recess as viewed in the first direction,
the second member is closer to the obverse surface, and
each of the first member and the second member includes a portion protruding outward from the obverse surface when the elastic portion is in a natural state.

9. The semiconductor module according to claim 8, wherein the elastic portion is composed of one piece, and
the first member and the second member are supported on the elastic portion.

10. The semiconductor module according to claim 9, wherein when the elastic portion is in the natural state, an amount of the portion of each of the first and second members protruding outward from the obverse surface is greater for the first member than for the second member.

11. The semiconductor module according to claim 10, wherein the heat dissipating member includes a third member located between the first member and the second member in the second direction and supported on the elastic portion,
the third member includes a portion protruding outward from the obverse surface when the elastic portion is in the natural state, and
when the elastic portion is in the natural state, an amount of the portion of each of the first, second, and third members protruding outward from the obverse surface is greater for the first member than for the third member, and greater for the third member than for the second member.

12. The semiconductor module according to claim 8, wherein the elastic portion includes a first elastic portion and a second elastic portion spaced apart from each other,
the first member is supported on the first elastic portion, and
the second member is supported on the second elastic portion.

13. The semiconductor module according to claim 8, wherein the inlet ant the outlet are located opposite to each other with respect to the recess in a third direction orthogonal to the first direction and the second direction, and
the first member overlaps with the inlet and the outlet as viewed in the third direction.

14. The semiconductor module according to claim 13, wherein each of the first member and the second member is a plate-like structure that extends in the third direction.

15. The semiconductor module according to claim 8, wherein the housing includes a reverse surface facing away from the obverse surface in the first direction,
a distance between the inlet and the obverse surface in the first direction is smaller than a distance between the inlet and the reverse surface in the first direction, and
a distance between the outlet and the obverse surface in the first direction is smaller than a distance between the outlet and the reverse surface in the first direction.

16. The semiconductor module according to claim 15, wherein the cooling unit further includes a guide member accommodated in the recess and bonded to the housing,
the guide member includes a plurality of holes penetrating in the first direction, and
the first member and the second member are individually inserted through the plurality of holes.

17. The semiconductor module according to claim 16, wherein the guide member is located between the reverse surface and each of the inlet and the outlet in the first direction.

18. A semiconductor module comprising:
a first cooling unit;
a second cooling unit spaced apart from the first cooling unit in a first direction; and
a semiconductor device attached to the first cooling unit and the second cooling unit,
wherein each of the first cooling unit and the second cooling unit includes: a housing including a recess that is open on a first side in a first direction and a bottom portion that is located on a second side in the first direction and defines a portion of the recess; and a heat dissipating member attached to the bottom portion, at least a portion of the heat dissipating member being accommodated in the recess,
the semiconductor device includes: a first heat dissipating layer covering the recess of the second cooling unit; a second heat dissipating layer covering the recess of the first cooling unit; and a semiconductor element located between the first heat dissipating layer and the second heat dissipating layer,
the recess of each of the first cooling unit and the second cooling unit includes an inlet and an outlet opposite to each other with respect to the recess in a direction orthogonal to the first direction,
the first heat dissipating layer includes a first base surface facing the recess of the second cooling unit and a first depression recessed from the first base surface,
the first depression overlaps with the recess of the second cooling unit as viewed in the first direction,
the second heat dissipating layer includes a second base surface facing the recess of the first cooling unit and a second depression recessed from the second base surface, and
the second depression overlaps with the recess of the first cooling unit as viewed in the first direction.
